(19) United States
(12) Patent Application Publication
(10) Pub. No.: US 2009/0321814 A1
(43) Pub. Date: Dec. 31, 2009

(54) SEMICONDUCTOR MEMORY DEVICE AND MANUFACTURING METHOD OF THE SAME

(76) Inventors: Koichi KAWASHIMA, Hyogo (JP); Nobuyoshi Takahashi, Niigata (JP)

Correspondence Address: MCDERMOTT WILL & EMERY LLP, 600 13TH STREET, NW, WASHINGTON, DC, 20005-3096, US

(21) Appl. No.: 12/433,535

(22) Filed: Apr. 30, 2009

(30) Foreign Application Priority Data
Jun. 25, 2008 (JP) 2008-165617

(51) Int. Cl. H01L 29/792; H01L 29/788; H01L 21/336

(52) U.S. Cl. 257/324; 438/261; 257/E29.309; 257/E29.3; 257/E21.409; 257/314; 438/257

(57) ABSTRACT

A semiconductor memory device includes, in a memory region, a plurality of bit line diffusion layers, a plurality of word lines, and a plurality of memory elements composed of a bit line diffusion layer pair, a gate insulating film, and a gate electrode. The plurality of bit line diffusion layers are divided into plural in respective columns, and are connected electrically to each other through bit line contact diffusion layers. The width of sidewall insulating films on the sides of the bit line contact diffusion layers formed at the word lines arranged adjacent to the bit line contact diffusion layers is smaller than that of the sidewall insulating films formed on the opposite sides of the bit line contact diffusion layers.

### CROSS REFERENCE TO RELATED APPLICATIONS

This application claims priority under 35 U.S.C. §119(a) on Patent Application No. 2008-165617 filed in Japan on Jun. 25, 2008, the entire contents of which are hereby incorporated by reference.

### BACKGROUND

The present disclosure relates to semiconductor memory devices and manufacturing methods thereof, and particularly relates to a nonvolatile semiconductor memory device having a structure in which bit line diffusion layers are electrically connected to bit lines thereabove through bit line contact parts, and a manufacturing method thereof.

Recently, various kinds of nonvolatile semiconductor memory devices are proposed. For example, a nonvolatile semiconductor memory element is configured in such a fashion that bit lines composed of a diffusion layer and word lines composed of a conductive layer of polysilicon or the like are intersected with one another and charges are stored in a trap film. Such an element can be highly integrated easily, and therefore catches attention (see US Patent Application publication No. 2006/0214218, for example).

The conventional nonvolatile semiconductor memory device and a manufacturing method thereof will be described below.

The structure of the conventional nonvolatile semiconductor memory device is shown in the plan view of FIG. 38 and the cross-sectional views of FIG. 39A to FIG. 39E

FIG. 39A is a cross-sectional view taken along the line 100a1-100a2 in FIG. 38. FIG. 39B is a cross-sectional view taken along the line 100b1-100b2 in FIG. 38. FIG. 39C is a cross-sectional view taken along the line 100c1-100c2 in FIG. 38. FIG. 39D is a cross-sectional view taken along the line 100d1-100d2 in FIG. 38. FIG. 39E is a cross-sectional view taken along the line 100e-100e2 in FIG. 38.

The manufacturing method for realizing the structure of the conventional nonvolatile semiconductor memory device will be described in sequence of the manufacturing process with reference to FIGS. 40A to 40E, 41A to 41E, 42A to 42D, 43A to 43D, 44A to 44D, 45A, and 45B. In the following description, the cross-sectional views indicating key points in the steps will referred to.

First of all, as shown in FIG. 40A (a cross-sectional view corresponding to that taken along the line 100d1-100d2 in FIG. 38), a mask formation film 102A of silicon nitride with a thickness of, for example, about 80 nm to 300 nm is formed on the principal surface of a semiconductor substrate 101 made of silicon. Then, a resist film 103 is deposited, and openings are formed by photolithography.

Next, as shown in FIG. 40B (a cross-sectional view corresponding to that taken along the line 100d1-100d2 in FIG. 38), after the mask formation film 102A exposed in the openings is etched, and the resist film 103 is removed, the semiconductor substrate 101 is etched to form trenches below the openings of a mask film 102.

Subsequently, as shown in FIG. 40C (a cross-sectional view corresponding to that taken along the line 100d1-100d2 in FIG. 38), an insulating film of silicon oxide or the like is filled in the trenches, and the oxide silicon thus filled is planarized by chemical mechanical polishing (CMP) to form isolation regions 104 by STI or the like. The height of the surface of the isolation regions 104 is equal to that of the mask film 102 initially by planarization by CMP, and is therefore adjusted not to be lower than the surface of the semiconductor substrate 101 by wet etching or the like for preparation. This height adjustment is performed for facilitating the later etching process, and is employed usually.

Thereafter, as shown in FIG. 40D (a cross-sectional view corresponding to that taken along the line 100d1-100d2 in FIG. 38), a trap film 106 is deposited entirely. Then, a mask formation film 107A of silicon nitride, for example, is deposited, and a resist film 108 is coated on the mask formation film 107A.

Next, as shown in FIG. 40E (a cross-sectional view corresponding to that taken along the line 100b1-100b2 in FIG. 38), an opening pattern for opening regions where source/drain regions 105 are to be formed in a later step is formed in the resist film 108 by lithography.

Subsequently, as shown in FIG. 41A (a cross-sectional view corresponding to that taken along the line 100b1-100b2 in FIG. 38), dry etching using the resist film 108 as a mask is performed on the mask formation film 107A to form, from the mask formation film 107A, a mask film 107 having openings for forming the source/drain regions 105. Then, the trap film 106 below the openings of the patterned mask film 107 is removed.

Thereafter, as shown in FIG. 41B (a cross-sectional view corresponding to that taken along the line 100b1-100b2 in FIG. 38), ion implantation of, for example, arsenic as an n-type impurity is performed using the mask film 107 to form the source/drain regions 105 formed with n-type impurity diffusion layers. The source/drain regions 105 function as bit line diffusion layers 105.

Next, as shown in FIG. 41C (a cross-sectional view corresponding to that taken along the line 100b1-100b2 in FIG. 38), an insulating film 109A of, for example, silicon oxide is deposited to fill the openings of the mask film 107.

Subsequently, as shown in FIG. 41D (a cross-sectional view corresponding to that taken along the line 100b1-100b2 in FIG. 38), the silicon oxide film 109A other than its part filled in the openings of the mask film 107 is selectively removed.

Thereafter, as shown in FIG. 41E (a cross-sectional view corresponding to that taken along the line 100b1-100b2 in FIG. 38), only the mask film 107 is removed selectively to expose the trap film 106, while the upper part of the insulating film 109A is etched to form buried oxide films 109 as buried bit lines. Herein, in order to adjust the height of the buried bit line oxide films 109 from the semiconductor substrate 101, wet etching or etching back is performed before or after selective removal of the mask film 107 to reduce the height thereof. This height adjustment is performed for facilitating the later etching process, similarly to the height adjustment for the isolation regions.

Next, as shown in FIG. 42A (a cross-sectional view corresponding to that taken along the line 100d1-100d2 in FIG. 38) and FIG. 42B (a cross-sectional view corresponding to that taken along the line 100e1-100e2 in FIG. 38), a conductive film 110A of a polycrystalline silicon film functioning as word lines (gate electrodes) is deposited.

Subsequently, as shown in FIG. 42C (a cross-sectional view corresponding to that taken along the line 100d1-100d2 in FIG. 38) and FIG. 42D (a cross-sectional view corresponding to that taken along the line 100e1-100e2 in FIG. 38), after coating a resist film, a resist pattern 108 for forming the word lines is formed in the direction across the source/drain regions 105 spaced from each other by lithography.

Thereafter, as shown in FIG. 43A (a cross-sectional view corresponding to that taken along the line 100d1-100d2 in FIG. 38) and FIG. 43B (a cross-sectional view corresponding to that taken along the line 100e1-100e2 in FIG. 38), predetermined regions of the conductive film 110A of a polycrystalline silicon film are opened by dry etching using the resist pattern 108 as a mask to form gate electrodes 110 and to expose the trap film 106 in the openings.

Next, as shown in FIG. 43C (a cross-sectional view corresponding to that taken along the line 100d1-100d2 in FIG. 38) and FIG. 43D (a cross-sectional view corresponding to that taken along the line 100e1-100e2 in FIG. 38), an insulating film is deposited to fill the openings between the word lines (the gate electrodes) 110, and etching back is performed to remove the insulating film on the tope of the gate electrodes 110 with the insulating film between the gate electrodes 110 left to form buried insulating films 111. Bit line contact parts 113 are disposed every predetermined number of word lines, and function as bit line backing contact regions for electrically connecting upper bit lines as bit line backing wires to the bit line diffusion layers 105. Of the word lines, word lines closest to the bit line contact parts 113 serve as dummy word lines not contributing to memory cell transistors.

Subsequently, as shown in FIG. 44A (a cross-sectional view corresponding to that taken along the line 100d1-100d2 in FIG. 38) and FIG. 44B (a cross-sectional view corresponding to that taken along the line 100e1-100e2 in FIG. 38), ion implantation of, for example, arsenic as an n-type impurity is performed using a mask film 124 open at the bit line contact parts 113 to form a high-concentration impurity diffusion layers 125 of n-type impurity diffusion layers in bit line contact regions.

Thereafter, as shown in FIG. 44C (a cross-sectional view corresponding to that taken along the line 100d1-100d2 in FIG. 38) and FIG. 44D (a cross-sectional view corresponding to that taken along the line 100e1-100e2 in FIG. 38), a metal film of cobalt, nickel, or the like is deposited on the entirety of the semiconductor substrate 101 by vacuum deposition or the like, and then, thermal treatment is performed. Thus, a metal silicide layer 123 is formed in the upper parts of the gate electrodes 110 and the upper parts of the high-concentration impurity diffusion layers 125. Then, an interlayer insulating film 112 is deposited on the entirety of the semiconductor substrate 101.

Next, as shown in FIG. 45A, connection holes are formed in the interlayer insulating film 112 to expose the metal silicide layer 123 on the high-concentration impurity diffusion layers 125 in the bit line contact regions. A conductive film is formed on the interlayer insulating film 112 entirely so as to fill the connection holes to form bit line contacts 114 connected to the high-concentration impurity diffusion layers 125 in the bit line contact regions. The conductive film is formed with a single layer or stacked metal film of tungsten, a tungsten compound, titanium, or a titanium compound, such as titanium nitride, or the like.

Subsequently, as shown in FIG. 45B, a conductive film is deposited, and is patterned so that the high-concentration impurity diffusion layers 125 in the bit line contact regions are connected to each other, thereby forming the bit lines 115 from the conductive film.

In order to implement further miniaturization and high integration in the above conventional technique, not only the word line pitch but also the bit line contact parts 113 must be reduced in size. However, size reduction of the bit line contact parts 113 in the above conventional technique is difficult because a decrease in the electric resistance is involved, and necessitates in turn a technique of resistance reduction using metal silicide at the contact parts.

As a method for metal silicidation of the bit line contact parts 113, a silicidation technique has been proposed in which only the trap film 106 of the bit line contact parts 113 is removed by appropriately controlling overetching in sidewall formation in the stage shown in FIG. 43C and FIG. 43C (see R. Koval et. Al, “Flash ETOX Virtual Ground Architecture: A Future Scaling Direction,” 2005 Symposium on VLSI Technology, 11B-1).

As to a structure in which only the contract parts are minimized, a semiconductor memory element has been proposed, for example, in which the contact parts large in diameter relative to the sidewalls of the gate electrodes are opened by a self-aligning technique (see Japanese Unexamined Patent Application Publication 2001-127174).

This patent document employs a self-aligned contact formation technique in which: an insulating film is formed so as to cover the gate electrodes of memory cells, and contact holes having a diameter larger than the width of the contact parts on the silicon substrate are formed, so that the insulating films on the side walls and the tops of the gate electrodes are left appropriately. With this structure, the source/drain regions and the contacts can be formed with substantially no influence involved on the memory cell part even if the width between the gate electrodes is narrow, thereby enabling reduction of the memory cell area.

### SUMMARY

The inventors carried out various examinations to find that the following problems are involved when further miniaturization of the bit line contact parts 113 is implemented in the technique proposed in the above non-patent document, R. Koval et. Al, “Flash ETOX Virtual Ground Architecture: A Future Scaling Direction,” 2005 Symposium on VLSI Technology, 11B-1.

Sidewalls formed beside the dummy word lines adjacent to the bit line contact parts 113 extend toward the bit line contact parts 113, and therefore, it is necessary for removing the trap film 106 to perform excessive overetching for a time period longer than an actual time period that corresponds to the thickness of the trapping film. This excessive overetching removes a plenty amount of the material of the buried insulating films. This may cause formation of large projections and depressions between the word lines.

Description will be given next of a newly found disadvantage in the conventional nonvolatile semiconductor memory device and the manufacturing method thereof disclosed in the above non-patent document.

The structure in which the bit line contact parts 113 are miniaturized in memory cell arrays of the conventional nonvolatile semiconductor memory device is shown in the plan view of FIG. 46 and the cross-sectional views of FIGS. 47A to 47D and FIGS. 48A and 48B.

Herein, FIG. 47A is a cross-sectional view taken along the line 100a1-100a2 in FIG. 46. FIG. 47B is a cross-sectional view taken along the line 100b1-100b2 in FIG. 46. FIG. 47C is a cross-sectional view taken along the line 100c1-100c2 in FIG. 46. FIG. 47D is a cross-sectional view taken along the line 100d1-100d2 in FIG. 46. FIG. 48A is a cross-sectional view taken along the line 100e1-100e2 in FIG. 46. FIG. 48B is an enlarged view of a region A in FIG. 48A.

Description will be given of a method of manufacturing the conventional nonvolatile semiconductor memory device where the bit line contact parts 113 are miniaturized in the memory cell arrays, with reference to the plan view of FIG. 46 and the cross-sectional views of FIGS. 49 to 54.

First, as shown in FIG. 49A (a cross-sectional view corresponding to that taken along the line 100d1-100d2 in FIG. 46), a mask formation film 102A of silicon nitride with a thickness of, for example, about 80 nm to 300 nm is formed on the principal surface of a semiconductor substrate 100 made of silicon. Then, a resist film 103 is deposited, and openings are formed by photolithography.

Next, as shown in FIG. 49B (a cross-sectional view corresponding to that taken along the line 100d1-100d2 in FIG. 46), the mask formation film 102A below the resist openings is etched to form a mask film 102 having openings. After the resist film 103 is removed, the semiconductor substrate 100 below the openings of the mask film 102 is etched to form trenches.

Subsequently, as shown in FIG. 49C (a cross-sectional view corresponding to that taken along the line 100d1-100d2 in FIG. 46), an insulating film of silicon oxide or the like is filled in the trenches, and the oxide silicon thus filled is planarized by CMP to form an isolation region 104 by STI or the like. The height of the surfaces of the isolation regions 104 is equalized to that of the mask film 102 initially by planarization by CMP, and is therefore adjusted not to be lower than the surface of the semiconductor substrate 101 by wet etching or the like for preparation. This height adjustment is performed for facilitating the later etching process, and is employed usually.

Thereafter, as shown in FIG. 49D (a cross-sectional view corresponding to that taken along the line 100d1-100d2 in FIG. 46), a trap film 106 is deposited entirely. Then, a mask formation film 107A of silicon nitride, for example is deposited, and a resist film 108 is coated on the mask formation film 107A.

Next, as shown in FIG. 49E (a cross-sectional view corresponding to that taken along the line 100b1-100b2 in FIG. 46), an opening pattern for opening regions where the source/drain regions 105 are to be formed in a later step is formed in the resist film 108 by lithography.

Subsequently, as shown in FIG. 50A (a cross-sectional view corresponding to that taken along the line 100b1-100b2 in FIG. 46), dry etching using the resist film 108 as a mask is performed on the mask formation film 107A to form, from the mask formation film 107A, a mask film 107 having openings for forming the source/drain regions 105. Then, the trap film 106 below the openings of the patterned mask film 107 is removed.

Thereafter, as shown in FIG. 50B (a cross-sectional view corresponding to that taken along the line 100b1-100b2 in FIG. 46), ion implantation of, for example, arsenic as an n-type impurity is performed using the mask film 107 to form the source/drain regions 105 formed with n-type impurity diffusion layers. The source/drain regions 105 function as bit line diffusion layers 105.

Next, as shown in FIG. 50C (a cross-sectional view corresponding to that taken along the line 100b1-100b2 in FIG. 46), an insulating film 109A of, for example, silicon oxide is deposited to fill the openings of the mask film 107.

Subsequently, as shown in FIG. 50D (a cross-sectional view corresponding to that taken along the line 100b1-100b2 in FIG. 46), the silicon oxide film 109A other than its part filled in the openings of the mask film 107 is selectively removed.

Thereafter, as shown in FIG. 51A (a cross-sectional view corresponding to that taken along the line 100b1-100b2 in FIG. 46) and FIG. 51B (a cross-sectional view corresponding to that taken along the line 100e1-100e2 in FIG. 46), only the mask film 107 is removed selectively to expose the trap film 106, while the upper part of the insulating film 109A is etched to form buried oxide films 109 as buried bit lines. Herein, in order to adjust the height of the buried bit line oxide films 109 from the semiconductor substrate 101, wet etching or etching back before or after selective removal of the mask film 107 to reduce the height thereof. This height adjustment is performed for facilitating the later etching process, similarly to the height adjustment for the isolation regions.

Next, as shown in FIG. 51C (a cross-sectional view corresponding to that taken along the line 100d1-100d2 in FIG. 46) and FIG. 51D (a cross-sectional view corresponding to that taken along the line 100e1-100e2 in FIG. 46), a conductive film 110A to be word lines (gate electrodes) is deposited.

Subsequently, as shown in FIG. 52A (a cross-sectional view corresponding to that taken along the line 100d1-100d2 in FIG. 46) and FIG. 52A (a cross-sectional view corresponding to that taken along the line 100e1-100e2 in FIG. 46), after coating a resist film, a resist pattern 108 for forming the word lines is formed in the direction across the source/drain regions 105 spaced from each other by lithography.

Thereafter, as shown in FIG. 52C (a cross-sectional view corresponding to that taken along the line 100d1-100d2 in FIG. 46) and FIG. 52D (a cross-sectional view corresponding to that taken along the line 100e1-100e2 in FIG. 46), predetermined regions of the conductive film 110A are opened by dry etching using the resist pattern 108 as a mask to form the gate electrodes 110 and to expose the trap film 106 at the openings.

Next, as shown in FIG. 53A (a cross-sectional view corresponding to that taken along the line 100d1-100d2 in FIG. 46) and FIG. 53B (a cross-sectional view corresponding to that taken along the line 100e1-100e2 in FIG. 46), an insulating film is deposited to fill the openings between the word lines (the gate electrodes), and etching back is performed to remove the insulating film on the tops of the gate electrodes 110 with the insulating film between the gate electrodes 110 left to form buried insulating films 111. At this time point, as shown in FIG. 53B, the insulating film is etched and removed at the central parts of the bit line contact parts to expose the trap film 106.

Subsequently, as shown in FIG. 53C (a cross-sectional view corresponding to that taken along the line 100d1-100d2 in FIG. 46) and FIG. 53D (a cross-sectional view corresponding to that taken along the line 100e1-100e2 in FIG. 46), ion implantation of, for example, arsenic as an n-type impurity using a mask film 124 is performed on the bit line contact parts 113 to form high-concentration impurity diffusion regions 125 of n-type impurity diffusion layers.

Thereafter, as shown in FIG. 54A (a cross-sectional view corresponding to that taken along the line 100d1-100d2 in FIG. 46) and FIG. 54B (a cross-sectional view corresponding to that taken along the line 100e1-100e2 in FIG. 46), a metal film of cobalt, nickel, or the like is deposited on the entirety of the semiconductor substrate 101 by vacuum deposition or the like, and then, thermal treatment is performed. Thus, a metal silicide layer 123 is formed in the upper parts of the gate electrodes 110 and the upper parts of the high-concentration impurity diffusion layers 125. Then, an interlayer insulating film 112 is deposited on the entirety of the semiconductor substrate 101.

Next, as shown in FIG. 54C (a cross-sectional view corresponding to that taken along the line 100d1-100d2 in FIG. 46), bit line contacts 114 are formed.

Subsequently, as shown in FIG. 54D (a cross-sectional view corresponding to that taken along the line 100e1-100e2 in FIG. 46), the bit lines 115 are formed.

In the step shown in FIGS. 53A and 53B in the above manufacturing method, the trap film 106 in the bit line contact parts 113 may be removed incompletely and left partially in the section in FIG. 53B by low rate overetching to an extent that the height of the buried insulating films 111 between the gate electrodes 110 is secured sufficiently. This may cause incomplete formation of the high-concentration impurity diffusion layers 125 in the bit line contact parts 113 in a later step. Hence, electric connection may not secured between the high-concentration impurity diffusion layers 125 in the bit line contact parts 113 and the bit lines 115. As well, the metal silicide layer 23 on the high-concentration impurity diffusion layers 125 may be formed incompletely to cause unsecured electrical connection between the bit line contacts 114 and the metal silicide layer 123. As a result, the yield is lowered remarkably.

On the other hand, by excessively high rate overetching allowing complete removal of the trap film 106 in the step shown in FIGS. 53A and 53B, a plenty amount of the buried insulating films 111 between the gate electrodes 110 is removed, as shown in FIG. 55A (a cross-sectional view corresponding to that taken long the line 100d1-100d2 in FIG. 46) and FIG. 55B (a cross-sectional view corresponding to that taken along the line 100e1-100e2 in FIG. 46), to form remarkable projections and depression between the word lines. When the later steps progress with this state, as shown in FIG. 56A (a cross-sectional view corresponding to that taken long the line 100d1-100d2 in FIG. 46) and FIG. 56B (a cross-sectional view corresponding to that taken along the line 100e1-100e2 in FIG. 46), a void 126 may be formed between the gate electrodes 110 in depositing the interlayer insulating film 112 in the step shown in FIGS. 54A and 54B.

Accordingly, the etching condition must be controlled for optimizing the amounts of the trap film 106 to be removed and the filling insulating film 111 to be left. Therefore, the etching control itself is very difficult.

In further miniaturization of the bit contact parts 113 in the technique employing the self-aligned contact formation proposed in Japanese Unexamined Patent Application Publication 2001-127174, the following problems may be involved.

Application of a scheme for leaving the insulating films on the gate electrodes involves difficulty in metal silicidation after formation of the gate electrodes for reducing the resistance of the gate electrodes, and accordingly, it is necessary to employ for preparation a staked film of polysilicon and metal silicide, such as a tungsten silicide film as a material of the gate electrodes. However, miniaturization accompanies an increase in resistance rate of the metal silicide, with a result that silicide of cobalt or nickel must be used for employing especially fine wires. Hence, miniaturization in this scheme may be limited.

In addition, the semiconductor memory device in Japanese Unexamined Patent Application Publication 2001-127174 premises a SRAM (Static Random Access Memory), and the intervals of the contacts can be increased. However, in the case of a memory element in which the contacts are disposed in chain as in a nonvolatile semiconductor memory element, the contacts are disposed at narrow intervals. For this reason, the use of this technique may involve another problem of inviting a short-circuit between the contacts.

In view of the foregoing, the objective of the present invention is to provide a nonvolatile semiconductor memory device in which a trap film in bit line contact parts can be removed completely and the amount of buried insulating films between gate electrodes in a memory cell part can be secured sufficiently, and a manufacturing method thereof.

To attain the above objective, a semiconductor memory device in one example embodiment of the present invention includes, in a memory region: a plurality of bit line diffusion layers formed in upper part of a substrate and extending in a column direction; a plurality of word lines formed on the substrate and extending in a line direction; and a plurality of memory elements arranged in matrix and each including a pair of adjacent bit line diffusion layers, a gate insulating film interposed between the substrate and the word lines between the bit line diffusion layer pairs, and a gate electrode formed with part of a word line on the gate insulating film, wherein each of the plurality of bit line diffusion layers is divided in plural in the column direction, the plurality of bit line diffusion layers in respective columns are connected electrically to each other through bit line contact diffusion layers formed in upper part of the substrate, regions between adjacent word lines are filled with sidewall insulating films formed on the respective sides of the adjacent word lines, and among the sidewall insulating films formed at word lines adjacent to the bit line contact diffusion layers, sidewall insulating films formed on the sides of the bit line contact diffusion layers have a width smaller than those formed on the opposite sides of the bit line contact diffusion layers.

In device of the example embodiment of the present invention, the gate electrode is formed with a stacked film of a lower layer film in each of the plurality of memory elements and an upper layer film formed on the lower layer film and forming a word line, and the height of top surfaces of buried insulating films formed on the bit line diffusion layers and between the lower layer films is equal to that of top surfaces of the lower layer film in the line direction.

In device of the example embodiment of the present invention, the gate insulating film forming a memory element includes a trap film having a charge storing function.

In device of the example embodiment of the present invention, the gate insulating film is formed with a stacked film of a silicon oxide film, a silicon nitride film having a charge storing function, and a silicon oxide film, which are formed in this order from below.

In device of the example embodiment of the present invention, the gate electrode is formed with a stacked film of a floating gate electrode as the lower layer film having a charge storing function, an inter-electrode insulating film formed on the floating gate electrode, and a control gate electrode as the upper layer film formed on the inter-electrode insulating film.

In device of the example embodiment of the present invention, the bit line diffusion layers include a first impurity diffusion layer of a conductivity type opposite to a conductivity type of the substrate, and a second impurity diffusion layer of the same conductivity type as that of the substrate, the second impurity diffusion layer being formed around the first impurity diffusion layer.

In device of the example embodiment of the present invention, the first impurity diffusion layer has an impurity concentration higher than the second impurity diffusion layer.

In device of the example embodiment of the present invention, the gate electrode is made of polycrystalline silicon or amorphous silicon.

The device of example embodiment of the present invention further includes a metal silicide layer formed in upper part of the gate electrode.

In device of the example embodiment of the present invention, the gate electrode is formed with a metal film.

In device of the example embodiment of the present invention, at least the upper layer film of the upper layer film and the lower layer film of the gate electrode is formed with a metal film.

The device of example embodiment of the present invention further includes a metal silicide layer formed in upper parts of the bit line contact diffusion layers.

The device of example embodiment of the present invention further includes a logic circuit region including a peripheral transistor in a region other than the memory region in the substrate, wherein the peripheral transistor includes a gate electrode made of the same material as the gate electrode in the memory element.

A semiconductor memory device manufacturing method in a first example embodiment includes: (a) forming on a substrate a trap film having a charge storing function and a mask film in this order; (b) forming, after forming openings by selectively removing the mask film, a plurality of bit line diffusion layers extending in a column direction and divided in plural in respective columns by introducing an impurity into the substrate through the openings; (c) exposing, after filling the openings with a first buried insulating film after (b), the top surface of the mask film; (d) removing, after (c), the mask film, while removing upper part of the first buried insulating film; (e) forming, after (d), a conductive film on the substrate to cover the first buried insulating film; (f) selectively removing the conductive film to expose part of the top surface of the trap film and part of the top surface of the first buried insulating film, and to form a plurality of word lines of the conductive film extending in a line direction; (g) depositing, after (f), an insulating film on the substrate to cover the word lines, the exposed top surface of the trap film, and the exposed top surface of the first buried insulating film, and then performing etching back, thereby allowing sidewall insulating films formed with the insulating film remaining on the side surfaces of the word lines to form second buried insulating films buried between adjacent word lines; (h) performing, after (g), etching using a mask pattern having openings for exposing bit line contact diffusion layer formation regions dividing the plurality of bit line diffusion layers in the respective columns to reduce the thickness of sidewall insulating films formed on the sides of the bit line contact diffusion layers among sidewall insulating films formed on word lines arranged adjacent to the bit line contact diffusion layer formation regions, and to remove the trap film exposed in the bit line contact diffusion layer formation regions, thereby exposing the substrate; and (i) forming, after (h), bit line contact diffusion layers in the bit line contact diffusion layer formation regions by introducing an impurity to the exposed parts of the substrate.

In the method of the first example embodiment of the present invention, the conductive film is a film selected from the group consisting of a polycrystalline silicon film, an amorphous silicon film, a metal film, a stacked film of a polycrystalline silicon film and a silicide film, and a stacked film of an amorphous silicon film and a silicide film.

A semiconductor memory device manufacturing method in a second example embodiment includes: (a) forming on a substrate a trap film having a charge storing function, a first conductive film, and a mask film in this order; (b) forming, after forming openings by selectively removing the mask film and the first conductive film, a plurality of bit line diffusion layers extending in a column direction and divided in plural in respective columns by introducing an impurity into the substrate through the openings; (c) exposing, after filling the openings with a first buried insulating film after (b), the top surface of the mask film; (d) removing, after (c), the mask film to expose the top surface of the first conductive film, while removing the upper part of the first buried insulating film to equalize the height of the first buried insulating film to that of the first conductive film: (e) forming, after (d), a second conductive film on the semiconductor substrate to cover the first conductive film and the first buried insulating film of which the top surfaces are exposed; (f) selectively removing the first conductive film and the second conductive film to expose part of the top surface of the trap film and part of the top surface of the first buried insulating film and to form a plurality of word lines of the second conductive film extending in a line direction; (g) depositing, after (f), an insulating film on the substrate to cover the word lines, the exposed top surface of the trap film, and the exposed top surface of first buried insulating film, and then performing etching back, thereby allowing sidewall insulating films formed with the insulating film remaining on the side surfaces of the word lines to form second buried insulating films buried between adjacent word lines; (h) performing, after (g), etching using a mask pattern having openings for exposing bit line contact diffusion layer formation regions dividing the plurality of bit line diffusion layers in the respective columns to reduce the thickness of sidewall insulating films formed on the sides of the bit line contact diffusion layers among sidewall insulating films formed on word lines arranged adjacent to the bit line contact diffusion layer formation regions, and to remove the trap film exposed in the bit line contact diffusion layer formation regions, thereby exposing the substrate; and (i) forming, after (h), bit line contact diffusion layers in the bit line contact diffusion layer formation regions by introducing an impurity to the exposed parts of the substrate.

In the method of the second example embodiment of the present invention, the second conductive film is a film selected from the group consisting of a polycrystalline silicon film, an amorphous silicon film, a metal film, a stacked film of a polycrystalline silicon film and a silicide film, and a stacked film of an amorphous silicon film and a silicide film.

In the method of the first or second example embodiment of the present invention, (b) includes introducing the impurity into the substrate through the trap film with the trap film remaining on regions where the bit line diffusion layer are to be formed.

In the method of the first or second example embodiment of the present invention, (b) includes introducing the impurity directly into the substrate with the trap film on regions where the bit line diffusion layers are to be formed removed.

A semiconductor memory device manufacturing method in a third example embodiment includes: (a) forming on a substrate a tunneling film, a first conductive film, and a mask film in this order; (b) forming, after forming openings by selectively removing the mask film and the first conductive film, a plurality of bit line diffusion layers extending in a column direction and divided in plural in respective columns by introducing an impurity into the substrate through the openings; (c) exposing, after filling the openings with a first buried insulating film after (b), the top surface of the mask film; (d) removing, after (c), the mask film to expose the top surface of the first conductive film, while removing the upper part of the first buried insulating film to equalize the height of the first buried insulating film to that of the first conductive film; (e) forming, after (d), an inter-electrode insulating film and a second conductive film on the substrate in this order to cover the first conductive film and the first buried insulating film of which the top surfaces are exposed; (f) selectively removing the first conductive film, the inter-electrode insulating film, and the second conductive film to expose part of the top surface of the tunneling film and part of the top surface of the first buried insulating film, and to form a plurality of word lines formed with the second conductive film and extending in a line direction; (g) depositing, after (f), an insulating film on the substrate to cover the word lines, the exposed top surface of the tunneling film, and the top surface of the first buried insulating film, and then performing etching back, thereby allowing sidewall insulating films formed with the insulating film remaining on the side surfaces of the word lines to form second buried insulating films between adjacent word lines; (h) performing, after (g), etching using a mask pattern having openings for exposing bit line contact diffusion layer formation regions dividing the plurality of bit line diffusion layers in the respective columns to reduce the thickness of sidewall insulating films formed on the sides of the bit line contact diffusion layers among sidewall insulating films formed on word lines arranged adjacent to the bit line contact diffusion layer formation regions, and to remove the tunneling film exposed in the bit line contact diffusion layer formation regions, thereby exposing the substrate; and (i) forming, after (h), bit line contact diffusion layers in the bit line contact diffusion layer formation regions by introducing an impurity to the exposed parts of the substrate.

In the method of the third example embodiment of the present invention, the second conductive film is a film selected from the group consisting of a polycrystalline silicon film, an amorphous silicon film, a metal film, a stacked film of a polycrystalline silicon film and a silicide film, and a stacked film of an amorphous silicon film and a silicide film.

In the method of the third example embodiment of the present invention, (b) includes introducing the impurity into the substrate through the tunneling film with the tunneling film remaining on regions where the bit line diffusion layers are to be formed.

In the method of the third example embodiment of the present invention, (b) includes introducing the impurity directly into the substrate with the tunneling film on regions where the bit line diffusion layers are to be formed removed.

The method of any of the first to third example embodiments of the present invention further includes siliciding, after (i), the upper parts of the word lines and the upper parts of the bit line contact diffusion layers.

In the method of any of the first to third example embodiments of the present invention, in (g), the etching back is performed so that height difference between the word lines and the second buried insulating films is equal to or smaller than 100 nm.

A semiconductor memory device manufacturing method of a fourth example embodiment includes: (a) forming a trap film having a charge storing function in a memory element formation region and a logic circuit formation region formed in regions defined in a substrate; (b) removing the trap film on the logic circuit formation region; (c) forming, after (b), a gate insulating film on the logic circuit formation region; (d) forming a mask film on the trap film in the memory element formation region; (e) forming, after forming openings by selectively removing the mask film, a plurality of bit line diffusion layers extending in a column direction and divided in plural in respective columns in the memory element formation region by introducing an impurity into the substrate through the openings; (f) exposing, after filling the openings with a first buried insulating film, the top surface of the mask film in the memory element formation region; (g) removing, after (f), the mask film, while removing the upper part of the first buried insulating film in the memory element formation region; (h) forming, after (g), a conductive film to cover the first buried insulating film in the memory element formation region, and to cover the gate insulating film in the logic circuit formation region; (i) selectively removing the conductive film to expose part of the top surface of the trap film and part of the top surface of the first buried insulating film and to form a plurality of word lines extending in the line direction and formed with the conductive film in the memory element formation region, and to form gate electrodes formed with the conductive film in the logic circuit formation region; (j) depositing, after (i), an insulating film on the substrate to cover the word lines, the exposed top surface of the trap film, and the exposed top surface of the first buried insulating film in the memory element formation region, and to cover the gate electrodes in the logic circuit formation region, and then performing etching back, thereby allowing first sidewall insulating films formed with the insulating film remaining on the side surfaces of the word lines to form second buried insulating films buried between adjacent word lines in the memory element formation region, and to form second sidewall insulating films formed with the insulating film remaining on the side surfaces of the gate electrodes in the logic circuit formation region; (k) performing, after (j), etching back using a mask pattern having openings for exposing bit line contact diffusion layer formation regions dividing the plurality of bit line diffusion layers in the respective columns in the memory element formation region to reduce the thickness of the first sidewall insulating films formed on the sides of the bit line contact diffusion layers among the first sidewall insulating films formed on word lines arranged adjacent to the bit line contact diffusion layer formation regions, and to remove the trap film exposed in the bit line contact diffusion layer formation regions, thereby exposing the semiconductor substrate; and (l) forming, after (k), bit line contact diffusion layers in the bit line contact diffusion layer formation regions in the memory element formation region by introducing an impurity to the exposed part of the substrate.

A semiconductor memory device manufacturing method in a fifth example embodiment includes: (a) forming a trap film having a charge storing function in a memory element formation region and a logic circuit formation region formed in regions defined in a substrate; (b) removing the trap film on the logic circuit formation region; (c) forming, after (b), a gate insulating film on the logic circuit formation region; (d) forming a first conductive film on the trap film in the memory element formation region, and on the gate insulating film in the logic circuit formation region; (e) forming a mask film on the first conductive film in the memory element formation region; (f) forming, after forming openings by selectively removing the mask film and the first conductive film, a plurality of bit line diffusion layers extending in a column direction and divided in plural in respective columns in the memory element formation region by introducing an impurity into the substrate through the openings; (g) filling the openings with a first buried insulating film, and then exposing the top surface of the mask film in the first memory element formation region; (h) removing, after (g), the mask film to expose the top surface of the first conductive film, while removing part of the upper part of the first buried insulating film in the memory element formation region, thereby equalizing the height of the first buried insulating film to that of the first conductive film; (i) forming, after (h), a second conductive film to cover the first conductive film and the first buried insulating film of which the top surfaces are exposed in the memory element formation region, and to cover the first conductive film in the logic circuit formation region; (j) selectively removing the second conductive film to expose part of the top surface of the trap film and part of the top surface of the first buried insulating film and to form a plurality of word lines extending in the line direction and formed with the second conductive film in the memory element formation region, and to form gate electrodes formed with the first conductive film and the second conductive film in the logic circuit formation region; (k) depositing, after (j), an insulating film on the substrate to cover the word lines, the exposed top surface of the trap film, and the exposed top surface of the first buried insulating film in the memory element formation region, and to cover the gate electrodes in the logic circuit formation region, and then performing etching back, thereby allowing first sidewall insulating films formed with the insulating film remaining on the side surfaces of the word lines to form second buried insulating films buried between adjacent word lines in the memory element formation region, and to form second sidewall insulating films formed with the insulating film remaining on the side surfaces of the gate electrodes in the logic circuit formation region; (l) performing, after (k), etching back using a mask pattern having openings for exposing bit line contact diffusion layer formation regions dividing the plurality of bit line diffusion layers in the respective columns in the memory element formation region to reduce the thickness of the first sidewall insulating films formed on the sides of the bit line contact diffusion layers among the first sidewall insulating films formed on word lines arranged adjacent to the bit line contact diffusion layer formation regions, and to remove the trap film exposed in the bit line contact diffusion layer formation regions, thereby exposing the semiconductor substrate; and (m) forming, after (l), bit line contact diffusion layers in the bit line contact diffusion layer formation regions in the memory element formation region by introducing an impurity to the exposed part of the substrate.

A semiconductor memory device manufacturing method in a sixth example embodiment includes: (a) forming a tunneling film having a charge storing function in a memory element formation region and a logic circuit formation region formed in regions defined in a substrate; (b) removing the tunneling film on the logic circuit formation region; (c) forming, after (b), a gate insulating film on the logic circuit formation region; (d) forming a first conductive film on the tunneling film in the memory element formation region, and the gate insulating film in the logic circuit formation region; (e) forming a mask film on the first conductive film in the memory element formation region; (f) forming, after forming openings by selectively removing the mask film and the first conductive film, a plurality of bit line diffusion layers extending in a column direction and divided in plural in respective columns in the memory element formation region by introducing an impurity into the substrate through the openings; (g) filling the openings with a first buried insulating film, and then exposing the top surface of the mask film in the memory element formation region; (h) removing, after (g), the mask film to expose the top surface of the first conductive film, while removing part of the upper part of the first buried insulating film in the memory element formation region, thereby equalizing the height of the first buried insulating film to that of the first conductive film; (i) forming, after (h), an inter-electrode insulating film in the memory element formation region and the logic circuit formation region, and then removing the inter-electrode insulating film on the logic circuit formation region; (j) forming, after (i), a second conductive film to cover the inter-electrode insulating film in the memory element formation region, and to cover the first conductive film in the logic circuit formation region; (k) selectively removing the second conductive film to expose part of the top surface of the tunneling film and part of the top surface of the first buried insulating film and to form a plurality of word lines extending in the line direction and formed with the second conductive film in the memory element formation region, and to form gate electrodes made of the first conductive film and the second conductive film in the logic circuit formation region; (l) depositing, after (k), an insulating film on the substrate to cover the word lines, the exposed top surface of the tunneling film, and the exposed top surface of the first buried insulating film in the memory element formation region, and to cover the gate electrodes in the logic circuit formation region, and then performing etching back, thereby allowing first sidewall insulating films formed with the insulating film remaining on the side surfaces of the word lines to form second buried insulating films buried between adjacent word lines in the memory element formation region, and to form second sidewall insulating films formed with the insulating film remaining on the side surfaces of the gate electrodes in the logic circuit formation region; (m) performing, after (l), etching back using a mask pattern having openings for exposing bit line contact diffusion layer formation regions dividing the plurality of bit line diffusion layers in the respective columns in the memory element formation region to reduce the thickness of the first sidewall insulating films formed on the sides of the bit line contact diffusion layers among the first sidewall insulating films formed on word lines arranged adjacent to the bit line contact diffusion layer formation regions, and to remove the tunneling film exposed in the bit line contact diffusion layer formation regions, thereby exposing the semiconductor substrate; and (n) forming, after (m), bit line contact diffusion layers in the bit line contact diffusion layer formation regions in the memory element formation region by introducing an impurity to the exposed part of the substrate.

According to the nonvolatile semiconductor memory device and the manufacturing method thereof in the above example embodiments of the present invention, the trap film in the bit line contact parts can be removed completely, while the amount of the buried insulating films between the gate electrodes in the memory cell part can be secured sufficiently. As a result, even when the bit line contact parts are miniaturized, a nonvolatile semiconductor memory device can be realized in which the electric connection between the bit line diffusion layers and the bit lines thereabove can be secured favorably and no void is formed in the upper part of the memory element.

### BRIEF DESCRIPTION OF THE DRAWINGS

FIG. 1 is a plan view of a nonvolatile semiconductor memory device in accordance with a first example embodiment of the present invention.

FIGS. 2A to 2E are cross-sectional views of the nonvolatile semiconductor memory device in accordance with the first example embodiment of the present invention.

FIGS. 3A to 3E are cross-sectional views showing manufacturing steps of the nonvolatile semiconductor memory device in accordance with the first example embodiment of the present invention.

FIGS. 4A to 4D are cross-sectional views showing manufacturing steps of the nonvolatile semiconductor memory device in accordance with the first example embodiment of the present invention.

FIGS. 5A to 5D are cross-sectional views showing manufacturing steps of the nonvolatile semiconductor memory device in accordance with the first example embodiment of the present invention.

FIGS. 6A to 6D are cross-sectional views showing manufacturing steps of the nonvolatile semiconductor memory device in accordance with the first example embodiment of the present invention.

FIGS. 7A to 7D are cross-sectional views showing manufacturing steps of the nonvolatile semiconductor memory device in accordance with the first example embodiment of the present invention.

FIGS. 8A to 8D are cross-sectional views showing manufacturing steps of the nonvolatile semiconductor memory device in accordance with the first example embodiment of the present invention.

FIGS. 9A to 9D are cross-sectional views showing manufacturing steps of the nonvolatile semiconductor memory device in accordance with the first example embodiment of the present invention.

FIGS. 10A to 10E are cross-sectional views showing a nonvolatile semiconductor memory device in accordance with a second example embodiment of the present invention.

FIGS. 11A to 11D are cross-sectional views showing manufacturing steps of the nonvolatile semiconductor memory device in accordance with the second example embodiment of the present invention.

FIGS. 12A to 12D are cross-sectional views showing manufacturing steps of the nonvolatile semiconductor memory device in accordance with the second example embodiment of the present invention.

FIGS. 13A to 13D are cross-sectional views showing manufacturing steps of the nonvolatile semiconductor memory device in accordance with the second example embodiment of the present invention.

FIGS. 14A to 14D are cross-sectional views showing manufacturing steps of the nonvolatile semiconductor memory device in accordance with the second example embodiment of the present invention.

FIGS. 15A to 15D are cross-sectional views showing manufacturing steps of the nonvolatile semiconductor memory device in accordance with the second example embodiment of the present invention.

FIGS. 16A to 16D are cross-sectional views showing manufacturing steps of the nonvolatile semiconductor memory device in accordance with the second example embodiment of the present invention.

FIGS. 17A and 17B are cross-sectional views showing manufacturing steps of the nonvolatile semiconductor memory device in accordance with the second example embodiment of the present invention.

FIGS. 18A to 18E are cross-sectional views showing a nonvolatile semiconductor memory device in accordance with a third example embodiment of the present invention.

FIGS. 19A to 19D are cross-sectional views showing manufacturing steps of the nonvolatile semiconductor memory device in accordance with the third example embodiment of the present invention.

FIGS. 20A to 20D are cross-sectional views showing manufacturing steps of the nonvolatile semiconductor memory device in accordance with the third example embodiment of the present invention.

FIGS. 21A to 21D are cross-sectional views showing manufacturing steps of the nonvolatile semiconductor memory device in accordance with the third example embodiment of the present invention.

FIGS. 22A to 22D are cross-sectional views showing manufacturing steps of the nonvolatile semiconductor memory device in accordance with the third example embodiment of the present invention.

FIGS. 23A to 23D are cross-sectional views showing manufacturing steps of the nonvolatile semiconductor memory device in accordance with the third example embodiment of the present invention.

FIGS. 24A to 24D are cross-sectional views showing manufacturing steps of the nonvolatile semiconductor memory device in accordance with the third example embodiment of the present invention.

FIGS. 25A and 25B are cross-sectional views showing the nonvolatile semiconductor memory device in accordance with the third example embodiment of the present invention.

FIGS. 26A to 26E are cross-sectional views showing manufacturing steps of a nonvolatile semiconductor memory device in accordance with a fourth example embodiment of the present invention.

FIGS. 27A to 27E are cross-sectional views showing manufacturing steps of the nonvolatile semiconductor memory device in accordance with the fourth example embodiment of the present invention.

FIGS. 28A to 28D are cross-sectional views showing manufacturing steps of the nonvolatile semiconductor memory device in accordance with the fourth example embodiment of the present invention.

FIGS. 29A to 29D are cross-sectional views showing manufacturing steps of the nonvolatile semiconductor memory device in accordance with the fourth example embodiment of the present invention.

FIGS. 30A to 30E are cross-sectional views showing manufacturing steps of a nonvolatile semiconductor memory device in accordance with a fifth example embodiment of the present invention.

FIGS. 31A to 31E are cross-sectional views showing manufacturing steps of the nonvolatile semiconductor memory device in accordance with the fifth example embodiment of the present invention.

FIGS. 32A to 32D are cross-sectional views showing manufacturing steps of the nonvolatile semiconductor memory device in accordance with the fifth example embodiment of the present invention.

FIGS. 33A to 33D are cross-sectional views showing manufacturing steps of the nonvolatile semiconductor memory device in accordance with the fifth example embodiment of the present invention.

FIGS. 34A to 34E are cross-sectional views showing manufacturing steps of a nonvolatile semiconductor memory device in accordance with a sixth example embodiment of the present invention.

FIGS. 35A to 35E are cross-sectional views showing manufacturing steps of the nonvolatile semiconductor memory device in accordance with the sixth example embodiment of the present invention.

FIGS. 36A to 36D are cross-sectional views showing manufacturing steps of the nonvolatile semiconductor memory device in accordance with the sixth example embodiment of the present invention.

FIGS. 37A to 37D are cross-sectional views showing manufacturing steps of the nonvolatile semiconductor memory device in accordance with the sixth example embodiment of the present invention.

FIG. 38 is a plan view showing a conventional nonvolatile semiconductor memory device.

FIGS. 39A to 39E are cross-sectional views showing the conventional nonvolatile semiconductor memory device.

FIGS. 40A to 40E are cross-sectional views showing manufacturing steps of the conventional nonvolatile semiconductor memory device.

FIGS. 41A to 41E are cross-sectional views showing manufacturing steps of the conventional nonvolatile semiconductor memory device.

FIGS. 42A to 42D are cross-sectional views showing manufacturing steps of the conventional nonvolatile semiconductor memory device.

FIGS. 43A to 43D are cross-sectional views showing manufacturing steps of the conventional nonvolatile semiconductor memory device.

FIGS. 44A to 44D are cross-sectional views showing manufacturing steps of the conventional nonvolatile semiconductor memory device.

FIGS. 45A and 45B are cross-sectional views showing manufacturing steps of the conventional nonvolatile semiconductor memory device.

FIG. 46 is a plan view showing another conventional nonvolatile semiconductor memory device.

FIGS. 47A to 47D are cross-sectional views showing the conventional nonvolatile semiconductor memory device.

FIGS. 48A and 48B are cross-sectional views showing manufacturing steps of the conventional nonvolatile semiconductor memory device.

FIGS. 49A to 49E are cross-sectional views showing manufacturing steps of the conventional nonvolatile semiconductor memory device.

FIGS. 50A to 50D are cross-sectional views showing manufacturing steps of the conventional nonvolatile semiconductor memory device.

FIGS. 51A to 51D are cross-sectional views showing manufacturing steps of the conventional nonvolatile semiconductor memory device.

FIGS. 52A to 52D are cross-sectional views showing manufacturing steps of the conventional nonvolatile semiconductor memory device.

FIGS. 53A to 53D are cross-sectional views showing manufacturing steps of the conventional nonvolatile semiconductor memory device.

FIGS. 54A to 54D are cross-sectional views showing manufacturing steps of the conventional nonvolatile semiconductor memory device.

FIGS. 55A and 55B are cross-sectional views showing manufacturing steps of the conventional nonvolatile semiconductor memory device.

FIGS. 56A and 56B are cross-sectional views showing manufacturing steps of the conventional nonvolatile semiconductor memory device.

### DETAILED DESCRIPTION

### First Example Embodiment

A first example embodiment of the present invention will be described with reference to the drawings.

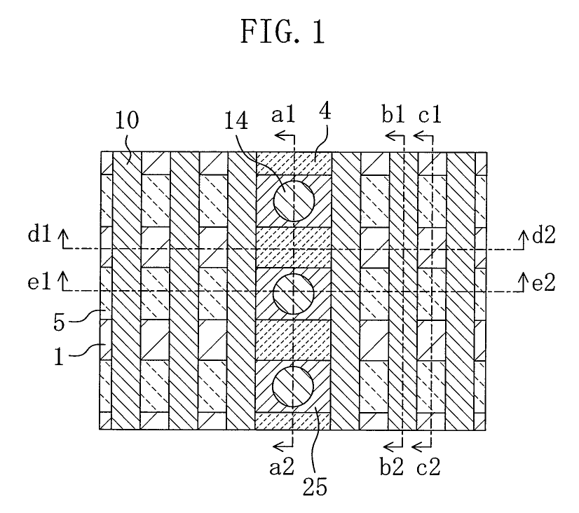

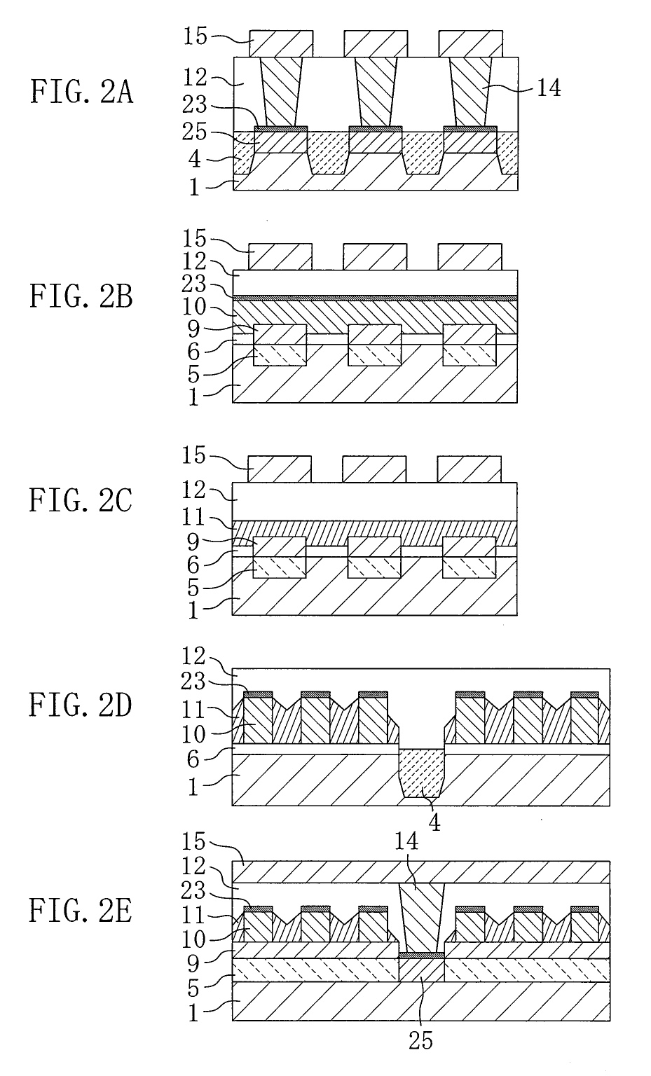

FIG. 1 is a plan view of a nonvolatile semiconductor memory device in accordance with the first example embodiment of the present invention. FIG. 2A is a cross-sectional view taken along the line a1-a2 in FIG. 1. FIG. 2B is a cross-sectional view taken along the line b1-b2 in FIG. 1. FIG. 2C is a cross-sectional view taken along the line c1-c2 in FIG. 1. FIG. 2D is a cross-sectional view taken along the line d1-d2 in FIG. 1. FIG. 2E is a cross-sectional view taken along the line e1-e2 in FIG. 1.

As shown in FIG. 1, a plurality of isolation regions 4 are formed by STI (shallow trench isolation) in the upper part of a semiconductor substrate 1 made of, for example, silicon. As shown in FIGS. 1, 2A, and 2B, source/drain regions 5 formed with a plurality of n-type impurity diffusion layers are formed in the upper part of the semiconductor substrate 1 at intervals. As shown in FIG. 1, high-concentration impurity diffusion layers 25 in bit line contact parts 13 connected to the source/drain regions 5 are isolated by the isolation regions 4.

As shown in FIGS. 2B and 2C, buried oxide films 9 as buried bit lines are formed on the source/drain regions 5. A trap film 6 is formed on the active regions between the source/drain regions 5. The trap film 6 is formed with a stacked film of, for example, silicon oxide (SiO₂), silicon nitride (SiN), and silicon oxide (SiO₂), which is generally called an ONO (oxide-nitride-oxide) film, and has a charge capturing site. On the trap film 6, gate electrodes 10 as word lines are formed across the buried bit line oxide films 9. The gate electrodes 10 are made of polycrystalline silicon with which phosphorous, for example, is introduced as an n-type impurity. The source/drain regions 5 are connected to the high-concentration impurity diffusion layer regions 25 formed in the bit line contact parts 13, as shown in FIG. 2E. The high-concentration impurity diffusion layer regions 25 are connected to contacts 14 to be connected to bit lines 15 made of metal, as shown in FIG. 1 and FIG. 2E.

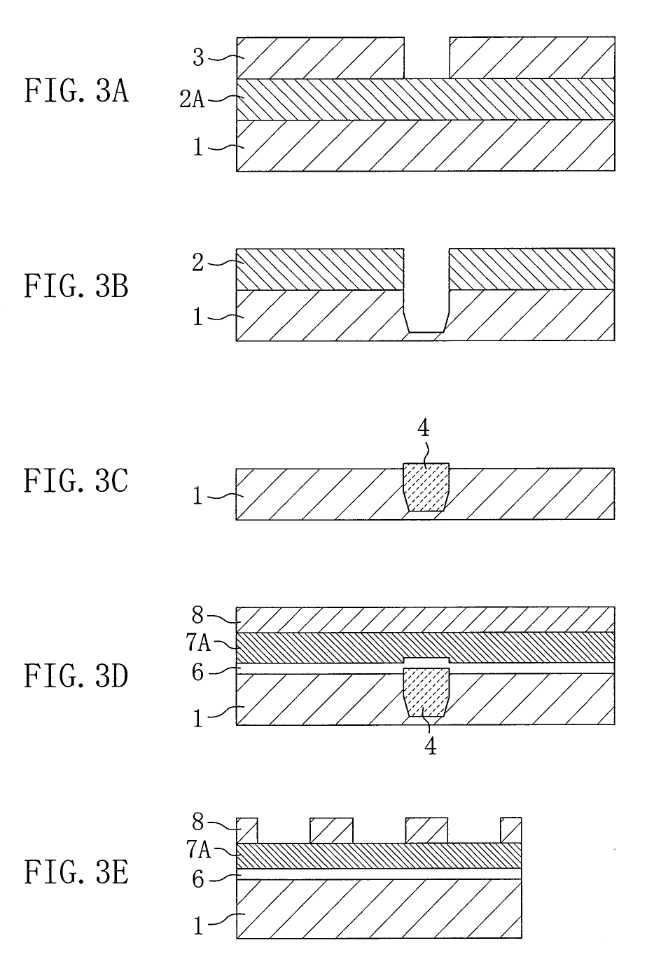

Description will be given below of a manufacturing method of the nonvolatile semiconductor memory device thus structured with reference to FIG. 3 to FIG. 9. The following description refers to cross-sectional views showing respective key points of the manufacturing steps.

First referring to FIG. 3A (a cross-sectional view corresponding to that taken along the line d1-d2 in FIG. 1), a mask formation film 2A of silicon nitride with a thickness of, for example, about 80 nm to 300 nm is formed on the principal surface of the semiconductor substrate 1 made of silicon. Then, a resist film 3 is deposited, and openings are formed by photolithography.

Next, as shown in FIG. 3B (a cross-sectional view corresponding to that taken along the line d1-d2 in FIG. 1), the mask formation film 2A below the resist openings is etched to form a mask film 2 having openings. After removing the resist film 3, the semiconductor substrate 1 below the openings of the mask film 2 is etched to form trenches.

Subsequently, as shown in FIG. 3C (a cross-sectional view corresponding to that taken along the line d1-d2 in FIG. 1), an insulating film of silicon oxide or the like is filled in the trenches, and the silicon oxide thus filled is planarized by CMP (chemical mechanical polishing) to form isolation regions 4 by STI or the like. The height of the surfaces of the isolation regions 4 is equal to that of the mask film 2 initially by planarization by CMP, and is therefore adjusted not to be lower than the surface of the semiconductor substrate 1 by wet etching or the like for preparation. This height adjustment is performed for facilitating the later etching process, and is employed usually.

Thereafter, as shown in FIG. 3D (a cross-sectional view corresponding to that taken along the line d1-d2 in FIG. 1), a trap film 6 with a thickness of 20 nm formed with an ONO film and having a charge capturing site is deposited on the entirety of the semiconductor substrate 1. Then, a mask formation film 7A of silicon nitride with a thickness of about 50 nm to 200 nm is deposited by chemical vapor deposition (CVD), for example, and a resist film 8 is coated on the mask formation film 7A.

Next, as shown in FIG. 3E (a cross-sectional view corresponding to that taken along the line b1-b2 in FIG. 1), a resist pattern 8 of the resist film 8 having openings for forming the source/drain regions 5 is formed by lithography. The openings have a width of 100 nm, which is the width of regions to be source/drain regions 5, and corresponds to the width of the bit line diffusion layers. Referring to the width of the resist, which is 150 nm, it corresponds to the channel width where memory cell transistors are formed.

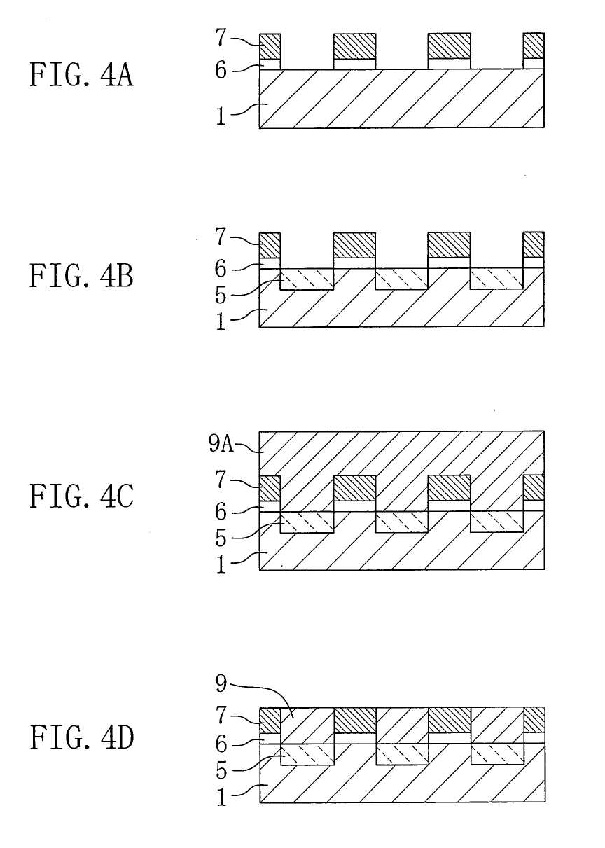

Subsequently, as shown in FIG. 4A (a cross-sectional view corresponding to that taken along the line b1-b2 in FIG. 1), dry etching using the resist pattern 8 as a mask is performed on the mask formation film 7A to form, from the mask formation film 7A, a mask film 7 having openings for forming the source/drain regions 5. Then, the trap film 6 below the openings of the patterned mask film 7 is removed. Alternatively, the trap film 6, which is thin, may not be removed for use as a protection film for ion implantation.

Thereafter, as shown in FIG. 4B (a cross-sectional view corresponding to that taken along the line b1-b2 in FIG. 1), ion implantation of, for example, arsenic as an n-type impurity is performed using the mask film 7 one time or two or more times under implantation conditions of 5 keV to 200 keV acceleration energy and 1×10¹⁴ cm⁻² to 1×10¹⁷ cm⁻² dosage to form the source/drain regions 5 formed with n-type impurity diffusion layers. The source/drain regions 5 function as bit line diffusion layers 5.

Next, as shown in FIG. 4C (a cross-sectional view corresponding to that taken along the line b1-b2 in FIG. 1), a silicon oxide film 9A to be buried insulating films is deposited in the openings of the mask film 7 by high density plasma chemical vapor deposition (HDPCVD), low pressure chemical vapor deposition (LPCVD), or the like, for example.

Subsequently, as shown in FIG. 4D (a cross-sectional view corresponding to that taken along the line b1-b2 in FIG. 1), the silicon oxide film 9A other than its part filled in the openings of the mask film 7 is selectively removed by CMP or etching back.

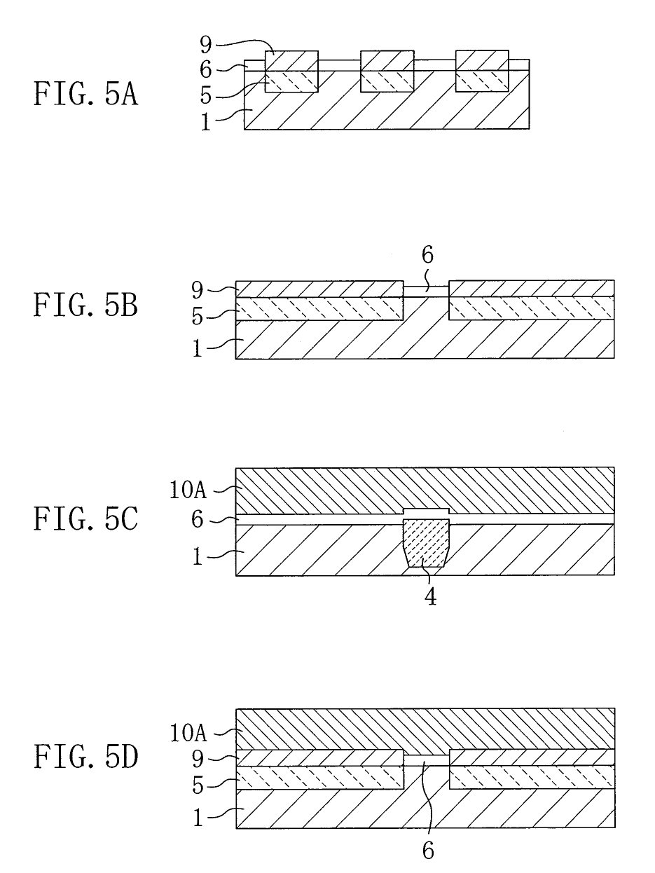

Next, as shown in FIG. 5A (a cross-sectional view corresponding to that taken along the line b1-b2 in FIG. 1) and FIG. 5B (a cross-sectional view corresponding to that taken along the line e1-e2 in FIG. 1), only the mask film 7 is removed selectively by wet etching or etching back to expose the trap film 6 and to form the buried bit line oxide films 9. Herein, the height of the buried bit line oxide films 9 from the semiconductor substrate 101 is adjusted to be approximately 50 nm by wet etching or etching back before or after selective removal of the mask film 7. This height adjustment is performed for facilitating the later etching process, similarly to the height adjustment for the isolation regions.

Thereafter, as shown in FIG. 5C (a cross-sectional view corresponding to that taken along the line d1-d2 in FIG. 1) and FIG. 5D (a cross-sectional view corresponding to that taken along the line e1-e2 in FIG. 1), an n-type impurity doped polycrystalline silicon film 10A with which phosphorous of 1×10¹⁸ cm⁻³ to 1×10²² cm⁻³ is doped is deposited on the trap film 6 and the buried bit line oxide films 9 by LPCVD, for example.

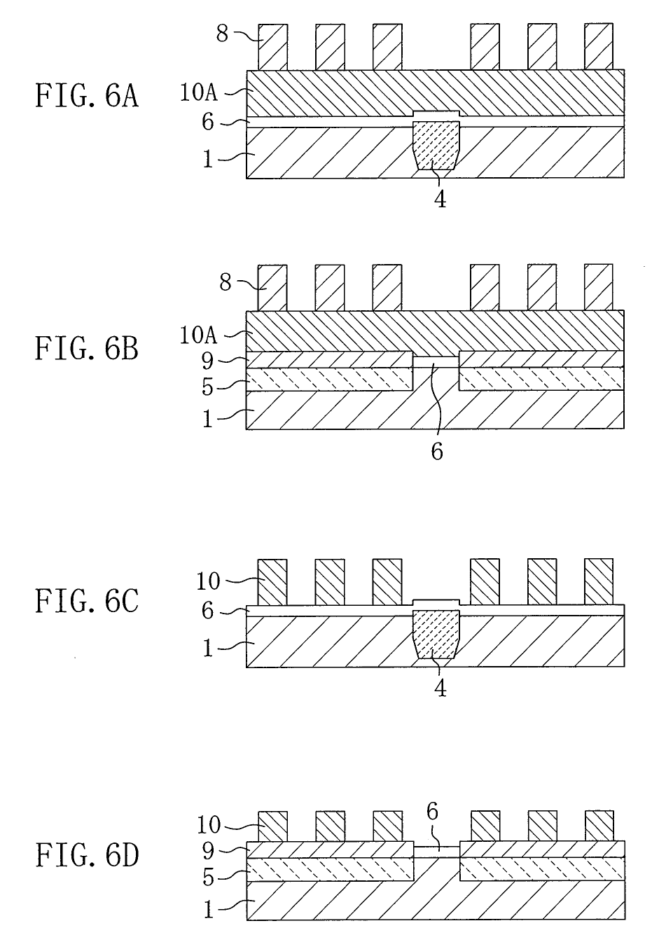

Next, as shown in FIG. 6A (a cross-sectional view corresponding to that taken along the line d1-d2 in FIG. 1) and FIG. 6B (a cross-sectional view corresponding to that taken along the line e1-e2 in FIG. 1), after coating a resist film, a resist pattern 8 for forming word lines is formed by lithography in the direction across the source/drain regions 5 spaced from each other.

Subsequently, as shown in FIG. 6C (a cross-sectional view corresponding to that taken along the line d1-d2 in FIG. 1) and FIG. 6D (a cross-sectional view corresponding to that taken along the line e1-e2 in FIG. 1), predetermined regions of the polycrystalline silicon film 10A are opened by dry etching using the resist pattern 8 as a mask to form the gate electrodes 10, and to expose the trap films 6 in the openings thus formed. In FIGS. 6C and 6D, the gate electrodes 10 are formed so that sidewalls thereof have an angle of approximately 90±1° relative to the substrate plane of the semiconductor substrate 1. Alternatively, the upper parts of the sidewalls may be tapered or rounded at an angle of about 84°.

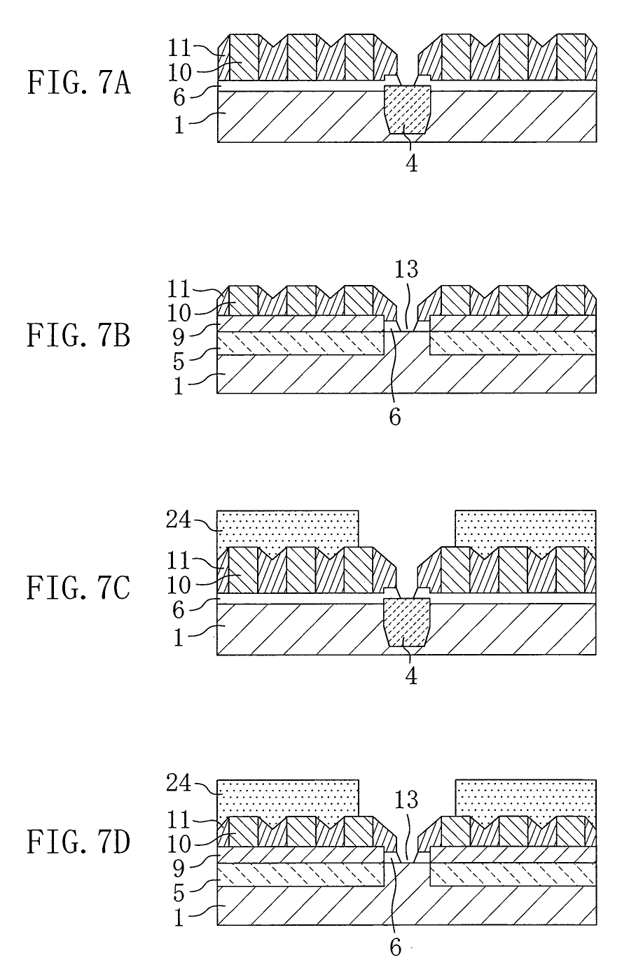

Thereafter, as shown in FIG. 7A (a cross-sectional view corresponding to that taken along the line d1-d2 in FIG. 1) and FIG. 7B (a cross-sectional view corresponding to that taken along the line e1-e2 in FIG. 1), after removing the resist pattern 8, an insulating film of silicon oxide or silicon nitride is deposited by, for example, LPCVD so as to fill the openings between the gate electrodes 10. Etching back is then performed to remove the insulating film on the tops of the gate electrodes 10 with the insulating film (sidewall insulating films 11) left between the gate electrodes 10, and to remove part of the insulating film and part of the trap film 6 below the insulating film in the bit line contact parts 13.

Herein, the etching rate for the insulating film is set so as to correspond to the time required for removing only the insulating film on the tops of the gate electrodes 10 (corresponding to the thickness of the insulating film). This may cause substantially no removal of the sidewall insulating films 11 filled between the gate electrodes 10, thereby forming ignorable projections and depressions on the memory cells. A desirable etching rate is preferably set by detecting the end point at the time point when the top surfaces of the gate electrodes 10 are exposed by luminance intensity variation or the like. Preferably, an appropriate amount of overetching is performed so as to remove part of the insulating film and part of the trap film 6 below the insulating film on the bit line contacts after exposure of the top surfaces of the gate electrodes 10. Referring to one specific example, detection of the etching end point and overetching are set so that height difference between the top surfaces of the gate electrodes 10 and the top surfaces of the sidewall insulating films 11 filled between the gate electrodes 10 is within 100 nm. With a value within this range, no void may be formed in forming an interlayer insulating film in a later step.

Next, as shown in FIG. 7C (a cross-sectional view corresponding to that taken along the line d1-d2 in FIG. 1) and FIG. 7D (a cross-sectional view corresponding to that taken along the line e1-e2 in FIG. 1), a resist pattern 24 is formed for selectively exposing the sidewall insulating films 11 and the trap film 6 of the boundary word lines closest to the bit line contact regions.

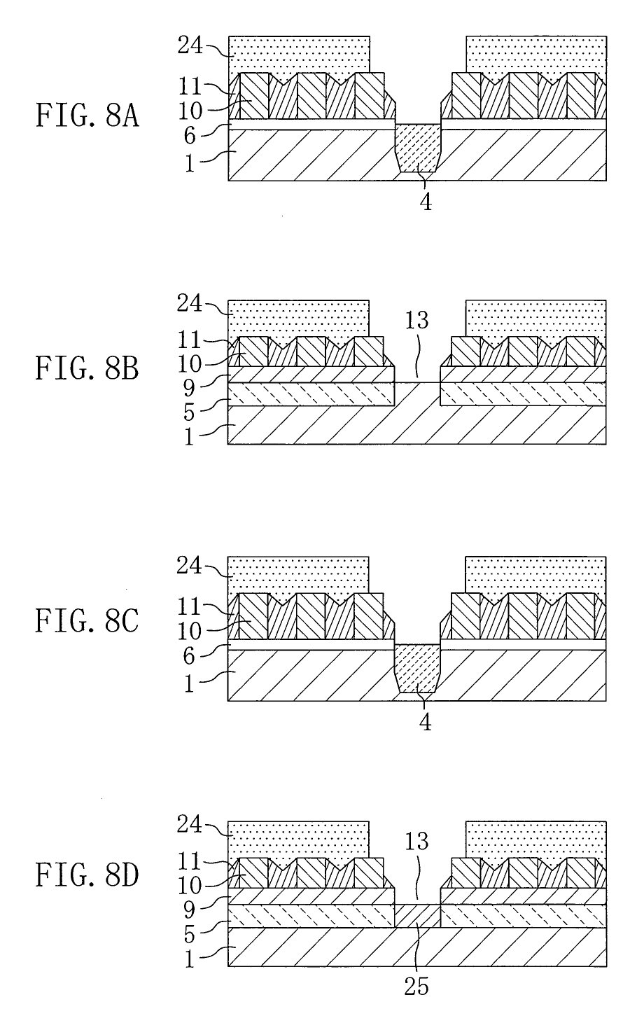

Subsequently, as shown in FIG. 8A (a cross-sectional view corresponding to that taken along the line d1-d2 in FIG. 1) and FIG. 8B (a cross-sectional view corresponding to that taken along the line e1-e2 in FIG. 1), by dry etching, the trap film 6 in the openings of the resist pattern 24 is removed, and part of the sidewall insulating films 11 of the boundary word lines is etched. By this step, the sidewall insulating films 11 of the boundary word lines are processed so as to decrease in width as the etching for removing the trap film 6 progresses, in other words, so as to expand the opening regions of the semiconductor substrate 1 in the openings.

Thereafter, as shown in FIG. 8C (a cross-sectional view corresponding to that taken along the line d1-d2 in FIG. 1) and FIG. 8D (a cross-sectional view corresponding to that taken along the line e1-e2 in FIG. 1), ion implantation of, for example, arsenic as an n-type impurity is performed one time or two or more times under implantation conditions of 5 keV to 200 keV acceleration energy and 1×10¹⁴ cm⁻² to 1×10¹⁷ cm⁻² dosage to form the high-concentration impurity diffusion layers 25 of n-type impurity diffusion layers in the bit line contact regions. The high-concentration impurity diffusion layers 25 are electrically connected to the source/drain regions 5 formed below the buried bit line oxide films 9.

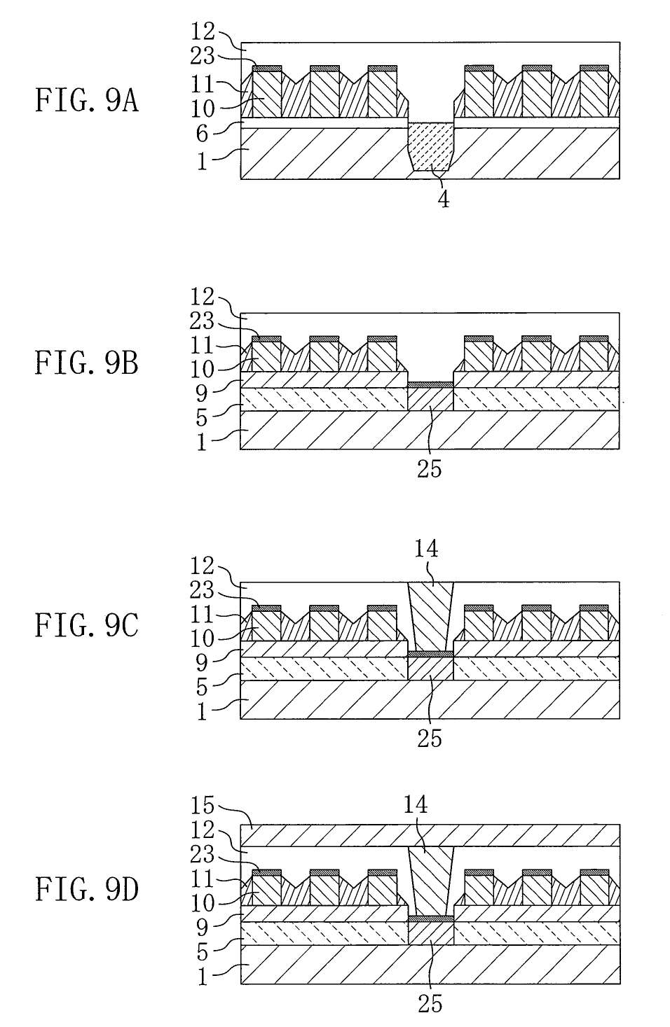

Next, as shown in FIG. 9A (a cross-sectional view corresponding to that taken along the line d1-d2 in FIG. 1) and FIG. 9B (a cross-sectional view corresponding to that taken along the line e1-e2 in FIG. 1), after removing the resist pattern 24, a metal film of cobalt, nickel, or the like is deposited on the entirety of the semiconductor substrate 1 by, for example, vacuum deposition, or the like, and thermal treatment is performed. Thus, the meal silicide layer 23 is formed in the upper parts of the gate electrodes 10 and the upper parts of the bit line contact parts 13. Then, an insulating film of silicon oxide is deposited entirely by HDPCVD, atmospheric-pressure chemical vapor deposition (APCVD), plasma-enhanced chemical-vapor deposition (PECVD), or the like, and the resultant surface is planarized by, for example, CMP, dry etching back, or the like to form an interlayer insulating film 12.

Subsequently, as shown in FIG. 9C (a cross-sectional view corresponding to that taken along the line e1-e2 in FIG. 1), connection holes are formed to expose the metal silicide layer 23 on the high-concentration impurity diffusion layers 25 in the bit line contact regions, and a conductive film formed with a single layer or stacked metal film is deposited entirely on the interlayer insulating film 12 to fill the connection holes, thereby forming the contacts 14. Examples of the metal of the conductive film include tungsten, a tungsten compound, titanium, a titanium compound, such as titanium nitride, and the like.

Thereafter, as shown in FIG. 9D (a cross-sectional view corresponding to that taken along the line e1-e2 in FIG. 1), the deposited conductive film is patterned so that the high-concentration impurity diffusion layers 25 in the bit line contact regions are connected to each other to form the bit lines 15 from the conductive film.

As described above, according to the present example embodiment, the insulating films 11 between the gate electrodes 10 in the memory cell part is hardly removed, and therefore, projections and depressions formed there can be ignorable. In turn, no void may be formed in the memory cell part in forming the interlayer insulating film 12. The trap film 6 in the bit line contact parts 13 is selectively removed to achieve ensured electrical connection to the high-concentration impurity diffusion layers 25 in forming the contacts 14. Accordingly, in the present example embodiment, even if the width of the bit line contact regions is narrower than that in the conventional technique, no void may be formed in the interlayer insulating film 12 between the gate electrodes 10, and the contacts 14 can be connected securely to the high-concentration impurity diffusion layers 25. Hence, the manufacturing yield of a miniaturized semiconductor device can be increased.

In the present example embodiment, the mask film 2 for forming the source/drain regions 5 is made of silicon nitride. Rather than silicon nitride, an insulating film made of a silicon compound, such as silicon oxide or the like may be used. In forming the source/drain regions 5, a resist material may be used as a mask without using the mask film made of a silicon compound.

As the trap film 6 having a charge capturing site, a stacked film of silicon oxide, silicon nitride, and silicon oxide is employed in the present example embodiment. In place of this, any of the following films may be employed: a single layer film of silicon oxinitride; a single layer film of silicon nitride; a stacked film of silicon oxide and silicon nitride deposited in this order on the semiconductor substrate; and a stacked film of silicon oxide, silicon nitride, silicon oxide, silicon nitride, and silicon oxide deposited in this order thereon.

In the present example embodiment, the film thickness of the trap film 6 is set at 20 nm as one example. The film thickness thereof may be adjusted appropriately within the range between 10 nm and 30 nm so as to optimize the transistor characteristics.

In the present example embodiment, the height of the buried oxide films 9 is set at 50 nm as an example. The height thereof may be adjusted appropriately within the range between 20 nm and 100 nm so as to optimize the leakage current between the gate electrodes and the sources or the drains.

Further, in the present example embodiment, the width of the n-type impurity diffusion layers is set at 100 nm as an example. It may be adjusted within the range between 50 nm and 300 nm so as to optimize the transistor characteristics.

The resist material is used as the mask for dry etching the polycrystalline silicon film 10A in the present example embodiment. It may be inferred that higher etching selectivity is required in a process for higher integration. In such a case, a mask of a silicon oxide film or a silicon nitride film, or a mask of a stacked film of them and the resist material may be employed.

The polycrystalline silicon film 10A forming the gate electrodes 10 is deposited as doped polysilicon in the present example embodiment. Alternatively, an impurity may be doped after non-doped polysilicon with which no impurity is doped is deposited. The polycrystalline silicon film is only one example as a material of the gate electrodes, and may be replaced by a single layer film or a stacked film of any of polycrystalline silicon, amorphous silicon, high-melting point metal having a melting point equal to or higher than 600° C, such as tantalum, titanium, and the like, a metal compound, and metal silicide. Alternatively, the polycrystalline silicon film 10A forming the word lines 10 may be silicided by metal.

In the present example embodiment, a silicon oxide film and a silicon nitride film by CVD are used as an example of, but does not limit films buried and filled between the word lines 10. Any insulating film is applicable which is excellent in step coverage and which can be formed by film formation using no plasma. However, a film requiring high temperature baking in a later step, such as atmospheric pressure CVD is difficult in handling, and highly accurate film formation condition and baking condition must be set.

A memory element of which source/drain regions 5 are n-type is referred to in the present example embodiment. The memory element may be p-type, of course.

In the present example embodiment, the side and bottom surfaces of the n-type impurity diffusion layers forming the source/drain regions 5 may be covered with a p-type impurity diffusion layer having an impurity concentration lower than that of the n-type impurity diffusion layers. With this configuration, the p-type impurity diffusion layer can suppress the short channel effect caused due to impurity diffusion in the n-type diffusion layers, and the spaces between the sources and the drains in the source/drain regions 5 can be minimized, thereby enabling reduction in gate length. Hence, further miniaturization of the nonvolatile semiconductor memory device can be implemented.

### Second Example Embodiment

The second example embodiment of the present invention will be described next with reference to the drawings.

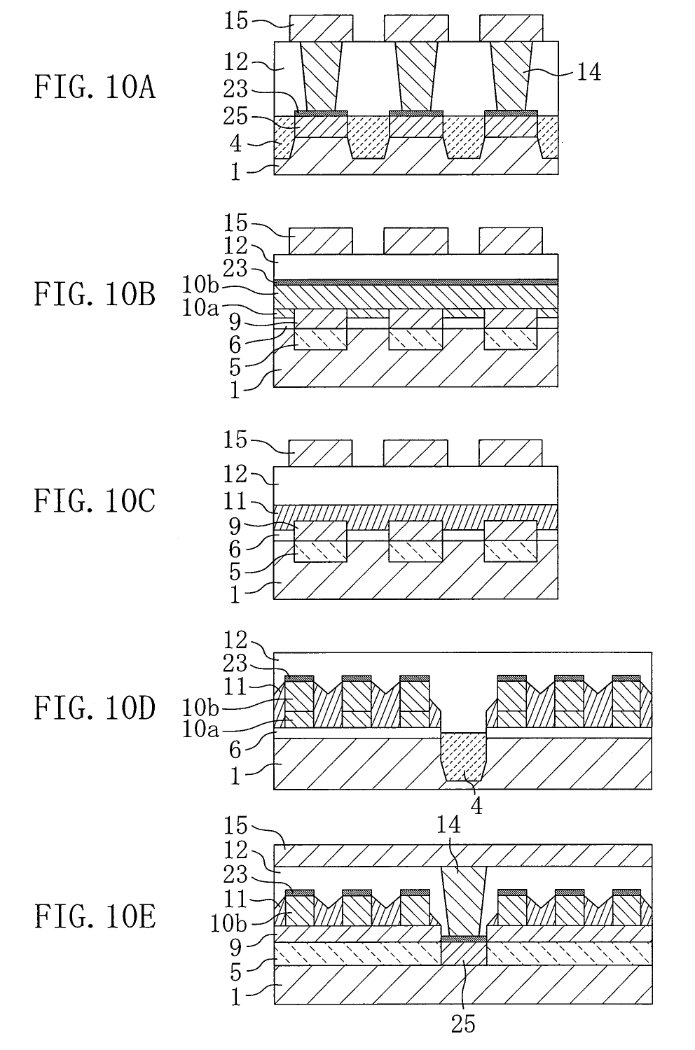

FIGS. 10A to 10E are cross-sectional views of a nonvolatile semiconductor memory device in accordance with the second example embodiment of the present invention. FIG. 10A is a cross-sectional view taken along the line a1-a2 in FIG. 1. FIG. 10B is a cross-sectional view taken along the line b1-b2 in FIG. 1. FIG. 10C is a cross-sectional view taken along the line c1-c2 in FIG. 1. FIG. 10D is a cross-sectional view taken along the line d1-d2 in FIG. 1. FIG. 10E is a cross-sectional view taken along the line e1-e2 in FIG. 1. The plan view of the nonvolatile semiconductor memory device in accordance with the second example embodiment of the present invention is the same as that referred to in the first example embodiment.

As shown in FIG. 1, a plurality of isolation regions 4 are formed by STI in the upper part of a semiconductor substrate 1 made of, for example, silicon. As shown in FIGS. 1, 10A, and 10B, source/drain regions 5 formed with a plurality of n-type impurity diffusion layers are formed in the upper part of the semiconductor substrate 1 at intervals. As shown in FIG. 1, high-concentration impurity diffusion layer regions 25 in bit line contact parts 13 connected to the source/drain regions 5 are isolated by the isolation regions 4.

As shown in FIGS. 10A and 10B, buried oxide films 9 as buried bit lines are formed on the source/drain regions 5. A trap film 6 is formed on the active regions between the source/drain regions 5. The trap film 6 is formed with a stacked film of, for example, silicon oxide (SiO₂), silicon nitride (SiN), and silicon oxide (SiO₂), which is generally called an ONO film, and has a charge capturing site. On the trap film 6, gate electrodes 10 (10a, 10b) as word lines are formed across the buried bit line oxide film 9. The gate electrodes 10 are made of two layers of polycrystalline silicon (first and second polycrystalline silicon films 10a, 10b) with which phosphorous, for example, is introduced as an n-type impurity. The source/drain regions 5 are connected to the high-concentration impurity diffusion layer regions 25 formed in the bit line contact parts 13, as shown in FIG. 10E. The high-concentration impurity diffusion layer regions 25 are connected to contact 14 to be connected to bit lines 15 made of metal, as shown in FIG. 1 and FIG. 10E.

Description will be given below of a manufacturing method of the nonvolatile semiconductor memory device thus structured with reference to FIG. 3 and FIG. 11 to FIG. 17. The following description refers to cross-sectional views showing respective key points of the manufacturing steps.

First, the same steps are carried out as those described with reference to FIGS. 3A to 3C. Specifically, as shown in FIG. 3A, a mask formation film 2A of silicon nitride with a thickness of, for example, about 80 nm to 300 nm is formed on the principal surface of the semiconductor substrate 1 made of silicon. Then, a resist film 3 is deposited, and openings are formed by photolithography. Then, as shown in FIG. 3B, the mask formation film 2A below the resist openings is etched to form a mask film 2 having openings. After removing the resist film 3, the semiconductor substrate 1 below the openings of the mask film 2 is etched to form trenches. As shown in FIG. 3C, an insulating film of silicon oxide or the like is filled in the trenches, and the silicon oxide thus filled is planarized by CMP to form isolation regions 4 by STI or the like. The height of the surfaces of the isolation regions 4 is equal to that of the mask film 2 initially by planarization by CMP, and is therefore adjusted not to be lower than the surface of the semiconductor substrate 1 by wet etching or the like for preparation. This height adjustment is performed for facilitating the later etching process, and is employed usually.

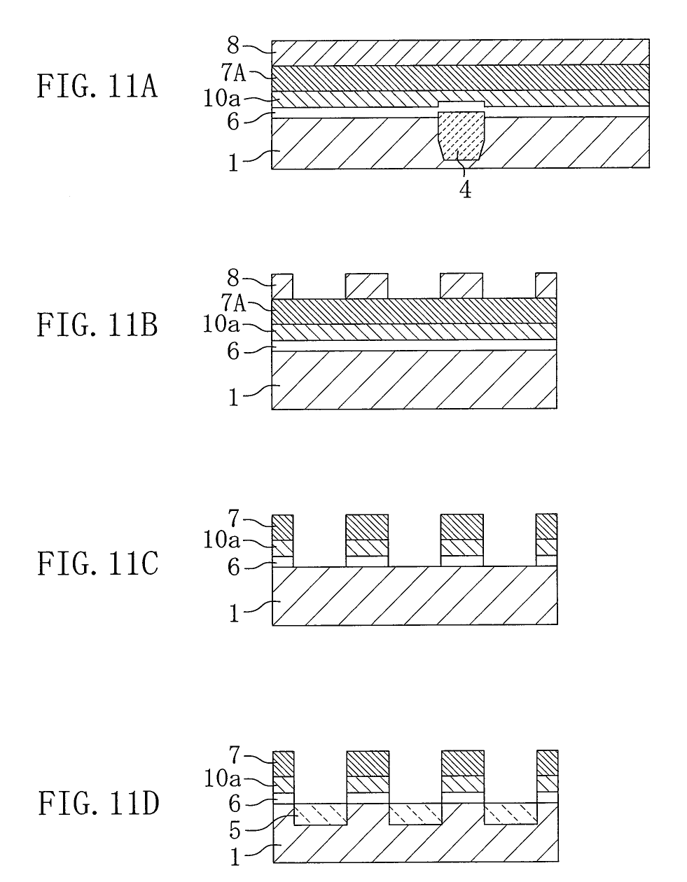

Next, as shown in FIG. 11A (a cross-sectional view corresponding to that taken along the line d1-d2 in FIG. 1), the trap film 6 with a thickness of 20 nm formed with an ONO film and having a charge capturing site is deposited on the entirety of the semiconductor substrate 1. Then, a first polycrystalline silicon film 10a with a thickness of about 20 nm to 80 nm is formed by CVD, for example, and a thin silicon oxide film (not shown) with a thickness of approximately 10 nm is deposited. Further, a mask formation film 7A of silicon nitride with a thickness of 50 nm to 200 nm is deposited by CVD, for example. The thin silicon oxide film (not shown) is formed for protecting the polycrystalline silicon film 10 in selectively removing the mask formation film 7A in a later step, and may be therefore omitted if the process condition for removing the mask formation film 7A is set precisely enough. Further, the thin silicon oxide film is removed subsequently to height adjustment of buried bit line oxide films, and is therefore involves no influence on a later word line forming step. Then, a resist film 8 is coated on the mask formation film 7A.

Next, as shown in FIG. 11B (a cross-sectional view corresponding to that taken along the line b1-b2 in FIG. 1), a resist pattern 8 of the resist film 8 having openings at parts corresponding to the source/drain regions 5 is formed by lithography. The openings have a width of 100 nm, which is the width of regions to be the source/drain regions 5, and corresponds to the width of the bit lines. Referring to the width of the resist, which is 150 nm, it corresponds to the channel width where the memory cell transistors are formed.

Subsequently, as shown in FIG. 11C (a cross-sectional view corresponding to that taken along the line b1-b2 in FIG. 1), dry etching using the resist pattern 8 as a mask is performed on the mask formation film 7A to form, from the mask formation film 7A, a mask film 7 having openings for forming the source/drain regions 5. Then, the silicon oxide film (not shown), the first polycrystalline silicon film 10a, and the trap film 6 below the openings of the patterned mask film 7 are removed. Alternatively, the trap film 6, which is thin, may not be removed for use as a protection film for ion implantation.

Thereafter, as shown in FIG. 11D (a cross-sectional view corresponding to that taken along the line b1-b2 in FIG. 1), ion implantation of, for example, arsenic as an n-type impurity is performed using the mask film 7 one time or two or more times under implantation conditions of 5 keV to 200 keV acceleration energy and 1×10¹⁴ cm⁻² to 1×10¹⁷ cm⁻² dosage to form the source/drain regions 5 formed with n-type impurity diffusion layers. The source/drain regions 5 function as bit line diffusion layers 5.

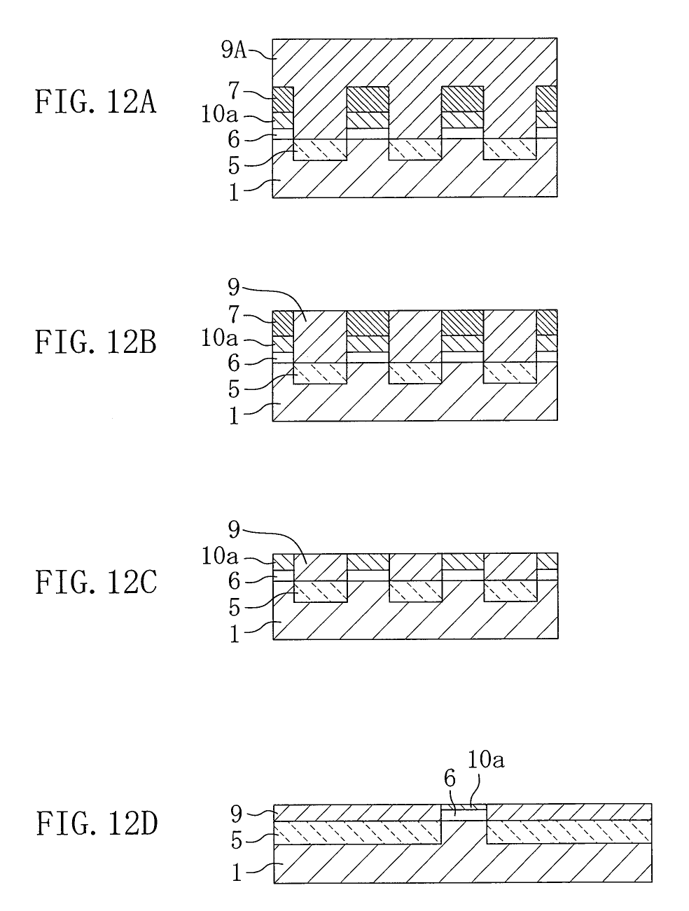

Next, as shown in FIG. 12A (a cross-sectional view corresponding to that taken along the line b1-b2 in FIG. 1), a silicon oxide film 9A to be buried insulating films is deposited in the openings of the mask film 7 by HDPCVD, LPCVD, or the like, for example.

Subsequently, as shown in FIG. 12B (a cross-sectional view corresponding to that taken along the line b1-b2 in FIG. 1), the silicon oxide film 9A other than its part filled in the openings of the mask film 7 is selectively removed by CMP or etching back.

Subsequently, as shown in FIG. 12C (a cross-sectional view corresponding to that taken along the line b1-b2 in FIG. 1) and FIG. 12D (a cross-sectional view corresponding to that taken along the line e1-e2 in FIG. 1), the height of the filled silicon oxide film is adjusted to be almost equal to the height of the first polycrystalline silicon film 10a by wet etching or etching back. Then, only the mask film 7 is removed selectively by wet etching or etching back, and the silicon oxide film (not shown) is removed to form the buried bit line oxide films 9. By doing this, the height of the buried bit line oxide films 9 becomes almost equal to that of the first polycrystalline silicon film 10a. This height adjustment is carried out before selective removal of the mask film 7 in the preset example embodiment. For further precise adjustment, it is carried out both before and after selective removal of the mask film 7. This height adjustment is performed for facilitating the later etching process, similarly to the height adjustment for the isolation regions.

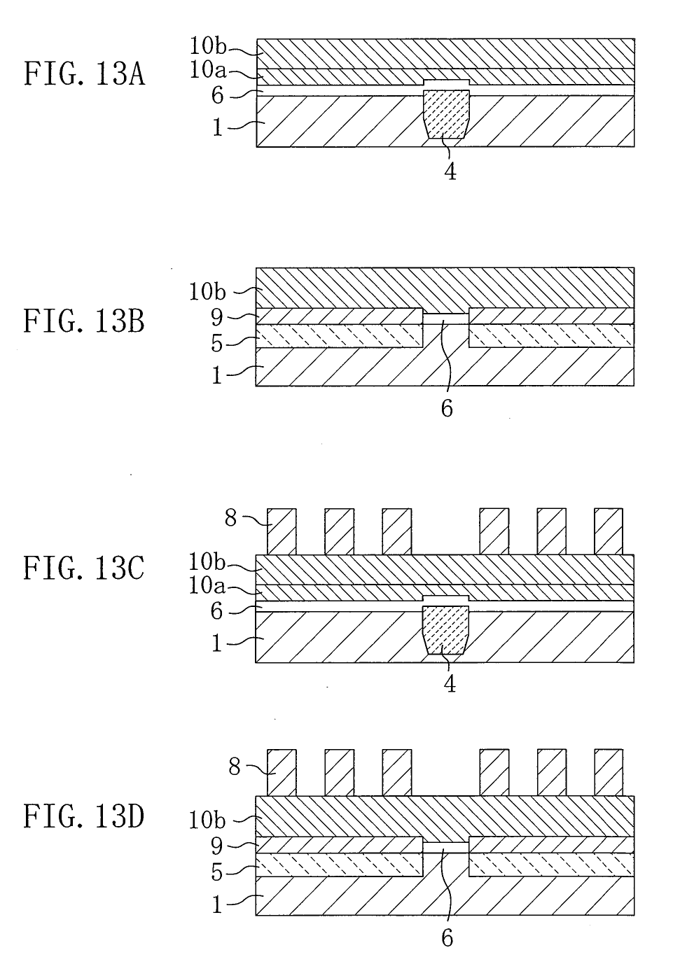

Thereafter, as shown in FIG. 13A (a cross-sectional view corresponding to that taken along the line d1-d2 in FIG. 1) and FIG. 13B (a cross-sectional view corresponding to that taken along the line e1-e2 in FIG. 1), an n-type impurity doped second polycrystalline silicon film 10b with which phosphorous of 1×10¹⁸ cm⁻³ to 1×10²² cm⁻³ is doped is deposited on the first polycrystalline silicon film 10a and the buried bit line oxide films 9 by LPCVD, for example. In this time point, a thin natural oxide film of about 1 nm may be formed at the interface between the first polycrystalline silicon film 10a and the second polycrystalline silicon film 10b. However, this involves no problem on the use as the gate electrodes because the first polycrystalline silicon film 10a is connected electrically to the second polycrystalline silicon film 10b.

Next, as shown in FIG. 13C (a cross-sectional view corresponding to that taken along the line d1-d2 in FIG. 1) and FIG. 13D (a cross-sectional view corresponding to that taken along the line e1-e2 in FIG. 1), a resist pattern 8 for forming word lines is formed in the direction across the source/drain regions 5 spaced from each other by lithography after coating a resist film.

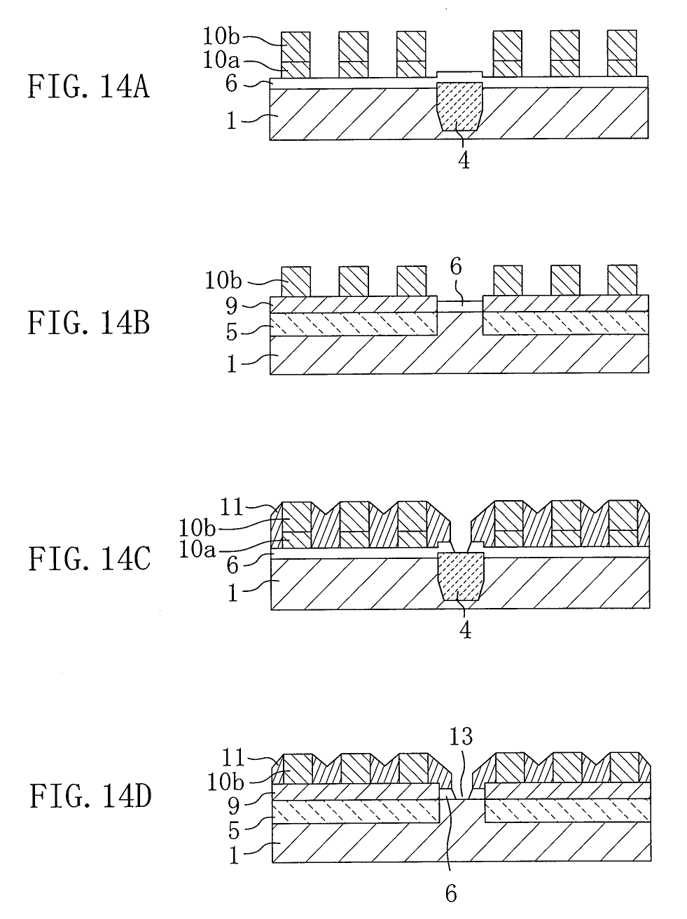

Subsequently, as shown in FIG. 14A (a cross-sectional view corresponding to that taken long the line d1-d2 in FIG. 1) and FIG. 14B (a cross-sectional view corresponding to that taken along the line e1-e2 in FIG. 1), predetermined regions of the first and second polycrystalline silicon films 10a, 10b are opened by dry etching using the resist pattern 8 as a mask to form the gate electrodes 10a, 1b, and to expose the trap film 6 in the openings thus formed. In FIGS. 14A and 14B, the gate electrodes 10 are formed so that the sidewalls thereof have an angle of approximately 90±1° relative to the substrate plane of the semiconductor substrate 1. Alternatively, the upper parts of the sidewalls of the gate electrodes 10b may be tapered or rounded at an angle of about 84°.

Thereafter, as shown in FIG. 14C (a cross-sectional view corresponding to that taken along the line d1-d2 in FIG. 1), and FIG. 14D (a cross-sectional view corresponding to that taken along the line e1-e2 in FIG. 1), after removing the resist pattern 8, an insulating film of silicon oxide or silicon nitride is deposited by, for example, LPCVD so as to fill the openings between the gate electrodes 10. Etching back is then performed to remove the insulating film on the tops of the gate electrodes 10 with the insulating film (to be sidewall insulating films 11) left between the gate electrodes 10, and to remove part of the insulating film and part of the trap film 6 below the insulating film in the bit line contact parts 13.

Herein, the etching rate for insulating film is set to correspond to the time required for removing only the insulating film on the tops of the gate electrodes 10 (corresponding to the thickness of the insulating film). This may cause substantially no removal of the insulating film filled between the gate electrodes 10, thereby forming ignorable projections and depressions on the memory cells. A desirable etching rate is preferably set by detecting the end point at the time point when the top surfaces of the gate electrodes 10 are exposed by luminance intensity variation or the like. Preferably, an appropriate amount of overetching is performed so as to remove part of the insulating film and part of the trap film 6 below the insulating film on the bit line contacts after exposure of the top surfaces of the gate electrodes 10. Referring to one specific example, detection of the etching end point and overetching are set so that height difference between the top surfaces of the gate electrodes 10 and the top surfaces of the insulating film 11 filled between the gate electrodes 10 is within 100 nm. With a value within this range, no void may be formed in forming an interlayer insulating film in a later step.

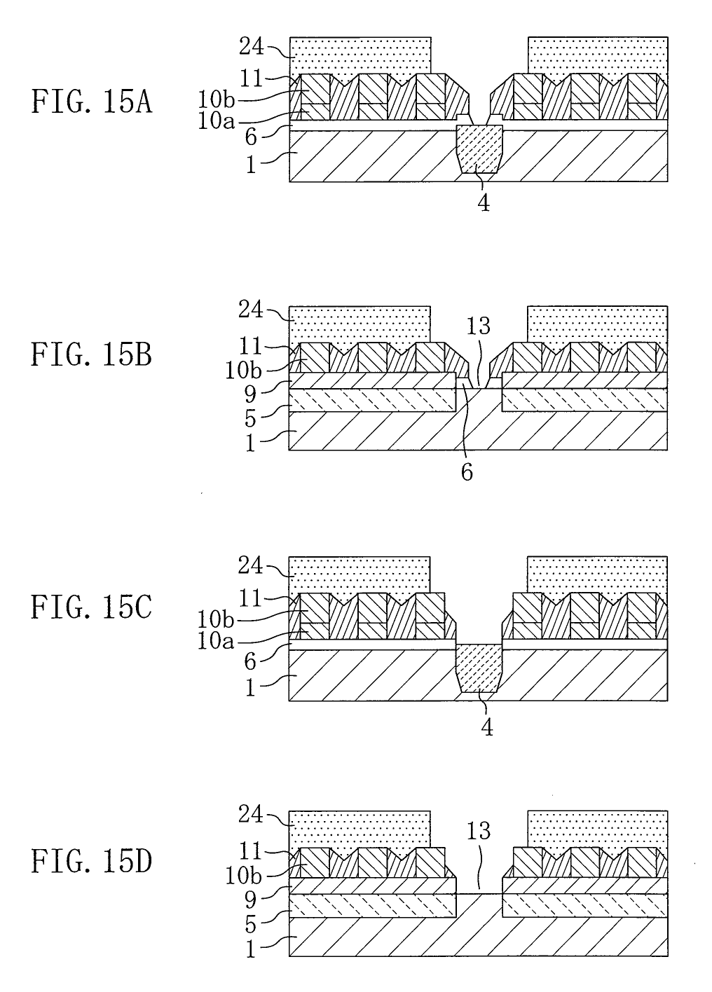

Next, as shown in FIG. 15A (a cross-sectional view corresponding to that taken along the line d1-d2 in FIG. 1) and FIG. 15B (a cross-sectional view corresponding to that taken along the line e1-e2 in FIG. 1), a resist pattern 24 is formed for selectively exposing the sidewall insulating films 11 and the trap film 6 of the boundary word lines closest to the bit line contact regions.

Subsequently, as shown in FIG. 15C (a cross-sectional view corresponding to that taken along the line d1-d2 in FIG. 1) and FIG. 15D (a cross-sectional view corresponding to that taken along the line e1-e2 in FIG. 1), by dry etching, the trap film 6 in the openings of the resist pattern 24 is removed, and part of the sidewall insulating films 11 of the boundary word lines is etched. By this step, the sidewall insulating films 11 of the boundary word lines are processed so as to decrease in width as the etching for removing the trap film 6 progresses, in other words, so as to expand the opening regions of the semiconductor substrate 1 in the openings.

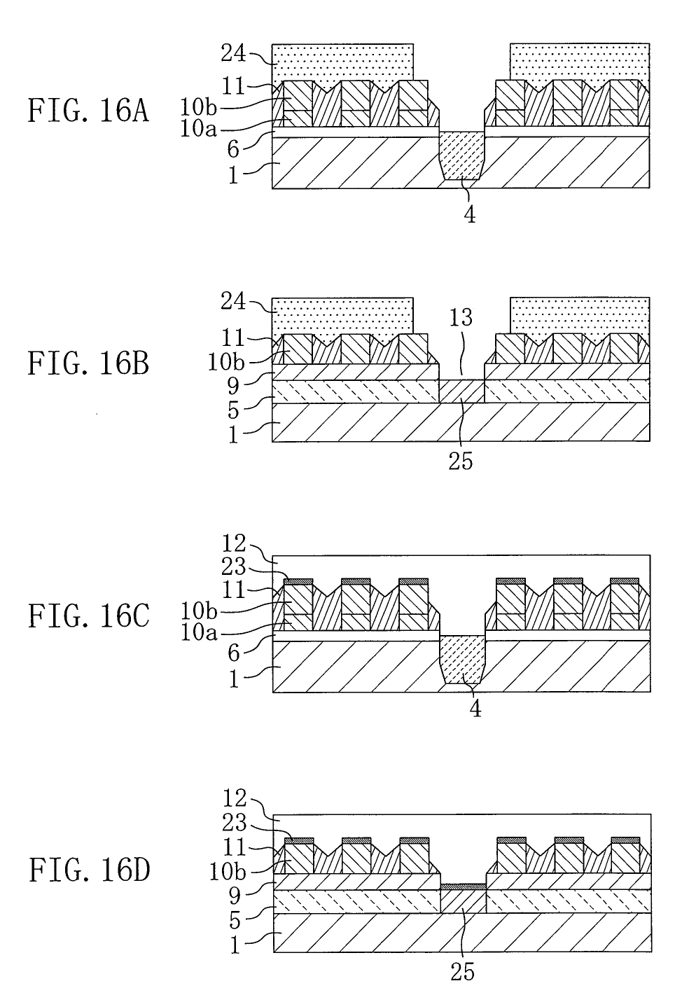

Thereafter, as shown in FIG. 16A (a cross-sectional view corresponding to that taken along the line d1-d2 in FIG. 1) and FIG. 16B (a cross-sectional view corresponding to that taken along the line e1-e2 in FIG. 1), ion implantation of, for example, arsenic as an n-type impurity is performed one time or two or more times under implantation conditions of 5 keV to 200 keV acceleration energy and 1×10¹⁴ cm⁻² to 1×10¹⁷ cm⁻² dosage to form the high-concentration impurity diffusion layers 25 of n-type impurity diffusion layers in the bit line contact regions. The high-concentration impurity diffusion layers 25 are electrically connected to the source/drain regions 5 formed below the buried bit line oxide films 9.

Next, as shown in FIG. 16C (a cross-sectional view corresponding to that taken along the line d1-d2 in FIG. 1) and FIG. 16D (a cross-sectional view corresponding to that taken along the line e1-e2 in FIG. 1), after removing the resist pattern 24, a metal film of cobalt, nickel, or the like is deposited on the entirety of the semiconductor substrate 1 by, for example, vacuum deposition, or the like, and thermal treatment is performed. Thus, a meal silicide layer 23 is formed in the upper parts of the gate electrodes 10 and the upper parts of the bit line contact parts 13. Then, an insulating film of silicon oxide is deposited entirely by HDPCVD, APCVD, PECVD, or the like, and the resultant surface is planarized by, for example, CMP, dry etching back, or the like to form an interlayer insulating film 12.

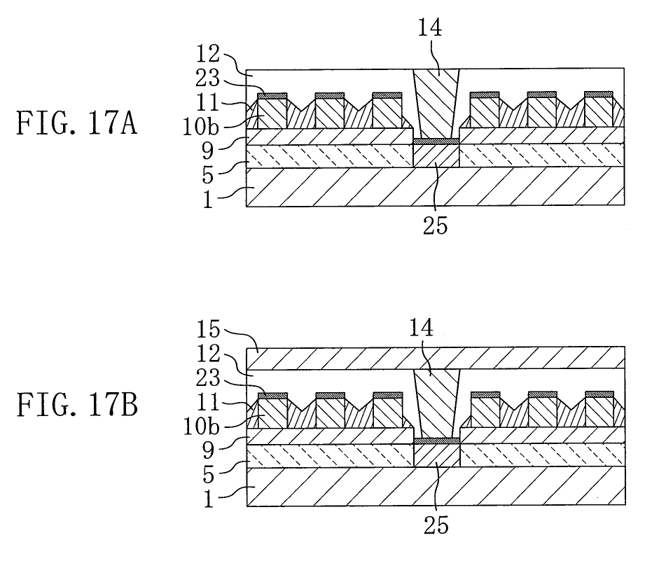

Subsequently, as shown in FIG. 17A (a cross-sectional view corresponding to that taken along the line d1-d2 in FIG. 1), connection holes are formed to expose the metal silicide layer 23 on the high-concentration impurity diffusion layers 25 in the bit line contact regions, and a conductive film formed with a single layer or stacked metal film is deposited entirely on the interlayer insulating film 12 to fill the connection holes, thereby forming the contacts 14. Examples of the metal of the conductive film include tungsten, a tungsten compound, titanium, a titanium compound, such as titanium nitride, and the like.

Thereafter, as shown in FIG. 17B (a cross-sectional view corresponding to that taken along the line e1-e2 in FIG. 1), the deposited conductive film is patterned so that the high-concentration impurity diffusion layers 25 of the bit line contact regions are connected to each other to form the bit lines 15 from the conductive film.

As described above, according to the present example embodiment, the insulating films 11 between the gate electrodes 10 in the memory cell part is hardly removed, and therefore, projections and depressions formed there can be ignorable. In turn, no void may be formed in the memory cell part in forming the interlayer insulating film 12. The trap film 6 in the bit line contact parts 13 is selectively removed to achieve ensured electrical connection to the high-concentration impurity diffusion layers 25 in forming the contacts 14. Accordingly, in the present example embodiment, even if the width of the bit line contact regions is narrower than that in the conventional technique, no void may be formed in the interlayer insulating film 12 between the gate electrodes 10, and electrical connection between the contacts 14 and the high-concentration impurity diffusion layers 25 can be secured. Hence, the manufacturing yield of a miniaturized semiconductor device can be increased.

In the present example embodiment, the buried bit line oxide films 9 are formed with the first polycrystalline silicon film 10a formed for preparation. This can facilitate height adjustment and can achieve highly precise control on the yield when compared with the case of the first example embodiment.

In the present example embodiment, the mask film 2 for forming the source/drain regions 5 is made of silicon nitride. Rather than silicon nitride, an insulating film made of a silicon compound, such as silicon oxide or the like may be used. In forming the source/drain regions 5, a resist material may be used as a mask without using the mask film made of a silicon compound.

As the trap film 6 having a charge capturing site, a stacked film of silicon oxide, silicon nitride, and silicon oxide is employed in the present example embodiment. In place of this, any of the following films may be employed: a single layer film of silicon oxinitride; a single layer film of silicon nitride; a stacked film of silicon oxide and silicon nitride deposited in this order on the semiconductor substrate; and a stacked film of silicon oxide, silicon nitride, silicon oxide, silicon nitride, and silicon oxide deposited in this order thereon.

In the present example embodiment, the film thickness of the trap film 6 is set at 20 nm as one example. The film thickness thereof may be adjusted appropriately within the range between 10 nm and 30 nm so as to optimize the transistor characteristics.

Each height of the first polycrystalline silicon film 10a and the buried oxide films 9 is set at 50 nm as an example in the present example embodiment, but may be appropriately adjusted in the range between 20 nm and 100 nm so as to optimize the leakage current between the gate electrodes 10 and the sources or the drains.

Further, in the present example embodiment, the width of the n-type impurity diffusion layers is set at 100 nm as an example. It may be adjusted within the range between 50 nm and 300 nm so as to optimize the transistor characteristics.

The resist material is used as the mask for dry etching the first and second polycrystalline silicon films 10a, 10b in the present example embodiment. It may be inferred that higher etching selectivity is required in a process for higher integration. In such a case, a mask of a silicon oxide film or a silicon nitride film, or a mask of a stacked film of them and the resist material may be employed.

The second polycrystalline silicon film 10b forming the gate electrodes 10b is deposited as doped polysilicon in the present example embodiment. Alternatively, an impurity may be doped after non-doped polysilicon with which no impurity is doped is deposited. The polycrystalline silicon films are only examples as a material of the gate electrodes, and may be replaced by a single layer film or a stacked film of any of polycrystalline silicon, amorphous silicon, high-melting point metal having a melting point equal to or higher than 600° C., such as tantalum, titanium, and the like, a metal compound, and metal silicide. Alternatively, the second polycrystalline silicon film 10b forming the word lines 10b may be silicided by metal.

In the present example embodiment, a silicon oxide film and a silicon nitride film by CVD are used as an example of, but does not limit the films buried and filled between the word lines. Any insulating film is applicable which is excellent in step coverage and which can be formed by film formation using no plasma. However, a film requiring high temperature baking in a later step, such as atmospheric pressure CVD is difficult in handling, and highly accurate film formation condition and baking condition must be set.

A memory element of which source/drain regions 5 are n-type is referred to in the present example embodiment. The memory element may be p-type, of course.

In the present example embodiment, the side and bottom surfaces of the n-type impurity diffusion layers forming the source/drain regions 5 may be covered with a p-type impurity diffusion layer having an impurity concentration lower than that of the n-type impurity diffusion layers. With this configuration, the p-type impurity diffusion layer can suppress the short channel effect caused due to impurity diffusion in the n-type diffusion layers, and the spaces between the sources and the drains in the source/drain regions 5 can be minimized, thereby achieving reduction in gate length. Hence, further miniaturization of the nonvolatile semiconductor memory device can be implemented.

### Third Example Embodiment

The third example embodiment of the present invention will now be described with reference to the drawings.

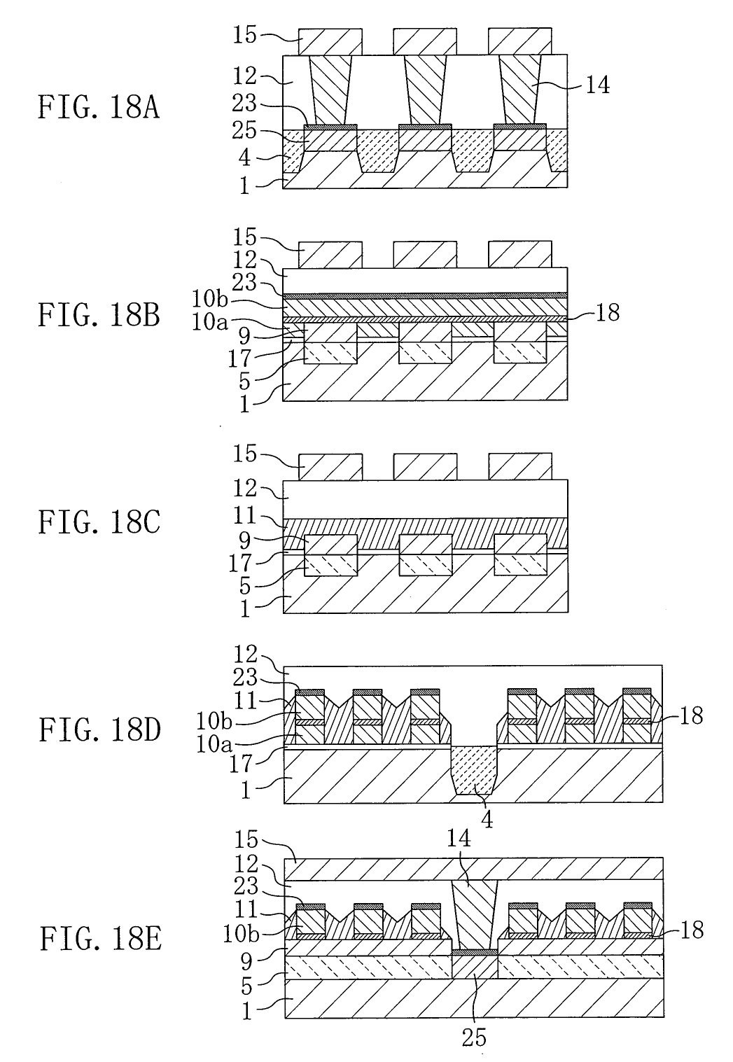

FIGS. 18A to 18E are cross-sectional views of a nonvolatile semiconductor memory device in accordance with the third example embodiment of the present invention. FIG. 18A is a cross-sectional view taken along the line a1-a2 in FIG. 1. FIG. 18B is a cross-sectional view taken along the line b1-b2 in FIG. 1. FIG. 18C is a cross-sectional view taken along the line c1-c2 in FIG. 1. FIG. 18D is a cross-sectional view taken along the line d1-d2 in FIG. 1. FIG. 18E is a cross-sectional view taken along the line e1-e2 in FIG. 1. The plan view of the nonvolatile semiconductor memory device in accordance with the third example embodiment of the present invention is the same as the plan view referred to in the first example embodiment.

As shown in FIG. 1, a plurality of isolation regions 4 are formed by STI in the upper part of a semiconductor substrate 1 made of, for example, silicon. As shown in FIGS. 1, 18A, and 18B, source/drain regions 5 formed with a plurality of n-type impurity diffusion layers are formed in the upper part of the semiconductor substrate 1 at intervals. As shown in FIG. 1, high-concentration impurity diffusion layer regions 25 in bit line contact parts 13 connected to the source/drain regions 5 are isolated by the isolation regions 4.

As shown in FIGS. 18B and 18B, buried bit line oxide films 9 are formed on the source/drain regions 5. On the active regions between the source/drain regions 5, a silicon oxide film, for example, (generally called a tunneling film 17) is formed. Floating gate electrodes of polycrystalline silicon (a first polycrystalline silicon film 10a) with which phosphorous, for example, as an n-type impurity is doped are formed on the tunneling film 17. An inter-electrode insulating film 18 formed with a stacked film of, for example, silicon oxide (SiO₂), silicon nitride (SiN), and silicon oxide (SiO₂), which is generally called an ONO film, is formed on the floating gate electrodes of the first polycrystalline silicon film 10a. Further, word lines of polycrystalline silicon (a second polycrystalline silicon film 10b) with which phosphorous, for example, as an n-type impurity is doped are formed across the buried bit line oxide films 9. The source/drain regions 5 are connected to the high-concentration impurity diffusion layer regions 25 formed in the bit line contact parts 13, as shown in FIG. 18E. The high-concentration impurity diffusion layer regions 25 are connected to contacts 14 to be connected to bit lines 15 made of metal, as shown in FIG. 1 and FIG. 18E.

Description will be given below of a manufacturing method of the nonvolatile semiconductor memory device thus structured with reference to FIG. 3 and FIGS. 19 to 25. The following description refers to cross-sectional views showing respective key points of the manufacturing steps.

First, the same steps are carried out as those described with reference to FIGS. 3A to 3C. Specifically, as shown in FIG. 3A, a mask formation film 2A of silicon nitride with a thickness of, for example, about 80 nm to 300 nm is formed on the principal surface of the semiconductor substrate 1 made of silicon. Then, a resist film 3 is deposited, and openings are formed by photolithography. Then, as shown in FIG. 3B, the mask formation film 2A below the resist openings is etched to form a mask film 2 having openings. After removing the resist film 3, the semiconductor substrate 1 below the openings of the mask film 2 is etched to form trenches. As shown in FIG. 3C, an insulating film of silicon oxide or the like is filled in the trenches, and the silicon oxide thus filled is planarized by CMP to form isolation regions 4 by STI or the like. The height of the surfaces of the isolation regions 4 is equal to that of the mask film 2 initially by planarization by CMP, and is therefore adjusted not to be lower than the surface of the semiconductor substrate 1 by wet etching or the like for preparation. This height adjustment is performed for facilitating the later etching process, and is employed usually.

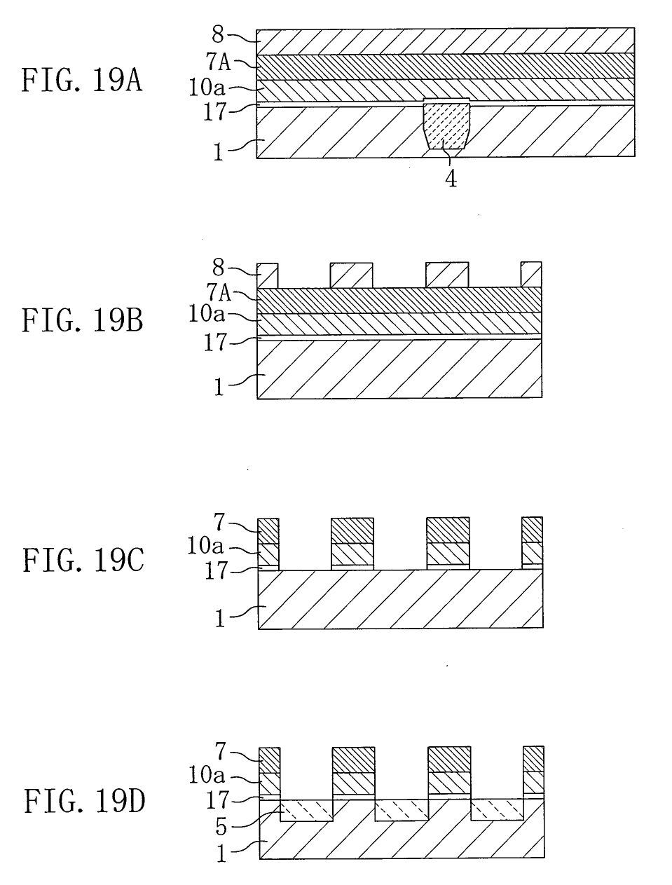

Next, as shown in FIG. 19A (a cross-sectional view corresponding to that taken along the line d1-d2 in FIG. 1), the tunneling film 17 of silicon oxide or the like with a thickness of 10 nm is deposited on the entirety of the semiconductor substrate 1. A first polycrystalline silicon film 10a with a thickness of about 20 nm to 80 nm is formed by CVD, for example, and a thin silicon oxide film (not shown) of approximately 10 nm in thickness is deposited. Then, a mask formation film 7A of silicon nitride with a thickness of about 50 nm to 200 nm is deposited by CVD, for example. The thin silicon oxide film (not shown) is formed for protecting the polycrystalline silicon film 10a in selectively removing the mask formation film 7A in a later step. Therefore, formation of the thin silicon oxide film may be omitted by highly precisely adjusting the process conditions for removing the mask formation film 7A. In addition, the thin oxide silicon film is removed subsequently to the height adjustment of the buried bit line insulating films, and therefore involves no influence on the later word line forming step.

Subsequently, as shown in FIG. 19B (a cross-sectional view corresponding to that taken along the line b1-b2 in FIG. 1), after a resist film 8 is coated on the mask formation film 7A, a resist pattern 8 of the resist film 8 having openings at parts corresponding to the source/drain regions 5 is formed by lithography. The openings have a width of 100 nm, which is the width of regions to be the source/drain regions 5, and corresponds to the width of the bit lines. Referring to the width of the resist, which is 150 nm, it corresponds to the channel width where the memory cell transistors are formed.

Thereafter, as shown in FIG. 19C (a cross-sectional view corresponding to that taken along the line b1-b2 in FIG. 1), dry etching using the resist pattern 8 as a mask is performed on the mask formation film 7A to form, from the mask formation film 7A, a mask film 7 having openings for forming the source/drain regions 5. Then, the silicon oxide film (not shown), the first polycrystalline silicon film 10a, and the tunneling film 17 below the openings of the patterned mask film 7 are removed. Alternatively, the tunneling film 17 may not be removed for use as a protection film for ion implantation.

Next, as shown in FIG. 19D (a cross-sectional view corresponding to that taken along the line b1-b2 in FIG. 1), ion implantation of, for example, arsenic as an n-type impurity is performed using the mask film 7 one time or two or more times under implantation conditions of 5 keV to 200 keV acceleration energy and 1×10¹⁴ cm⁻² to 1×10¹⁷ cm⁻² dosage to form the source/drain regions 5 formed with n-type impurity diffusion layers. The source/drain regions 5 function as bit line diffusion layers 5.

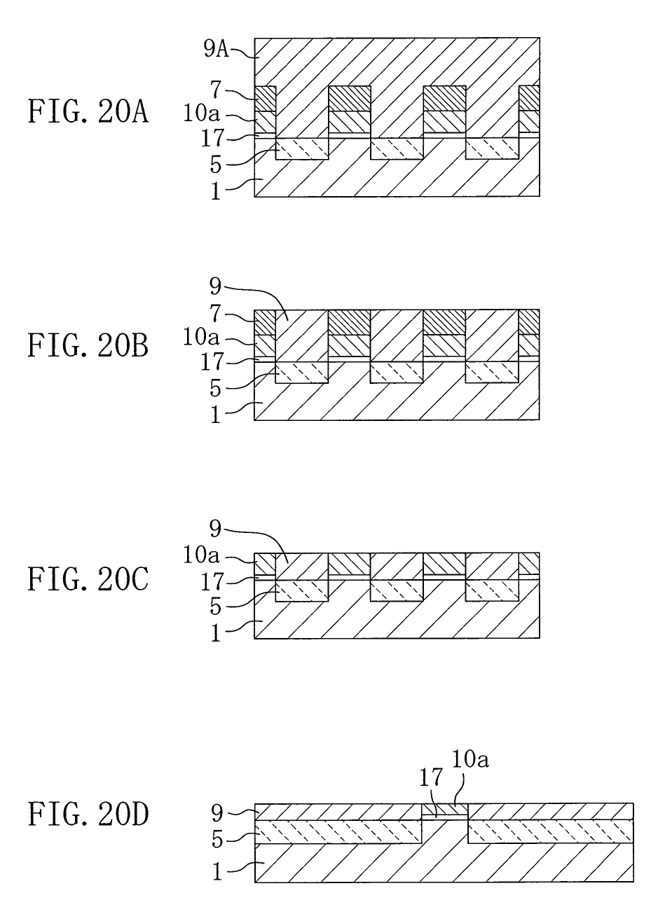

Subsequently, as shown in FIG. 20A (a cross-sectional view corresponding to that taken along the line b1-b2 in FIG. 1), a silicon oxide film 9A to be buried insulating films is deposited in the openings of the mask film 7 by LPCVD, or the like, for example.

Next, as shown in FIG. 20B (a cross-sectional view corresponding to that taken along the line b1-b2 in FIG. 1), the silicon oxide film 9A other than its part filled in the openings of the mask film 7 is selectively removed by CMP or etching back.

Subsequently, as shown in FIG. 20C (a cross-sectional view corresponding to that taken along the line b1-b2 in FIG. 1) and FIG. 20D (a cross-sectional view corresponding to that taken along the line e1-e2 in FIG. 1), the height of the filled silicon oxide film is adjusted to be almost equal to that of the first polycrystalline silicon film 10a by wet etching or etching back. Then, only the mask film 7 is removed selectively by wet etching or etching back, and the silicon oxide film (not shown) is removed to form the buried bit line oxide films 9. Whereby, the height of the buried bit line oxide films 9 is adjusted to be almost equal to that of the first polycrystalline silicon film 10a. This height adjustment is performed before selective removal of the mask film 7 in this example embodiment, but may be preferably performed both before and after selective removal thereof for further accurate adjustment.

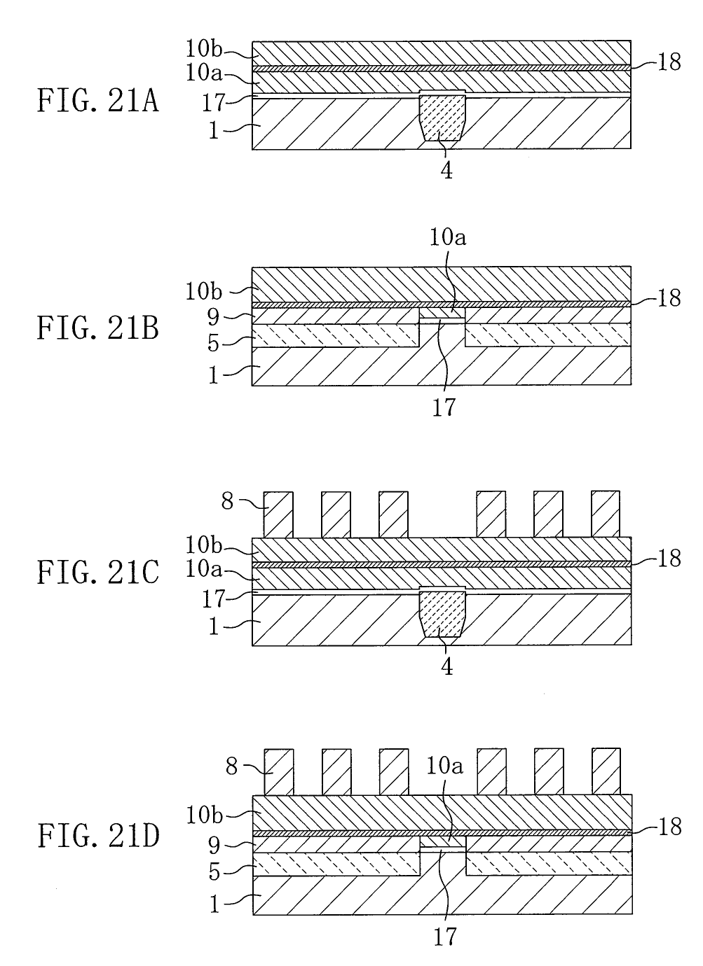

Thereafter, as shown in FIG. 21A (a cross-sectional view corresponding to that taken along the line d1-d2 in FIG. 1) and FIG. 21B (a cross-sectional view corresponding to that taken along the line e1-e2 in FIG. 1), an inter-electrode insulating film 18 of a stacked film (ONO film) of silicon oxide, silicon nitride, and silicon oxide is deposited on the first polycrystalline silicon film 10a and the buried bit line oxide films 9 by LPCVD, for example. Then, a second polycrystalline silicon film 10b with which phosphorous as an n-type impurity is doped at 1×10¹⁸ cm⁻³ to 1×10²² cm⁻³ is deposited by LPCVD, for example.

Next, as shown in FIG. 21C (a cross-sectional view corresponding to that taken along the line d1-d2 in FIG. 1) and FIG. 21D (a cross-sectional view corresponding to that taken along the line e1-e2 in FIG. 1), after coating a resist film, a resist pattern 8 for forming word lines is formed in the direction across the source/drain regions 5 spaced from each other by lithography.

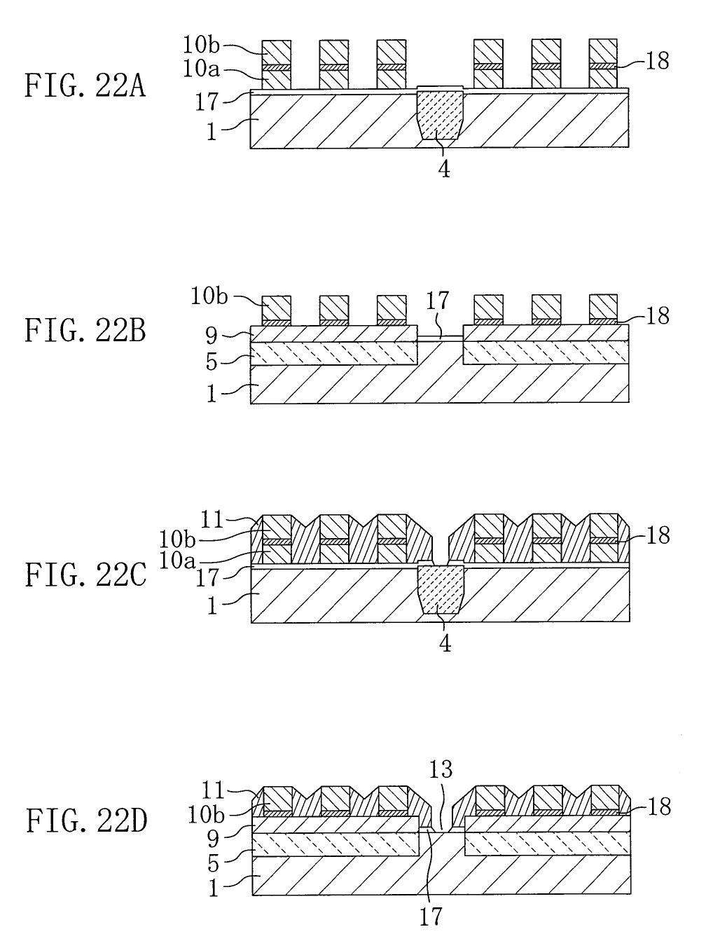

Subsequently, as shown in FIG. 22A (a cross-sectional view corresponding to that taken along the line d1-d2 in FIG. 1) and FIG. 22B (a cross-sectional view corresponding to that taken along the line e1-e2 in FIG. 1), predetermined regions of the first and second polycrystalline silicon films 10a, 10b and the inter-electrode insulating film 18 are opened by dry etching using the resist pattern 8 as a mask to form lower floating gate electrodes 10a of the first polycrystalline silicon film 10a and upper control gate electrodes 10b of the second polycrystalline silicon film 10b, and to expose the tunneling film 17 in the openings thus formed. In FIGS. 22A and 22B, the upper control gate electrodes 10b and the lower floating gate electrodes 10a are formed so that the sidewalls thereof have an angle of approximately 90±1° relative to the substrate plane of the semiconductor substrate 1. Alternatively, the sidewalls of only the upper control gate electrodes 10b may be tapered or rounded at an angle of about 84°.

Thereafter, as shown in FIG. 22C (a cross-sectional view corresponding to that taken along the line d1-d2 in FIG. 1) and FIG. 22D (a cross-sectional view corresponding to that taken along the line e1-e2 in FIG. 1), after removing the resist pattern 8, an insulating film of silicon oxide or silicon nitride is deposited by, for example, LPCVD so as to fill the openings between the adjacent upper control gate electrodes and lower floating gate electrodes. Etching back is then performed to remove the insulating film on the tops of the gate electrodes 10b with the insulating film (to be sidewall insulating films 11) left between the gate electrodes 10a, 10b, and to remove part of the tunneling film 17 on the bit line contact parts 13.

Herein, the etching rate for insulating film is set to correspond to the time required for removing only the insulating film on the topes of the gate electrodes 10b (corresponding to the thickness of the insulating film). This may cause substantially no removal of the insulating film filled between the gate electrodes 10a, 10b, thereby forming ignorable projections and depressions on the memory cells. Referring to a specific example, height difference between the top surfaces of the gate electrodes 10b and the top surfaces of the insulating film filled between the gate electrodes 10a, 10b is preferably set within 100 nm.

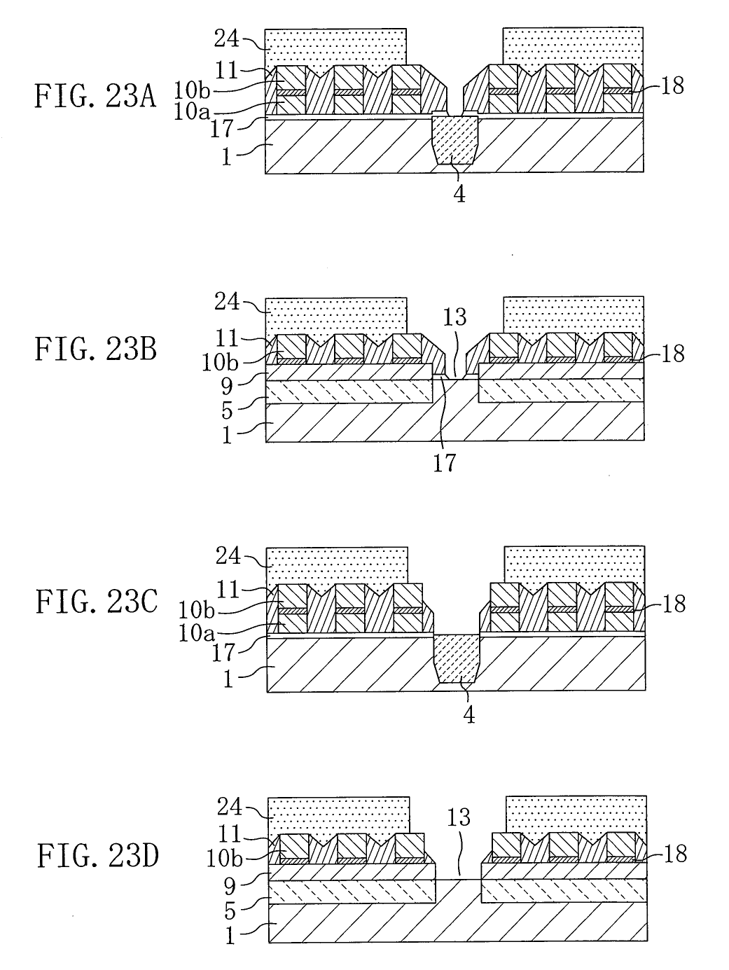

Next, as shown in FIG. 23A (a cross-sectional view corresponding to that taken along the line d1-d2 in FIG. 1) and FIG. 23B (a cross-sectional view corresponding to that taken along the line e1-e2 in FIG. 1), a resist pattern 24 is formed for selectively exposing sidewall insulating films 11 and the trap film 6 of the boundary word lines closest to the bit line contact regions.

Subsequently, as shown in FIG. 23C (a cross-sectional view corresponding to that taken along the line d1-d2 in FIG. 1) and FIG. 23D (a cross-sectional view corresponding to that taken along the line e1-e2 in FIG. 1), by dry etching, the tunneling film 17 in the openings of the resist pattern 24 is removed, and part of the sidewall insulating films 11 of the boundary word lines is etched. By this step, the sidewall insulating films 11 of the boundary word lines are processed so as to decrease in width as the etching for removing the tunneling film 17 progresses, in other words, so as to expand the opening regions of the semiconductor substrate 1 in the openings.

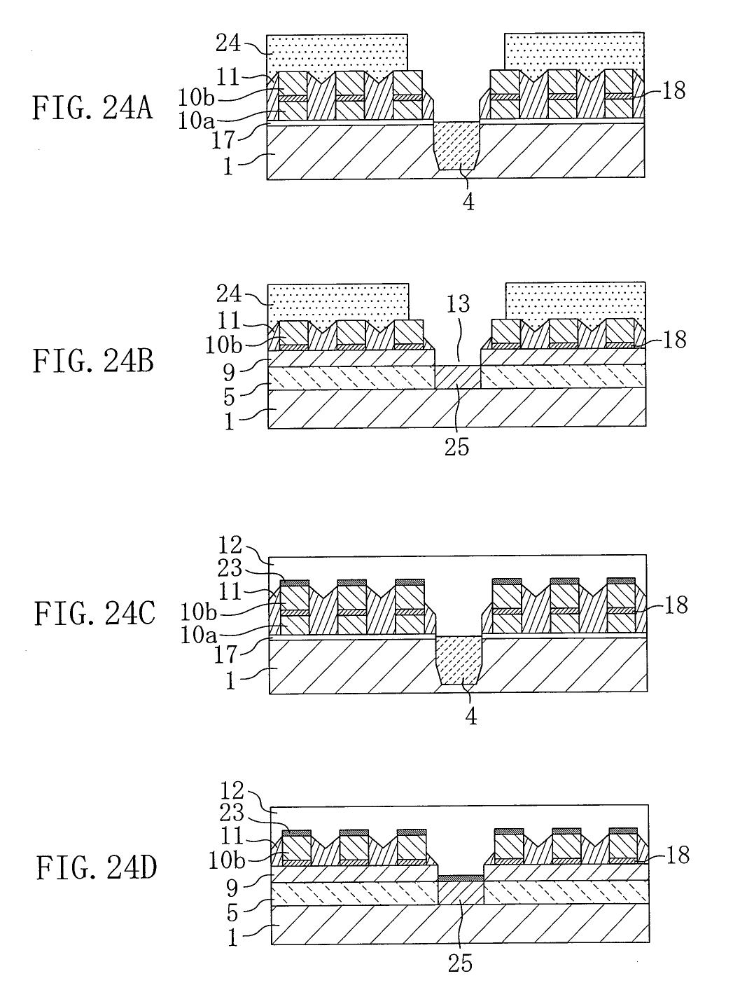

Thereafter, as shown in FIG. 24A (a cross-sectional view corresponding to that taken along the line d1-d2 in FIG. 1) and FIG. 24B (a cross-sectional view corresponding to that taken along the line e1-e2 in FIG. 1), ion implantation of, for example, arsenic as an n-type impurity is performed one time or two or more times under implantation conditions of 5 keV to 200 keV acceleration energy and 1×10¹⁴ cm⁻² to 1×10¹⁷ cm⁻² dosage to form the high-concentration impurity diffusion layers 25 of n-type impurity diffusion layers in the bit line contact regions. The high-concentration impurity diffusion layers 25 are electrically connected to the source/drain regions 5 formed below the buried bit line oxide films 9.

Next, as shown in FIG. 24C (a cross-sectional view corresponding to that taken along the line d1-d2 in FIG. 1) and FIG. 24D (a cross-sectional view corresponding to that taken along the line e1-e2 in FIG. 1), after removing the resist pattern 24, a metal film of cobalt, nickel, or the like is deposited on the entirety of the semiconductor substrate 1 by, for example, vacuum deposition, or the like, and thermal treatment is performed. Thus, the meal silicide layer 23 is formed in the upper parts of the gate electrodes 10b and the upper parts of the bit line contact parts 13. Then, an insulating film of silicon oxide is deposited entirely by HDPCVD, APCVD, PECVD, or the like, and the resultant surface is planarized by, for example, CMP, dry etching, or the like to form an interlayer insulating film 12.

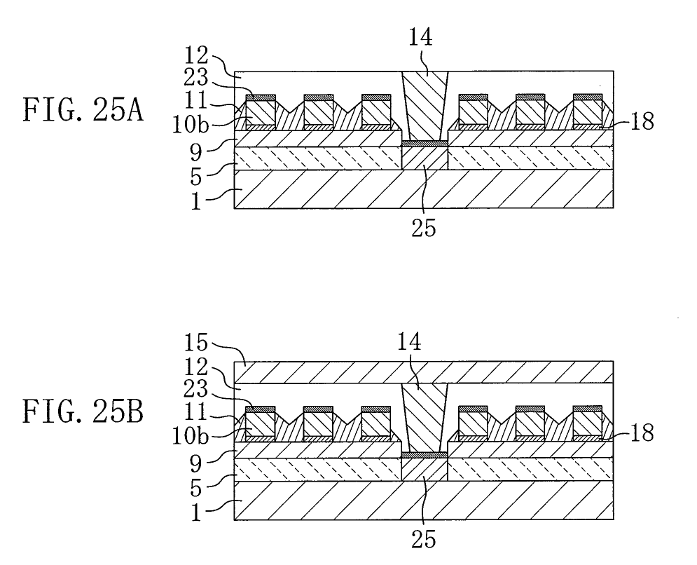

Subsequently, as shown in FIG. 25A (a cross-sectional view corresponding to that taken along the line e1-e2 in FIG. 1), connection holes are formed to expose the metal silicide layer 23 on the high-concentration impurity diffusion layers 25 in the bit line contact regions, and a conductive film formed with a single layer or stacked metal film is deposited entirely on the interlayer insulating film 12 to fill the connection holes, thereby forming the contacts 14. Examples of the metal of the conductive film include tungsten, a tungsten compound, titanium, a titanium compound, such as titanium nitride, and the like.

Thereafter, as shown in FIG. 25B (a cross-sectional view corresponding to that taken along the line e1-e2 in FIG. 1), the deposited conductive film is patterned so that the high-concentration impurity diffusion layers 25 of the bit line contact regions are connected to each other to form the bit lines 15 from the conductive film.

As described above, according to the present example embodiment, the insulating films 11 between the gate electrodes 10a, 10b in the memory cell part is hardly removed, and therefore, projections and depressions formed there can be ignorable. In turn, no void may be formed in the memory cell part in forming the interlayer insulating film 12. The tunneling film 17 in the bit line contact parts 13 is removed selectively to achieve secured electrical connection to the high-concentration impurity diffusion layers 25 in forming the contacts 14. Accordingly, in the present example embodiment, even if the width of the bit line contact regions is narrower than that in the conventional technique, no void may be formed in the interlayer insulating film 12 between the gate electrodes 10a, 10b, and electrical connection between the contacts 14 and the high-concentration impurity diffusion layers 25 can be secured. Hence, the manufacturing yield of a miniaturized semiconductor device can be increased.

In the present example embodiment, the floating gate electrodes and the control gate electrodes can be formed in a self-aligned manner. This may facilitate formation of both of them more than separate formation of each of them. Hence, further miniaturization may be achieved by this method.

In the present example embodiment, the buried bit line oxide films 9 are formed with the first polycrystalline silicon film 10a formed for preparation. This can facilitate height adjustment, and can achieve highly precise control on the yield when compared with the case in the first example embodiment.

In the present example embodiment, the mask film 2 for forming the source/drain regions 5 is made of silicon nitride. Rather than silicon nitride, an insulating film made of a silicon compound, such as silicon oxide or the like may be used. In forming the source/drain regions 5, a resist material may be used as a mask without using the mask film made of a silicon compound.

In the present example embodiment, the film thickness of the tunneling film 17 is set at 10 nm as one example. The film thickness thereof may be adjusted appropriately within the range between 5 nm and 30 nm so as to optimize the characteristics of the memory element.

Each height of the first polycrystalline silicon film 10a and the buried oxide films 9 is set at 50 nm as an example in the present example embodiment, but may be appropriately adjusted in the range between 20 nm and 100 nm so as to optimize the leakage current between the gate electrodes 10a, 10b and the source or the drains and the charge accumulation amount.

Further, in the present example embodiment, the width of the n-type impurity diffusion layers is set at 100 nm as an example. It may be adjusted within the range between 50 nm and 300 nm so as to optimize the transistor characteristics.

The resist material is used as the mask for dry etching the first and second polycrystalline silicon films 10a, 10b in the present example embodiment. It may be inferred that higher etching selectivity is required in a process for higher integration. In such a case, a mask of a silicon oxide film or a silicon nitride film, or a mask of a stacked film of them and the resist material may be employed.

The second polycrystalline silicon film 10b forming the gate electrodes 10b is deposited as doped polysilicon in the present example embodiment. Alternatively, an impurity may be doped after non-doped polysilicon with which no impurity is doped is deposited. The polycrystalline silicon films are only examples as a material of the gate electrodes, and may be replaced by a single layer film or a stacked film of any of polysilicon, amorphous silicon, high-melting point metal having a melting point equal to or higher than 600° C., such as tantalum, titanium, and the like, a metal compound, and metal silicide. Alternatively, the second polycrystalline silicon film 10b forming the word lines 9 may be silicided by metal.

In the present example embodiment, a silicon oxide film and a silicon nitride film by LPCVD are used as an example of, but does not limit, the films buried and filled between the word lines. Any insulating film is applicable which is excellent in step coverage and which is capable of being formed without using plasma. However, high integration of a semiconductor memory element including floating gate electrodes increases the capacity between the floating gate electrodes to invite remarkable characteristics degradation. Therefore, this case requires burying and filling of a low dielectric material.

A memory element of which source/drain regions 5 are n-type is referred to in the present example embodiment. The memory element may be p-type, of course.

In the present example embodiment, the side and bottom surfaces of the n-type impurity diffusion layers forming the source/drain regions 5 may be covered with a p-type impurity diffusion layer having an impurity concentration lower than that of the n-type impurity diffusion layers. With this configuration, the p-type impurity diffusion layer can suppress the short channel effect caused due to impurity diffusion in the n-type diffusion layers, and the spaces between the sources and the drains in the source/drain regions 5 can be minimized, thereby enabling reduction in gate length. Hence, further miniaturization of the nonvolatile semiconductor memory device can be implemented.

### Fourth Example Embodiment

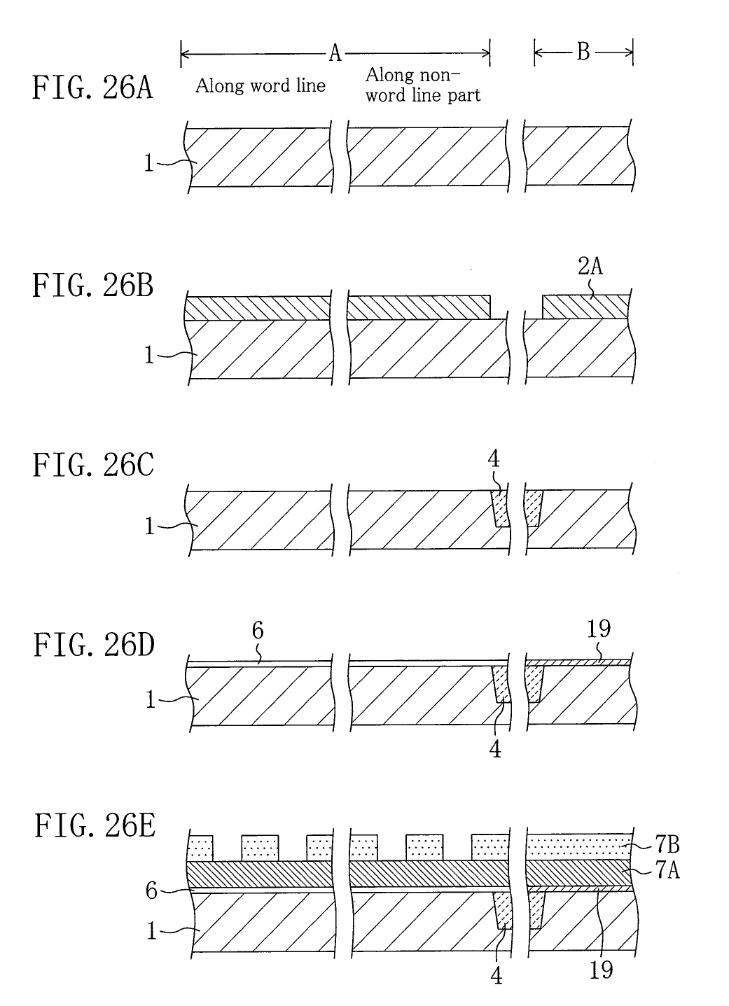

Description will be given below of a nonvolatile semiconductor memory device and a manufacturing method thereof in accordance with the fourth example embodiment of the present invention with reference to FIGS. 26 to 29.

The nonvolatile semiconductor memory device in accordance with the fourth example embodiment of the present invention includes a memory element part A including memory cell transistors according to the first example embodiment, and a logic circuit part B including a peripheral circuit and the like.

First of all, as shown in FIG. 26B, a mask formation film 2A of silicon nitride with a thickness of, for example, about 100 nm to 300 nm is formed on the principal surface of a semiconductor substrate 1 of silicon shown in FIG. 26A.

Next, as shown in FIG. 26C, isolation regions 4 are formed by STI or the like in the semiconductor substrate 1 to define the principal surface of the semiconductor substrate 1 into the memory element part A and the logic circuit part B. In general, the logic circuit part B includes an n-channel transistor and a p-channel transistor. Difference between the transistors is only difference in conductivity type of the impurity ions doped therewith, and therefore, only the n-channel transistor is indicated herein.

Subsequently, as shown in FIG. 26D, a trap film 6 with a thickness of 20 nm made of an ONO film and having a charge capturing site is deposited entirely. The uppermost oxide film of the ONO film may be formed thin by a film thickness corresponding to the film thickness of a gate oxide film in the case where it is formed simultaneously with the gate oxide film in the logic circuit part B in a later step. Then, the trap film 6 deposited on the logic circuit part B is removed, and a gate oxide film 19 with a thickness of 3 nm is formed entirely.

Thereafter, as shown in FIG. 26E, a mask formation film 7A of silicon nitride with a thickness of about 50 nm to 200 nm is deposited by LPCVD, for example. Then, after coating a resist film 7B on the mask formation film 7A, an opening pattern open at parts corresponding to source/drain regions 5 is formed in the resist film 7B by lithography. Herein, the openings have a width of 100 nm, which is the width of regions to be the source/drain regions 5. Referring to the width of the resist film 7B, which is 150 nm, it corresponds to the channel width where the memory cell transistors are formed.

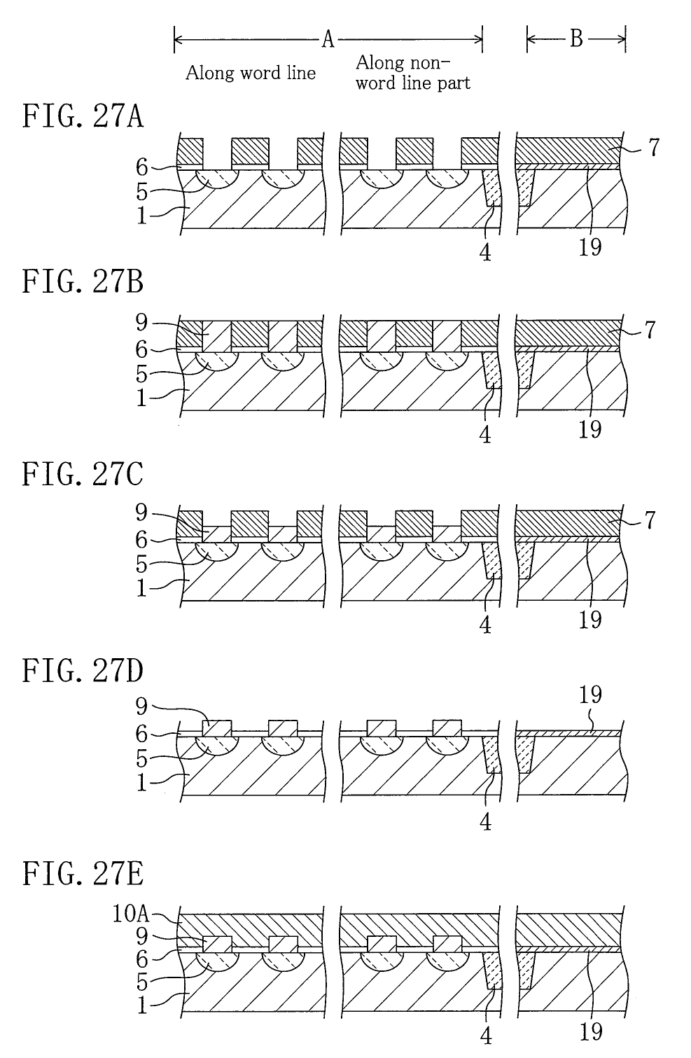

Next, as shown in FIG. 27A, dry etching using the resist film 7B (not shown) as a mask is performed on the mask formation film 7A to form, from the mask formation film 7A, a mask film 7 having openings for forming the source/drain regions 5, and subsequently, the trap film 6 in the openings is removed. Using the mask film 7 thus formed, for example, arsenic, as an n-type impurity is implanted at an acceleration energy of 5 keV to 200 keV with a dosage of 1×10¹⁴ cm⁻² to 1×10¹⁷ cm⁻² one time or two or more time to form the source/drain regions 5 of n-type impurity diffusion layers in the memory element part A. Then, the resist film 7B is removed.

Subsequently, as shown in FIG. 27B, an insulating film (to be buried oxide films) 9 of silicon oxide is filled and deposited in the openings of the mask film 7 by HDPCVD, LPCVD, or the like, and the silicon oxide film other than its part filled in the openings of the mask film 7 is removed selectively by CMP or etching back, for example.

Thereafter, as shown in FIG. 27C, wet etching or dry etching back is performed to adjust the height of the insulating film 9 from the semiconductor substrate 1 to be 50 nm.

Next, as shown in FIG. 27D, wet etching or dry etching back is performed to selectively remove only the mask film 7, thereby exposing the trap film 6 and forming the buried oxide films 9 in the memory element part A. At the same time, the gate oxide film 19 is exposed in the logic circuit part B.

Subsequently, as shown in FIG. 27E, LPCVD, for example, is performed to deposit a polycrystalline silicon film 10A, with which phosphorous as an n-type impurity of 1×10¹⁸ cm⁻³ to 1×10²² cm⁻³ is doped, on the trap film 6, the buried oxide films 9, and the gate oxide film 19.

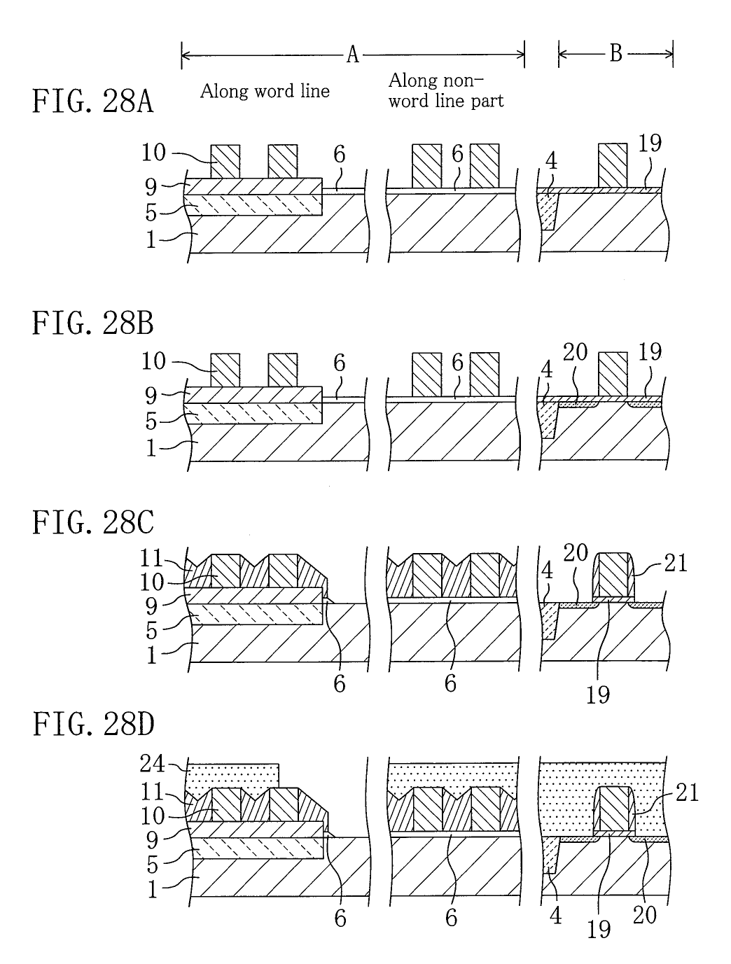

Thereafter, as shown in FIG. 28A, after coating a resist film (not shown), a resist pattern is formed in the direction of the word lines across source/drain formation regions arranged at intervals in the memory element part A by lithography. At the same time, a resist pattern is formed for a logic circuit in the logic circuit part B. Then, dry etching using the resist pattern as a mask is performed to form openings in predetermined regions of the polycrystalline silicon film 10A, thereby exposing the trap film 6 from the openings thus formed in the memory element part A, and exposing the gate oxide film 19 in the logic circuit part B. Thus, gate electrodes 10 of polycrystalline silicon film 10A are formed. In FIG. 28A, the gate electrodes 10 are formed so that the sidewalls thereof have an angle of approximately 90×1° relative to the semiconductor substrate 1. Alternatively, the upper parts of the sidewalls may be tapered or rounded at an angle of about 84°. Then, the resist film is removed.

Next, as shown in FIG. 28B, a resist film (not shown) having an opening pattern for exposing the logic circuit part B is formed on the semiconductor substrate 1, and an n-type ion impurity is implanted into the logic circuit part B with the use of the resist film thus formed and the gate electrodes 10 as a mask to form low-concentration impurity diffusion layers 20 on the respective sides of the gate electrodes 10 in the logic circuit part B of the semiconductor substrate 1. Then, the resist film is removed.

Subsequently, as shown in FIG. 28C, CVD is performed to deposit a silicon oxide film with a thickness of about 5 nm to 100 nm and a silicon nitride film with a thickness of about 30 nm to 100 nm, for example, on the entirety of the semiconductor substrate 1. Etching back is performed to remove the insulating film on the tops of the gate electrodes 10 with the insulting film left on the side surfaces of the gate electrodes 10. Further removed are the gate oxide film 19 in the logic circuit part B, and part of the insulating film and part of the trap film 6 in the bit line contact parts 13 in the memory element part A. Whereby, sidewall insulating films 21 are formed on the respective sides of the gate electrodes 10 in the logic circuit part B, while buried films 11 are formed between the word lines in the memory element part A.

The etching rate in this time is set to correspond to a time period required for removing only the insulating film on the tops of the gate electrodes 10, and the gate oxide film 19 in the logic circuit part B. This may cause substantially no removal of the insulating films buried between the gate electrodes 10 in the memory element part A to form ignorable projections and depressions on the memory cells. Appropriate adjustment of the overetching in the logic circuit part B may decrease variations in width of the sidewall insulating films 21, thereby enabling suppression of variations in transistor characteristics. For example, the etching rate is preferably set so that height difference between the top surfaces of the gate electrodes 10 and the top surface of the insulating films buried between the gate electrodes 10 is equal to or smaller than 100 nm.

Thereafter, as shown in FIG. 28D, a resist pattern 24 is formed in the memory element part A for selectively exposing the sidewall insulating films (the buried films 11) at the boundary word lines closest to the bit line contact regions and the trap film 6.

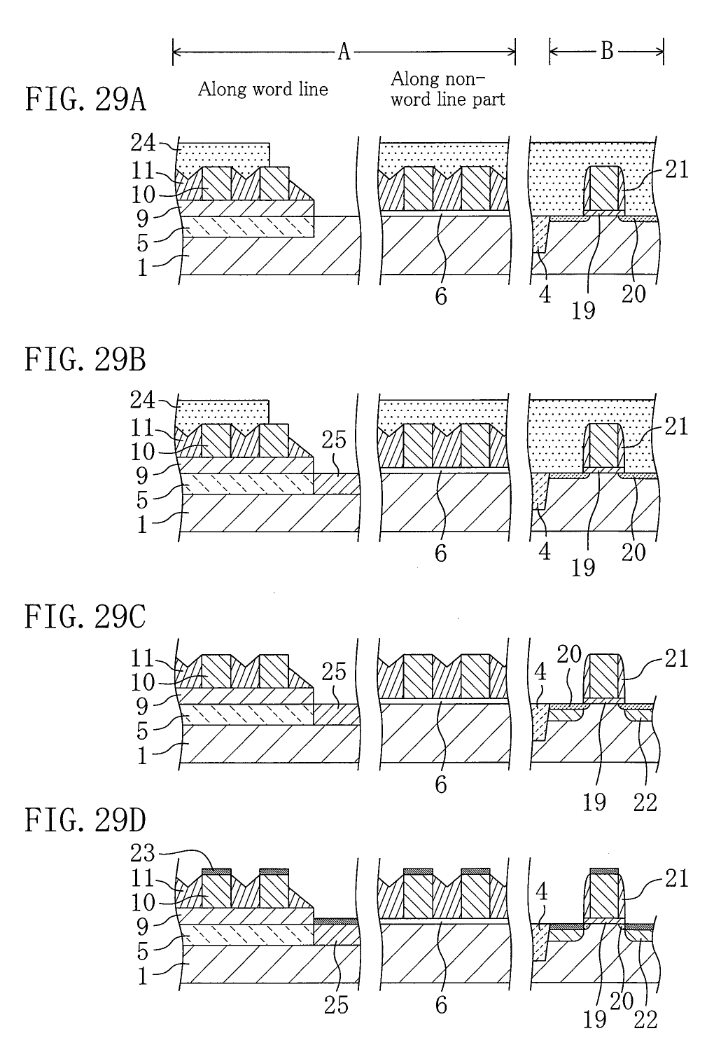

Next, as shown in FIG. 29A, dry etching is performed to remove the trap film 6 in the openings of the resist pattern 24 and to etch part of the sidewall insulating films (the buried films 11) of the boundary word lines. By this step, the sidewall insulating films (the buried films 11) of the boundary word lines are processed so as to be decrease in width as the etching for removing the trap film 6 progresses, in other words, so as to expand the opening regions of the semiconductor substrate 1 in the openings.

Subsequently, as shown in FIG. 29B, ion implantation of, for example, arsenic as an n-type impurity is performed one time or two or more times under implantation conditions of 5 keV to 200 keV acceleration energy and 1×10¹⁴ cm² to 1×10¹⁷ cm⁻² dosage to form high-concentration impurity diffusion layers 25 of n-type impurity diffusion layers in the bit line contact regions. The high-concentration impurity diffusion layers 25 are electrically connected to the source/drain regions 5 formed below the buried bit line oxide films 9. Then, the resist pattern 24 is removed.

Thereafter, as shown in FIG. 29C, a resist film (not shown) having an opening pattern for exposing the logic circuit part B is formed on the semiconductor substrate 1, and an n-type impurity ion is implanted selectively to the semiconductor substrate 1 with the use of the resist film thus formed, the gate electrodes 10, and the sidewall insulating films 21 as a mask to form high-concentration impurity diffusion layers 22 to be drain regions or source regions. The high-concentration impurity diffusion layers 22 in the logic circuit part B may be formed before forming the high-concentration diffusion layers 25 of the bit line contact parts 13 in the memory element part A shown in FIG. 28D to 29B.

Next, as shown in FIG. 29D, a metal film of cobalt, nickel, or the like is deposited on the entirety of the semiconductor substrate 1 by vacuum deposition, or the like, for example, and thermal treatment is performed. Thus, a meal silicide layer 23 is formed in the upper parts of the word lines 10 and the upper parts of the high-concentration impurity diffusion layers 25 of the bit line contact parts 13 in the memory element part A, while being formed in the upper parts of the gate electrodes 10 and the upper parts of the high-concentration impurity diffusion layers 22 in the logic circuit part B.

Although the steps thereafter will not be shown, as described in the first example embodiment, an interlayer insulating film of silicon oxide is deposited on the entirety of the semiconductor substrate 1 by CVD, for example, and then, a plurality of connection holes are formed selectively in the interlayer insulating film for exposing the metal silicide layer in the upper parts of the bit line contact parts by lithography and etching.

Subsequently, a conductive film of a single layer or stacked metal film is deposited entirely on the interlayer insulating film to fill the connection holes. The single layer or stacked metal film may be made of tungsten, a tungsten compound, titanium, a titanium compound of titanium nitride, or the like. Then, the conductive film thus deposited is patterned so that the source/drain regions 5 disposed in the line direction are connected to each other, thereby forming bit lines from the conductive film.

Thus, a nonvolatile semiconductor memory device including the logic circuit part B and the memory element part A, which has the same configuration as that in the first example embodiment, can be obtained.

Hence, the nonvolatile semiconductor memory device in accordance with the present example embodiment can obtain the same various effects as those described in the first example embodiment.

Since the word lines (the gate electrodes) 10 in the memory element part A and the gate electrodes 10 in the logic circuit part B can be formed in a single step, the number of steps can be reduced.

Variations can be suppressed in width of the sidewall insulating films 21 of the gate electrodes 10 of the transistors in the logic circuit part B to suppress variations in transistor characteristics. Hence, high yield can be achieved.

In the present example embodiment, the dry etching on the polycrystalline silicon film is stopped at the time point when the height of the openings becomes equal to the height of the buried oxide films. As long as the step is stopped at the time point when the openings become at a height within the range of about 30 nm above or below the height of the buried oxide films, etching residue can be removed substantially. Accordingly, no problem can be involved

The polycrystalline silicon film forming the word lines 10 in the memory element part A and forming the gate electrodes 10 in the logic circuit part B is deposited as doped polysilicon in the present example embodiment. Alternatively, an impurity may be implanted after non-doped polysilicon with which no impurity is doped is deposited. The polycrystalline silicon film is only one example, and may be replaced by a single layer film or a stacked film of any of polysilicon, amorphous silicon, high-melting point metal having a melting point equal to or higher than 600° C., such as tantalum, titanium, and the like, a metal compound, and metal silicide. Alternatively, the polycrystalline silicon film 10A forming the word lines 10 may be silicided by metal.

In the present example embodiment, a silicon oxide film and a silicon nitride film by CVD are used as films buried and filled between the word lines 10, as an example. Any insulating film can be preferably used which is excellent in step coverage and capable of being formed by film formation using no plasma. However, a film is desirable which can be deposited in the form required for formation of the sources and the drains by using sidewalls formed by a self-alignment technique in the logic circuit part B.

In the present example embodiment, the surfaces of parts in contact with the bit line contacts in the source/drain regions 5 of the memory element may be silicided by metal.

### Fifth Example Embodiment

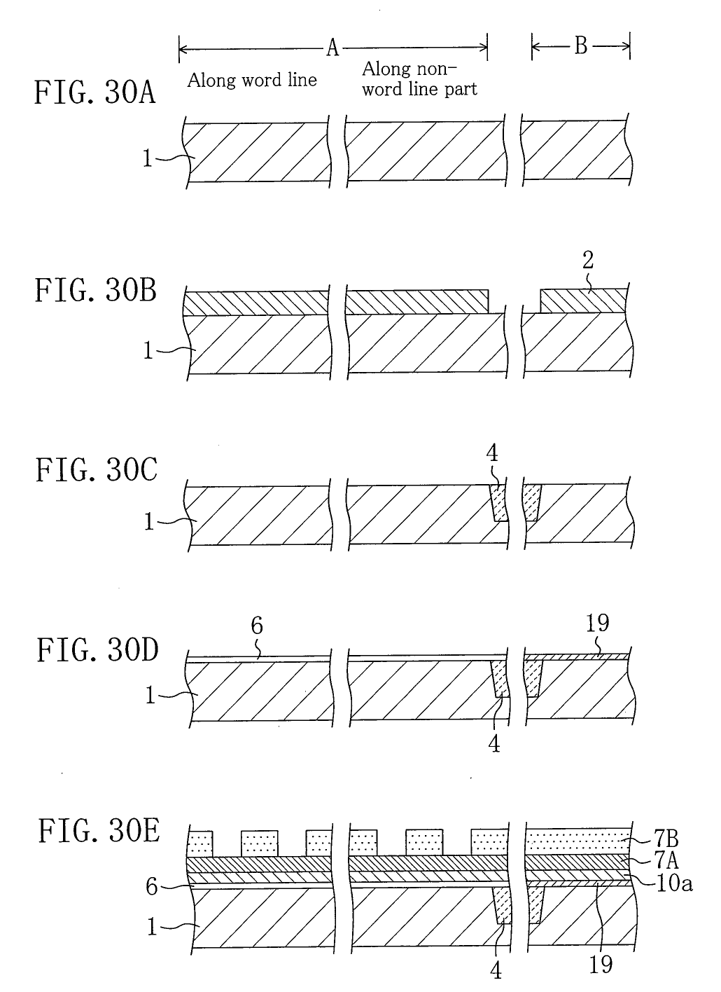

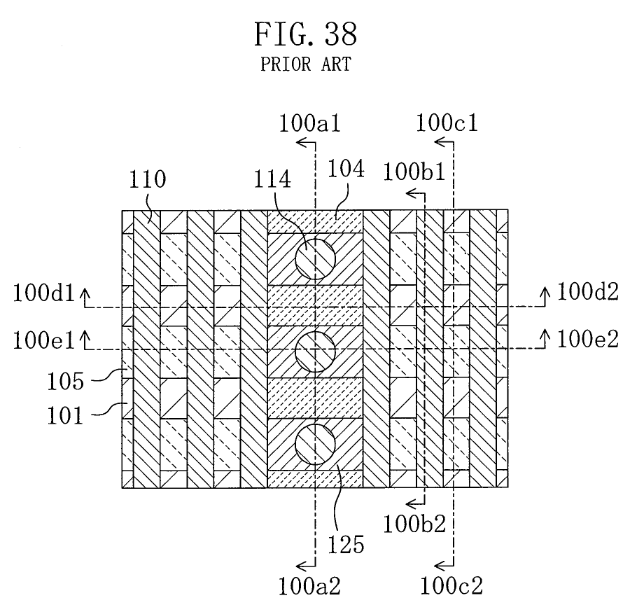

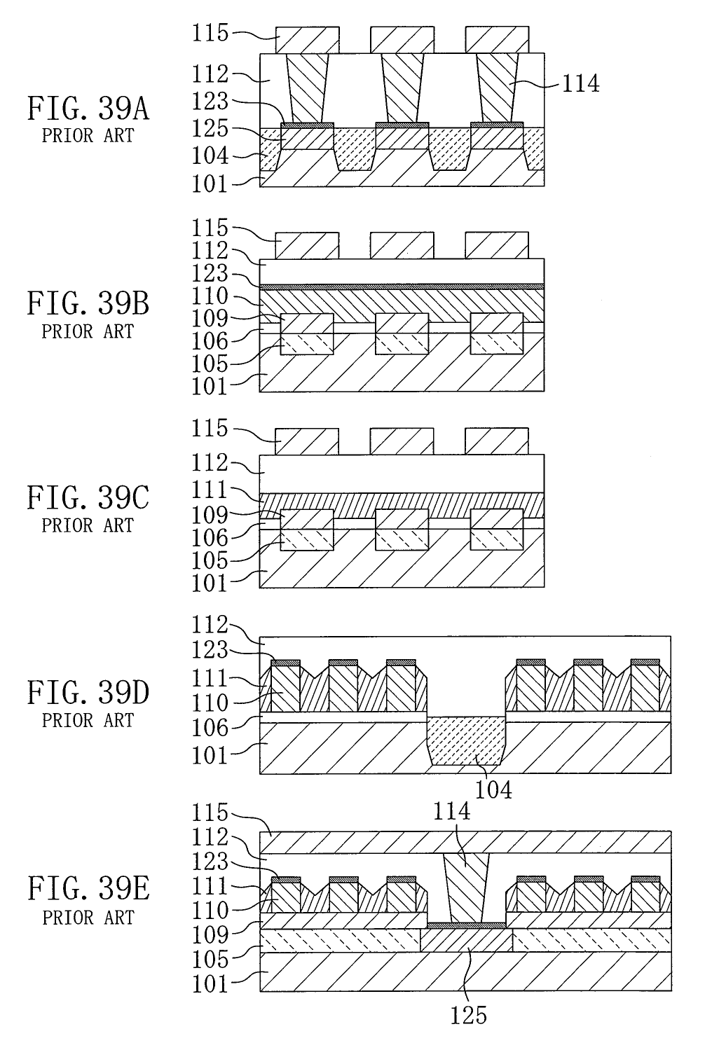

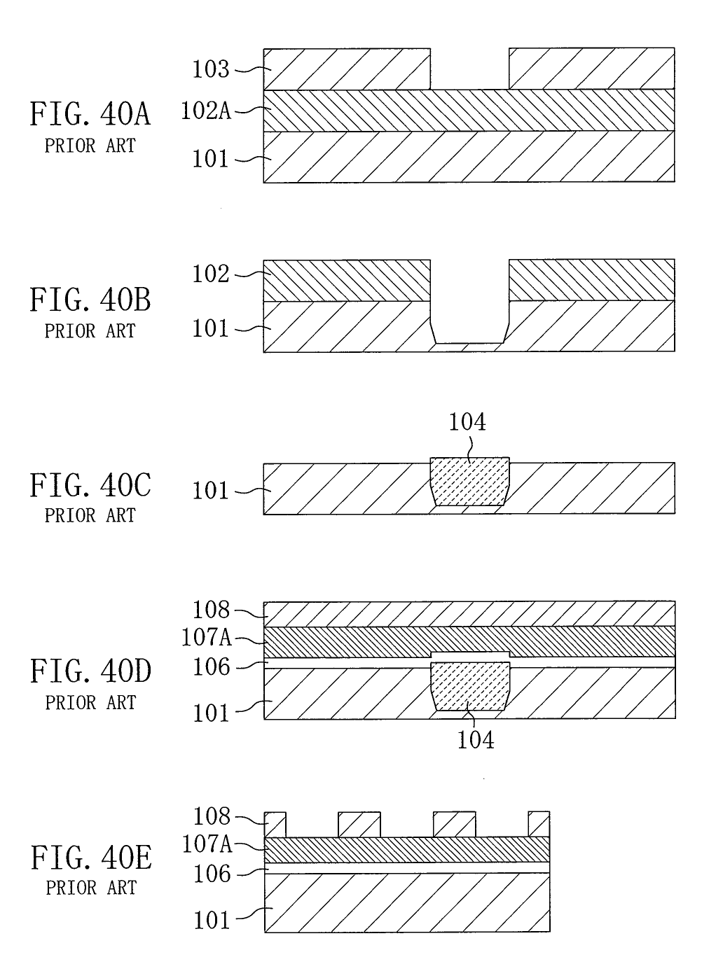

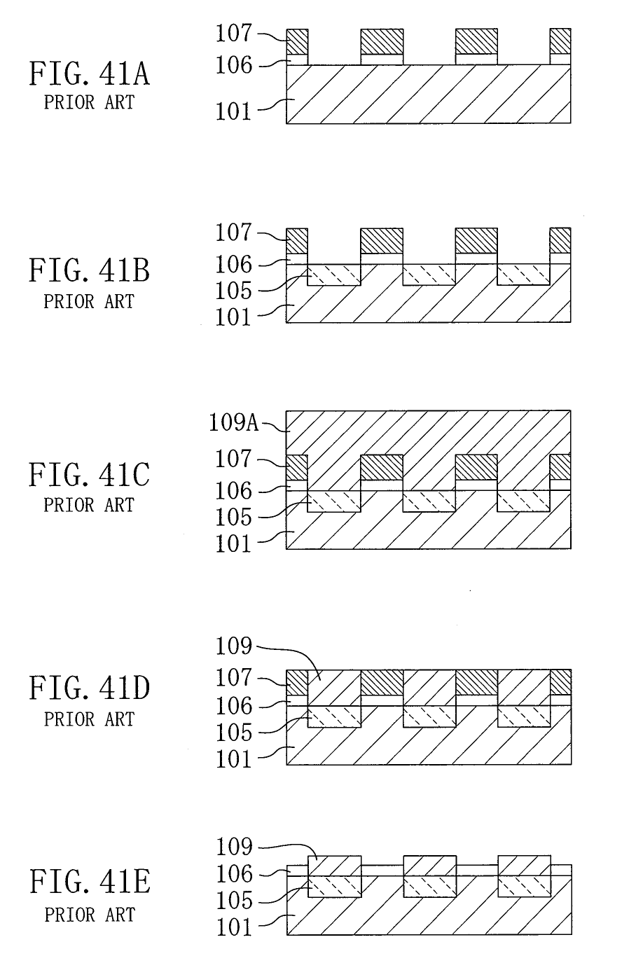

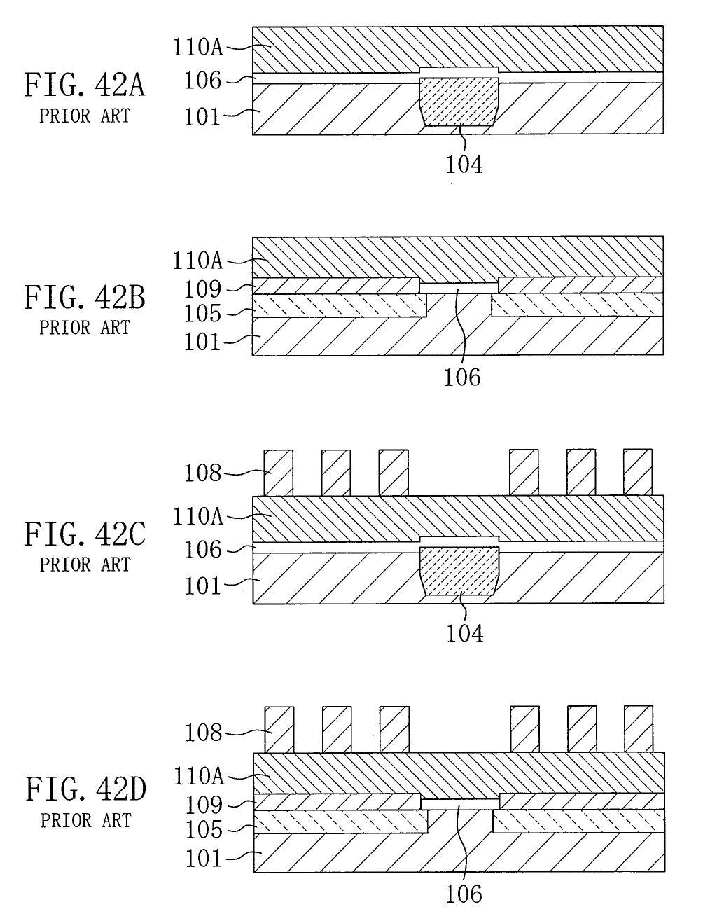

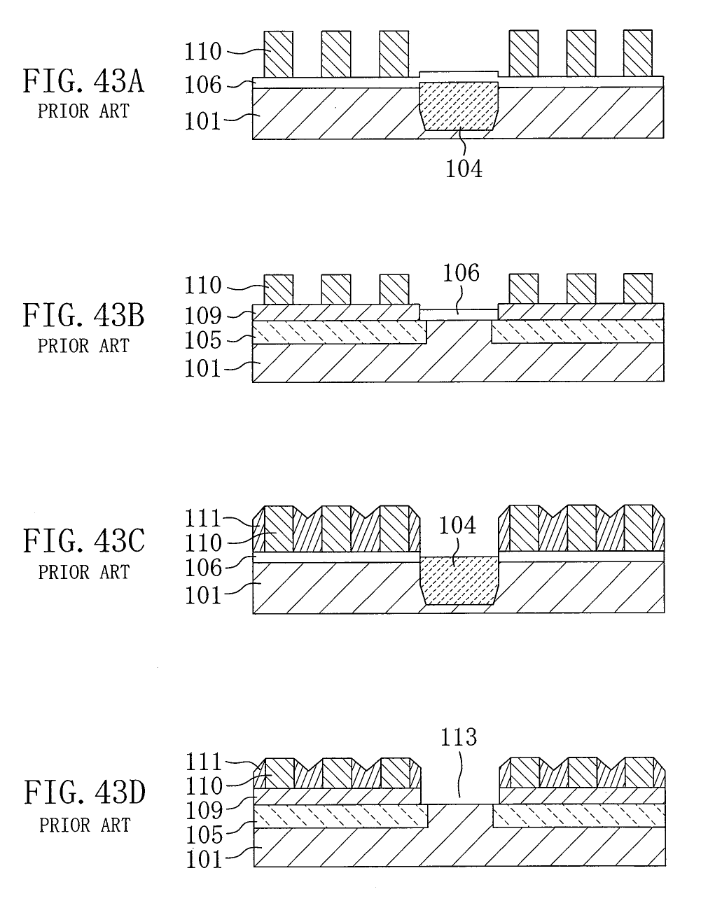

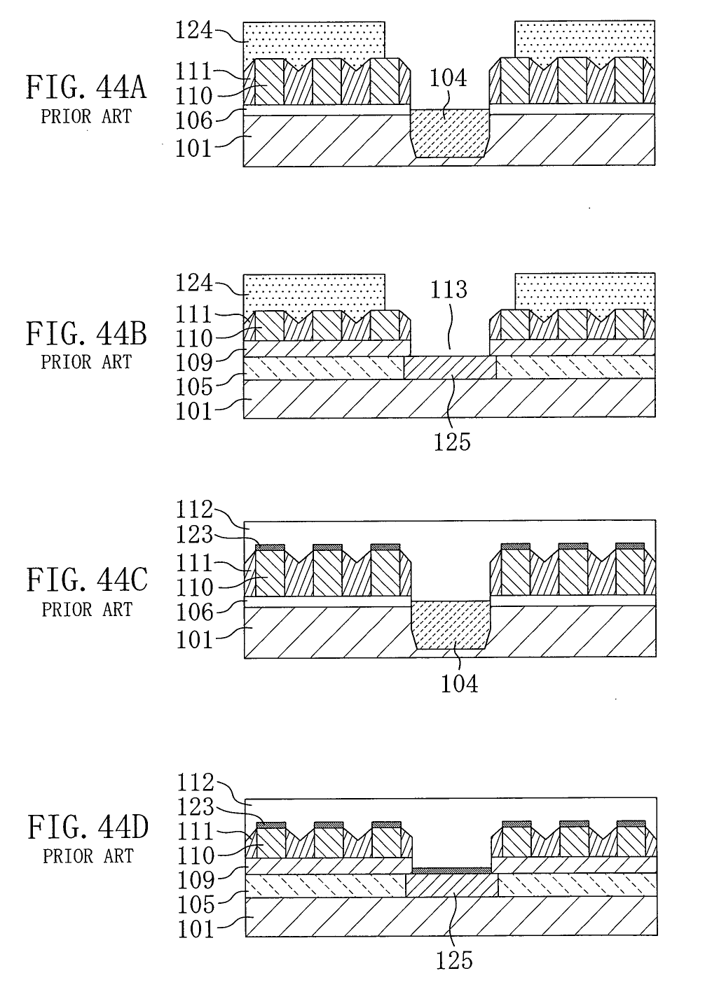

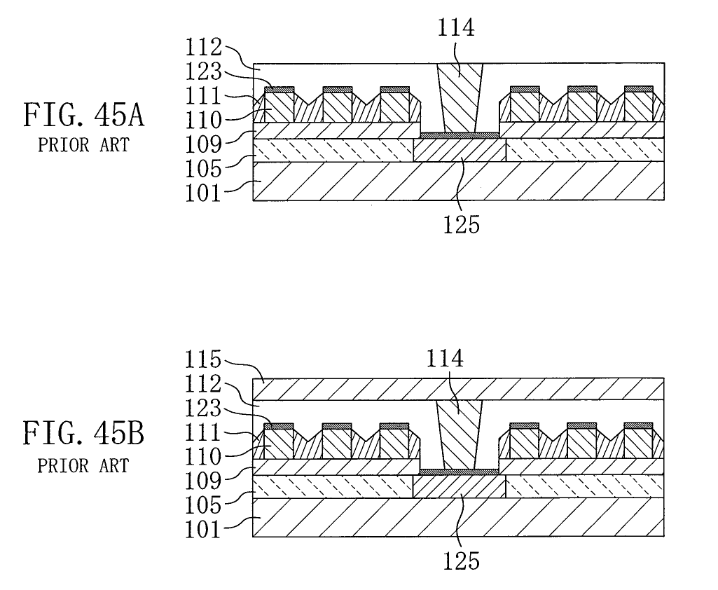

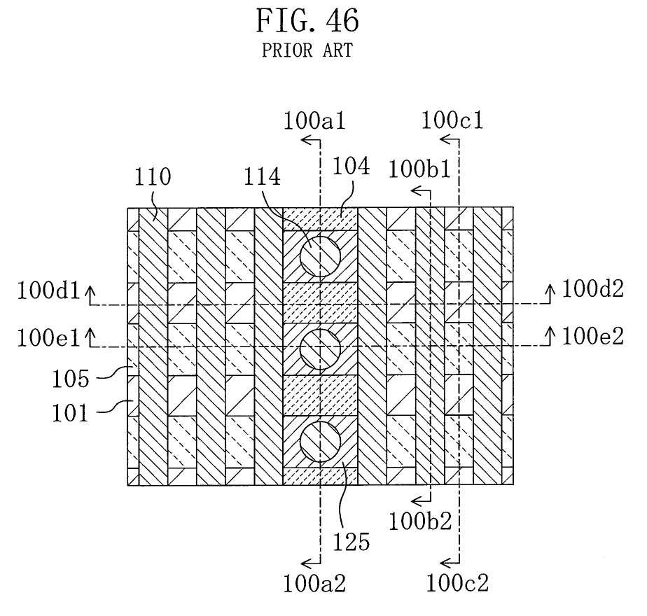

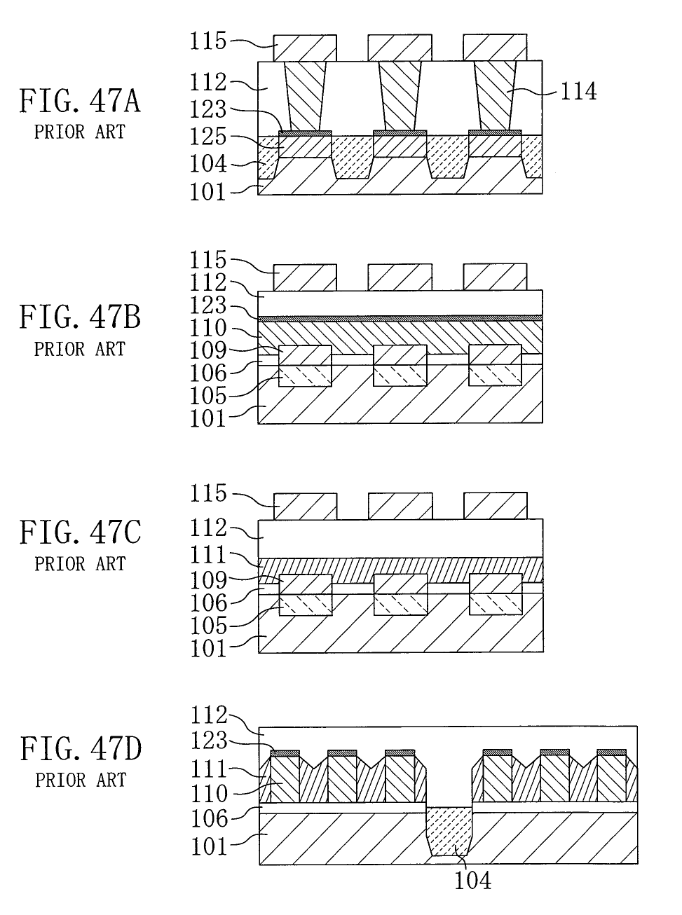

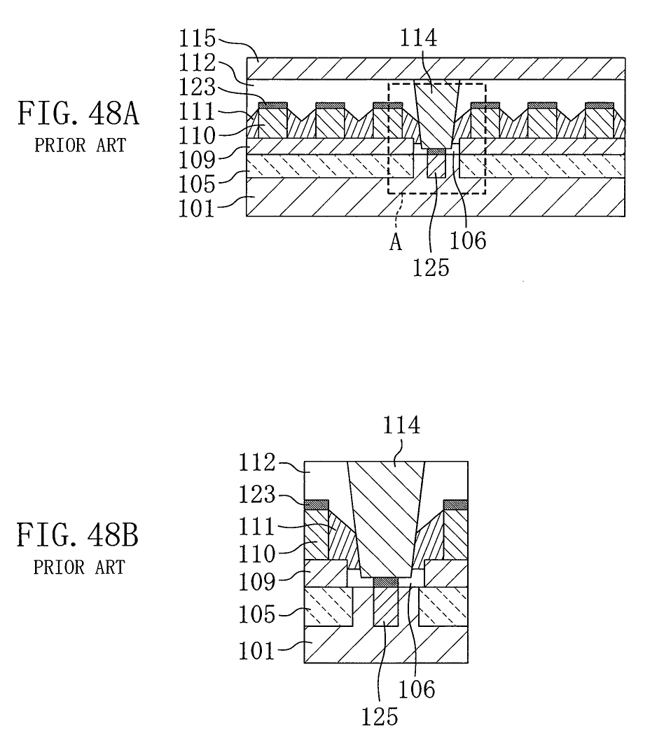

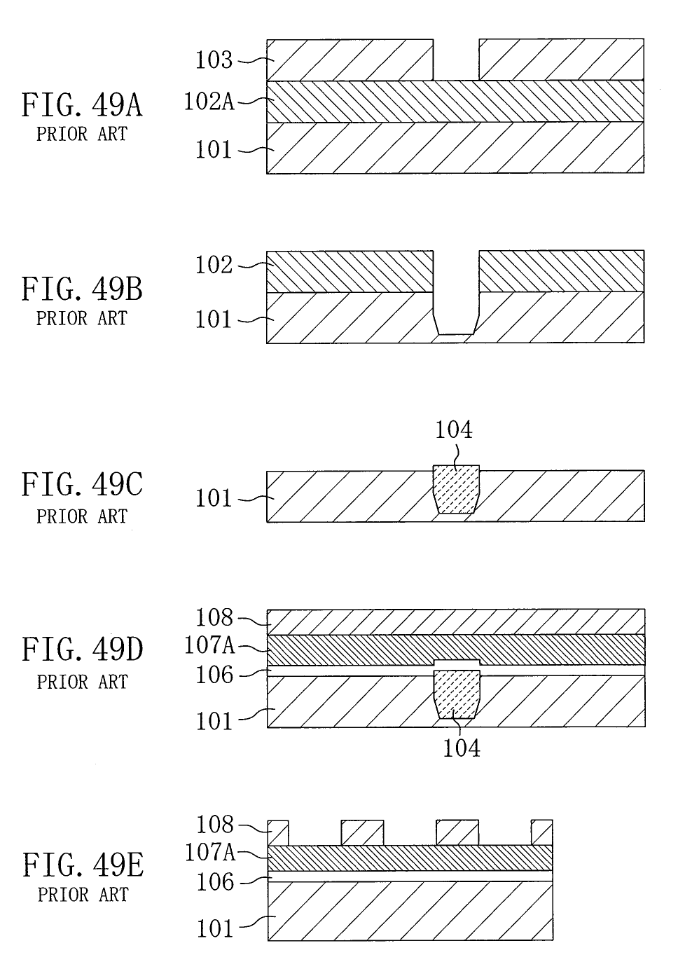

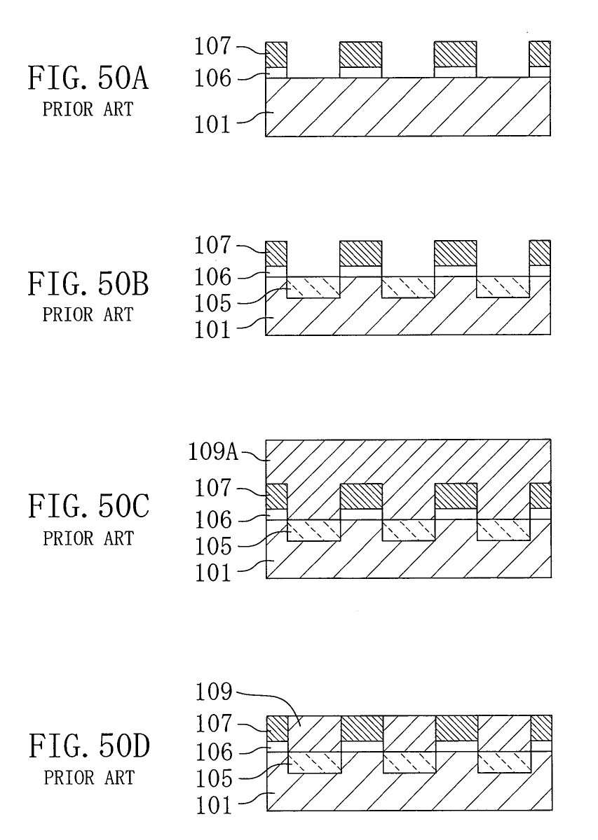

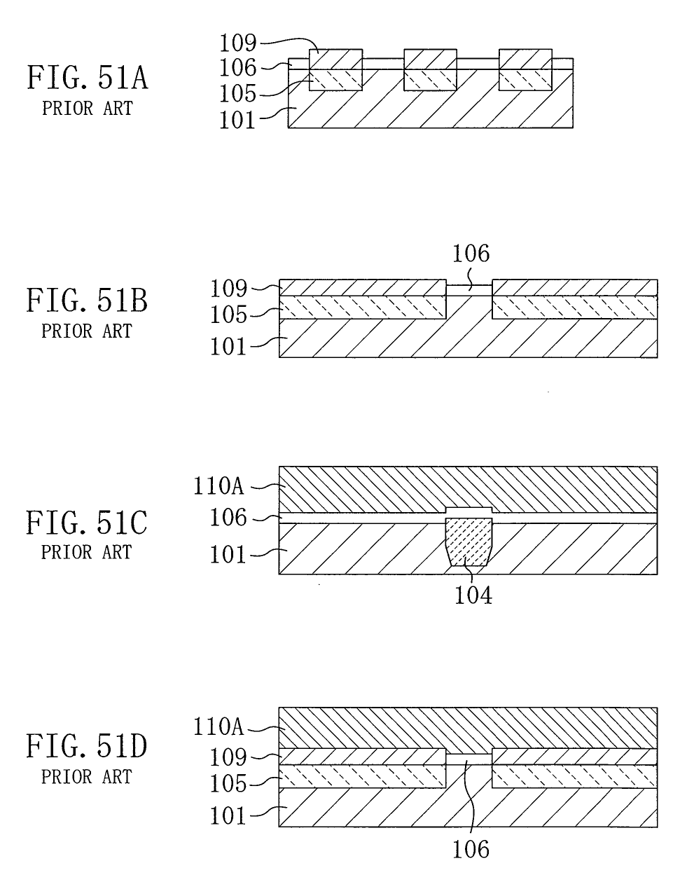

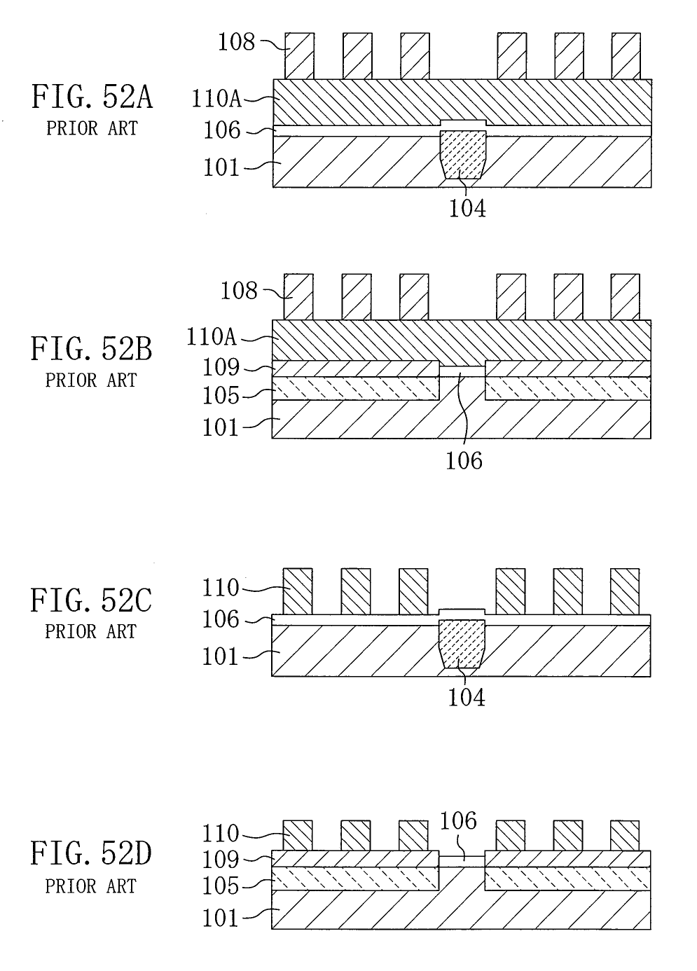

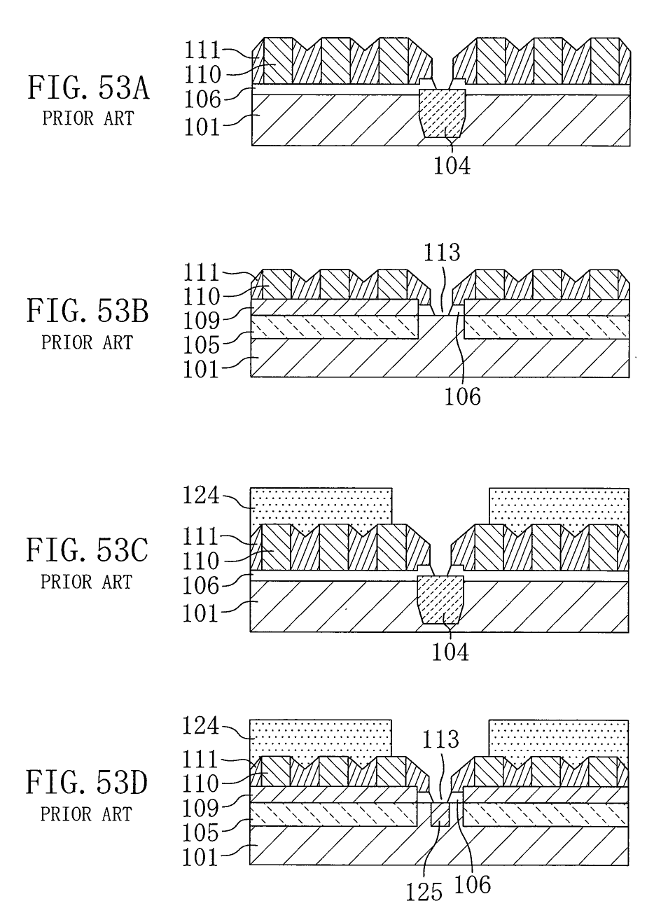

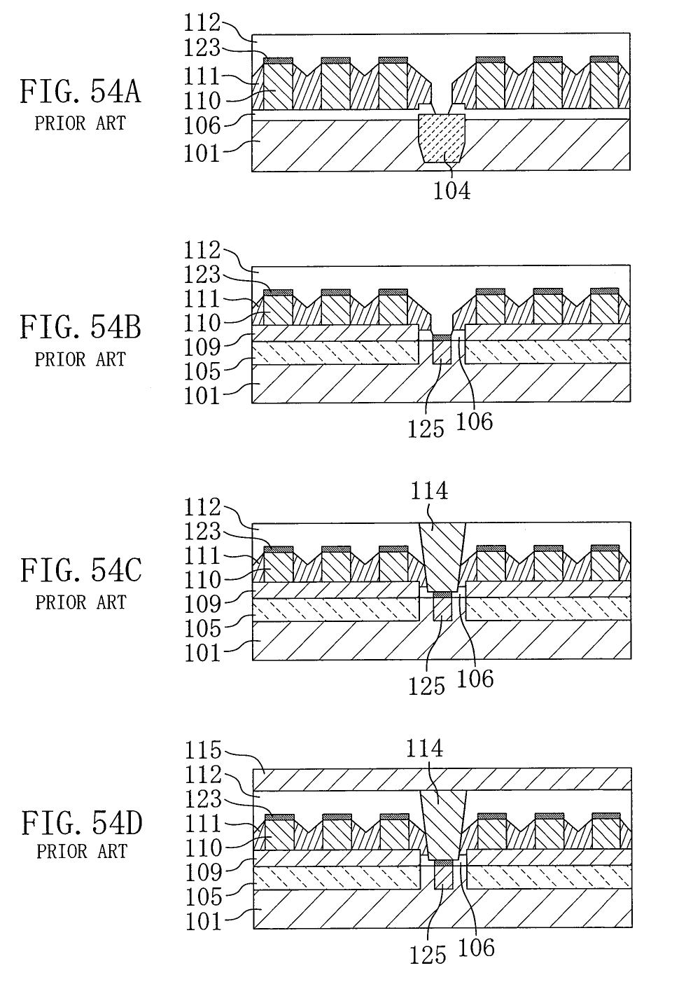

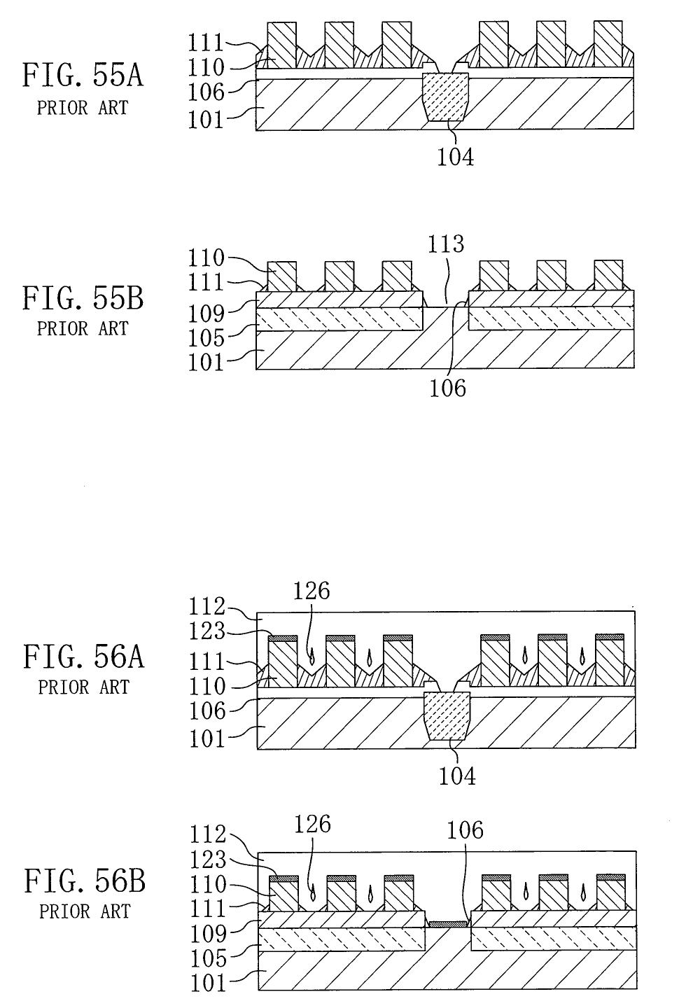

Description will be given below of a nonvolatile semiconductor memory device and a manufacturing method thereof in accordance with the fifth example embodiment of the present invention with reference to FIGS. 30 to 39.

The nonvolatile semiconductor memory device in accordance with the fifth example embodiment of the present invention includes a memory element part A including memory cell transistors according to the second example embodiment, and a logic circuit part B including a peripheral circuit and the like.

First, as shown in FIG. 30B, a mask formation film 2A of silicon nitride with a thickness of, for example, about 100 nm to 300 nm is formed on the principal surface of a semiconductor substrate 1 of silicon shown in FIG. 30A.

Next, as shown in FIG. 30C, isolation regions 4 are formed by STI or the like in the semiconductor substrate 1 to define the principal surface of the semiconductor substrate 1 into the memory element part A and the logic circuit part B. In general, the logic circuit part B includes an n-channel transistor and a p-channel transistor. Difference between the transistors is only difference in conductivity type of the impurity ions doped therewith, and therefore, only the n-channel transistor is indicated herein.

Subsequently, as shown in FIG. 30D, a trap film 6 with a thickness of 20 nm made of an ONO film and having a charge capturing site is deposited entirely. The uppermost oxide film of the ONO film may be formed thin by a film thickness corresponding to the film thickness of a gate oxide film in the case where it is formed simultaneously with the gate oxide film in the logic circuit part B in a later step. Then, the trap film 6 deposited on the logic circuit part B is removed, and a gate oxide film 19 with a thickness of 3 nm is formed entirely.

Thereafter, as shown in FIG. 30E, a first polysilicon 10a with a thickness of about 20 nm to 80 nm is formed by, for example, CVD, and a thin silicon oxide film (not shown) with a thickness of approximately 10 nm is deposited. Then, a mask formation film 7A of silicon nitride with a thickness of about 50 nm to 200 nm is deposited. After coating a resist film 7B on the mask formation film 7A, an opening pattern open at parts corresponding to source/drain regions 5 is formed in the resist film 7B by lithography. Herein, the openings have a width of 100 nm, which corresponds to the width of the source/drain regions. On the other hand, the width of the resist 7B is 150 nm, which corresponds to the channel width where the memory cell transistors are formed.

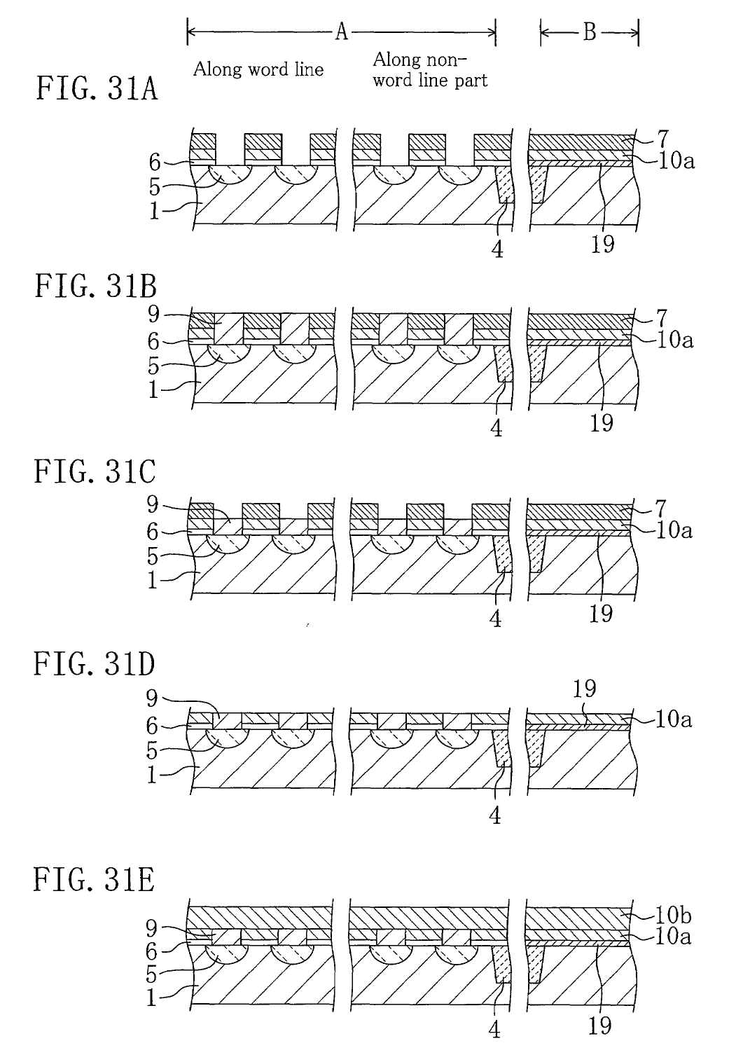

Next, as shown in FIG. 31A, dry etching using the resist film 7B (not shown) as a mask is performed on the mask formation film 7A to form, from the mask formation film 7A, a mask film 7 having openings for forming the source/drain regions 5. Then, the silicon oxide film (not shown), the first polycrystalline silicon film 10a, and the trap film 6 in the openings are removed. The trap oxide film 6, which is thin, may be left for use as a protection film in ion implantation. Subsequently, using the mask film 7 thus formed, arsenic, for example, as an n-type impurity is implanted at an acceleration energy of 5 keV to 200 keV with a dosage of 1×10¹⁴ cm⁻² to 1×10¹⁷ cm⁻² one time or two or more time to form the source/drain regions 5 of n-type impurity diffusion layers in the memory element part A. Then, the resist film 7B is removed.

Subsequently, as shown in FIG. 31B, an insulating film (to be buried oxide films) 9 of silicon oxide is deposited in the openings of the mask film 7 by HDPCVD, LPCVD, or the like, and the silicon oxide film other than its part filled in the openings of the mask film 7 is removed selectively by CMP or etching back, for example.

Thereafter, as shown in FIG. 31C, wet etching or dry etching back is performed to adjust the height of the filled silicon oxide film to be almost equal to the height of the first polycrystalline silicon film 10a.

Next, as shown in FIG. 31D, wet etching or etching back is performed to selectively remove only the mask film 4 to form bit line buried oxide films 9. Whereby, the height of the bit line buried oxide films 9 is adjusted to be almost equal to the height of the polycrystalline silicon film 10a. This height adjustment is performed before selective removal of the mask film 7 in the present example embodiment, but may be preferably performed both before and after the selective removal thereof where further precision is required.

Subsequently, as shown in FIG. 31E, LPCVD, for example, is performed to deposit a second polycrystalline silicon film 10b, with which phosphorous as an n-type impurity of 1×¹⁸ cm⁻³ to 1×10²² cm⁻³ is doped, on the buried oxide films 9 and the first polycrystalline silicon film 10a. In this time point, a thin natural oxide film of about 1 nm may be formed at the interface between the first polycrystalline silicon film 10a and the second polycrystalline silicon film 10b. However, since the first polycrystalline silicon film 10a and the second polycrystalline silicon film 10b are connected electrically to each other, no problem may be involved in use as gate electrodes.

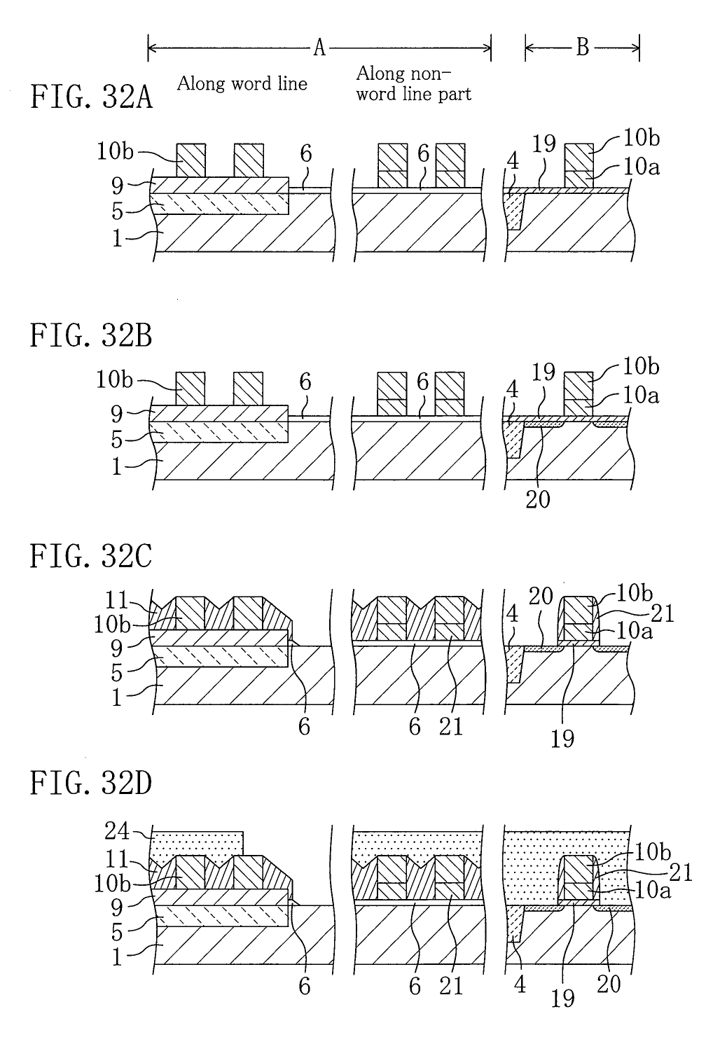

Thereafter, as shown in FIG. 32A, after coating a resist film (not shown), a resist pattern is formed in the direction of the word lines across source/drain formation regions arranged at intervals in the memory element part A by lithography. At the same time, a resist pattern for a logic circuit is formed in the logic circuit part B. Then, dry etching using the resist pattern thus formed as a mask is performed to form openings in predetermined regions of the first and second polycrystalline silicon films 10a, 10b, thereby exposing the trap film 6 from the openings thus formed in the memory element part A, and exposing the gate oxide film 19 in the logic circuit part B. In FIG. 32A, the gate electrodes 10a, 10b are shown which form an angle of approximately 90±1°. Alternatively, the gate electrodes 10b may be formed so that the sidewalls thereof incline at an angle of about 84°. Then, the resist film is removed.

Next, as shown in FIG. 32B, a resist film (not shown) having an opening pattern for exposing the logic circuit part B is formed on the semiconductor substrate 1, and an n-type ion is implanted into the logic circuit part B with the use of the resist film thus formed and the gate electrodes 10a, 10b as a mask to form low-concentration impurity diffusion layers 20 on the respective sides of the gate electrodes 10 in the logic circuit part B of the semiconductor substrate 1. Then, the resist film is removed.

Subsequently, as shown in FIG. 32C, CVD is performed to deposit a silicon oxide film with a thickness of about 5 nm to 100 nm and a silicon nitride film with a thickness of about 30 nm to 100 nm, for example, on the entirety of the semiconductor substrate 1. Etching back is performed to remove the insulating film on the tops of the gate electrodes 10b with the insulating film left on the side surfaces of the gate electrodes 10a, 10b. Further removed are the gate oxide film 19 in the logic circuit part B and part of the insulating film and part of the trap film 6 in the bit line contact parts 13 in the memory element part A. Whereby, sidewall insulating films 21 are formed on the respective sides of the gate electrodes 10a, 10b in the logic circuit part B, while buried films 11 are formed between the word lines in the memory element part A.

The etching rate in this time is set to correspond to a time period required for removing only the insulating film on the tops of the gate electrodes 10a, 10b, and the gate oxide film 19 in the logic circuit part B. This may cause substantially no removal of the insulating films buried between the gate electrodes 10a, 10b in the memory element part A to form ignorable projections and depressions on the memory cells. Appropriate adjustment of the overetching in the logic circuit part B may decrease variations in width of the sidewall insulating films 21, thereby enabling suppression of variations in transistor characteristics. For example, the etching rate is preferably set so that height difference between the top surfaces of the gate electrodes 10b and the top surfaces of the insulating films 11 buried between the gate electrodes 10a, 10b in the memory element part A is equal to or smaller than 100 nm.

Thereafter, as shown in FIG. 32D, a resist pattern 24 is formed in the memory element part A for selectively exposing the sidewall insulating films (the buried films 11) at the boundary word lines closest to the bit line contact regions and the trap film 6.

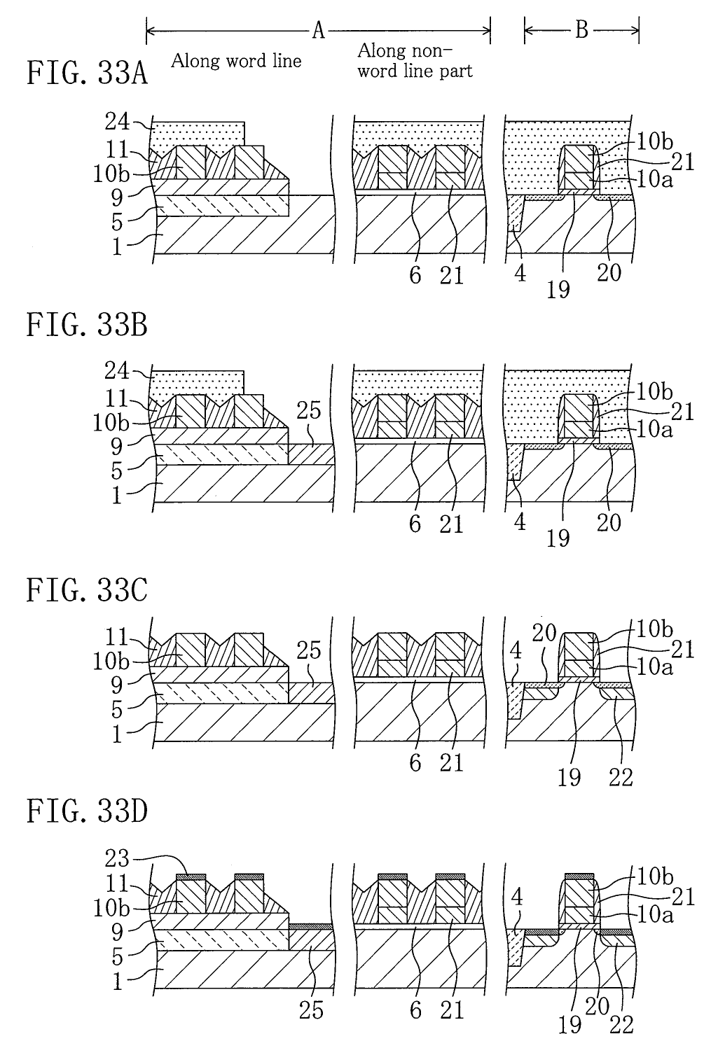

Next, as shown in FIG. 33A, dry etching is performed to remove the trap film 6 in the openings of the resist pattern 24, and to etch part of the sidewall insulating films (the buried films 11) of the boundary word lines. By this step, the sidewall insulating films (the buried films 11) of the boundary word lines are processed so as to decrease in width as the etching for removing the trap film 6 progresses, in other words, so as to expand the opening regions of the semiconductor substrate 1 in the openings.

Subsequently, as shown in FIG. 33B, ion implantation of, for example, arsenic as an n-type impurity is performed one time or two or more times under implantation conditions of 5 keV to 200 keV acceleration energy and 1×10¹⁴ cm⁻² to 1×10¹⁷ cm⁻² dosage to form high-concentration impurity diffusion layers 25 of n-type impurity diffusion layers in the bit line contact regions. The high-concentration impurity diffusion layers 25 are electrically connected to the source/drain regions 5 formed below the buried bit line oxide films 9. Then, the resist pattern 24 is removed.

Thereafter, as shown in FIG. 33C, a resist film (not shown) having an opening pattern for exposing the logic circuit part B is formed on the semiconductor substrate 1, and an n-type impurity ion is selectively implanted into the logic circuit part B with the use of the resist film thus formed, the gate electrodes 10a, 10b, and the sidewall insulating films 21 as a mask to form high-concentration impurity diffusion layers 22 to be drain regions or source regions. The high-concentration impurity diffusion layers 22 in the logic circuit part B may be formed before forming the high-concentration diffusion layers 25 of the bit line contact parts 13 in the memory element part A shown in FIG. 32D to 33B.

Next, as shown in FIG. 33D, a metal film of cobalt, nickel, or the like is deposited on the entirety of the semiconductor substrate 1 by, for example, vacuum deposition, or the like, and thermal treatment is performed. Thus, a meal silicide layer 23 is formed in the upper parts of first word lines (the first polycrystalline silicon film 10a) and second word lines (the second polycrystalline silicon film 10b), and the upper parts of the high-concentration impurity diffusion layers 25 of the bit line contact parts 13 in the memory element part A, while being formed in the upper parts of the gate electrodes 10b and the upper parts of the high-concentration impurity diffusion layers 22 in the logic circuit part B.

Although the steps thereafter will not be shown, as described in the second example embodiment, an interlayer insulating film of silicon oxide is deposited on the entirety of the semiconductor substrate 1 by CVD, for example, and then, a plurality of connection holes are formed selectively in the interlayer insulating film for exposing the metal silicide layer on the bit line contact parts by lithography and etching.

Subsequently, a conductive film of a single layer or stacked metal film is deposited entirely on the interlayer insulating film to fill the connection holes. The single layer or stacked metal film may be made of tungsten, a tungsten compound, titanium, a titanium compound of titanium nitride, or the like. Then, the conductive film thus deposited is patterned so that the source/drain regions 5 disposed in the line direction are connected to each other, thereby forming bit lines from the conductive film.

Thus, a nonvolatile semiconductor memory device including the logic circuit part B and the memory element part A, which has the same configuration as that in the second example embodiment, can be obtained.

Hence, according to the present example embodiment, the same various effects can be obtained as those described in the second example embodiment.

Since the word lines (the gate electrodes) 10a, 10b in the memory element part A and the gate electrodes 10a, 10b of the transistors in the logic circuit part B can be formed in a single step, the number of steps can be reduced.

Variations can be suppressed in width of the sidewall insulating films 21 of the gate electrodes 10a, 10b of the transistors in the logic circuit part B to suppress variations in transistor characteristics. Hence, high yield can be achieved.

In the present example embodiment, the dry etching on the polycrystalline silicon film is stopped at a time point when the height of the openings becomes equal to the height of the buried oxide films. As long as the step is stopped at the time point when the openings become at a height within the range of about 30 nm above or below the height of the buried oxide films, etching residue can be removed substantially. Accordingly, no problem can be involved

The polycrystalline silicon film 10b forming the word lines in the memory element part A and forming the gate electrodes in the logic circuit part B is deposited as doped polysilicon in the present example embodiment. Alternatively, an impurity may be implanted after non-doped polysilicon with which no impurity is doped is deposited. The polycrystalline silicon films 10a, 10b are only examples, and may be replaced by a single layer film or a stacked film of any of polysilicon, amorphous silicon, high-melting point metal having a melting point equal to or higher than 600° C., such as tantalum, titanium, and the like, a metal compound, and metal silicide. Alternatively, the second polycrystalline silicon film 10b forming the word lines may be silicided by metal.

In the present example embodiment, a silicon oxide film and a silicon nitride film by CVD are used as films buried and filled between the word lines 10, as an example. Any insulating film can be preferably used which is excellent in step coverage and capable of being formed by film formation using no plasma. However, a film is desirable which can be deposited in the form required for forming the sources and the drains by using sidewalls formed by a self-alignment technique in the logic circuit part B.

In the present example embodiment, the surfaces of parts in contact with the bit line contacts in the source/drain regions 5 of the memory element may be silicided by metal.

### Sixth Example Embodiment

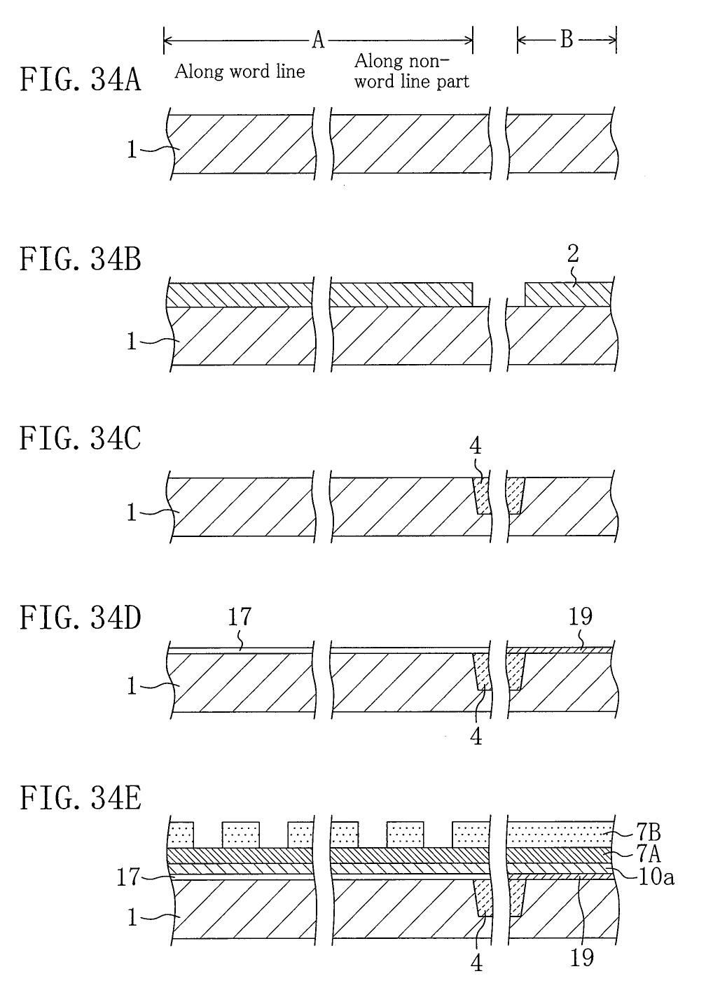

Description will be given below of a nonvolatile semiconductor memory device and a manufacturing method thereof in accordance with the sixth example embodiment of the present invention with reference to FIGS. 34 to 37.

The nonvolatile semiconductor memory device in accordance with the sixth example embodiment of the present invention includes a memory element part A including memory cell transistors according to the third example embodiment and a logic circuit part B including a peripheral circuit and the like.

First, as shown in FIG. 34B, a mask formation film 2A of silicon nitride with a thickness of, for example, about 100 nm to 300 nm is formed on the principal surface of a semiconductor substrate 1 of silicon shown in FIG. 34A.

Next, as shown in FIG. 34C, isolation regions 4 are formed by STI or the like in the semiconductor substrate 1 to define the principal surface of the semiconductor substrate 1 into the memory element part A and the logic circuit part B. In general, the logic circuit part B includes an n-channel transistor and a p-channel transistor. Difference between the transistors is only difference in conductivity type of the impurity ions doped therewith, and therefore, only the n-channel transistor is indicated herein.

Subsequently, as shown in FIG. 34D, a tunneling film 17 of a silicon oxide film with a thickness of 10 nm is deposited entirely. The tunneling film 17 may be thin by a film thickness corresponding to the film thickness of the gate oxide film 19 in the case where it is formed with a stacked film and is formed simultaneously with the gate oxide film 19 in the logic circuit part B in a later step. Then, the tunneling film 17 deposited in the logic circuit part B is removed, and the gate oxide film 19 with a thickness of 3 nm is formed entirely.

Thereafter, as shown in FIG. 34E, a first polysilicon 10a with a thickness of about 20 nm to 80 nm is formed by, for example, CVD, and a thin silicon oxide film (not shown) with a thickness of approximately 10 nm is deposited. Then, a mask formation film 7A of silicon nitride with a thickness of about 50 nm to 200 nm is deposited. After coating a resist film 7B on the mask formation film 7A, an opening pattern open at parts corresponding to source/drain regions 5 is formed in the resist film 7B by lithography. Herein, the openings have a width of 100 nm, which corresponds to the width of the source/drain regions 5. On the other hand, the width of the resist 7B is 150 nm, which corresponds to the channel width where the memory cell transistors are formed.

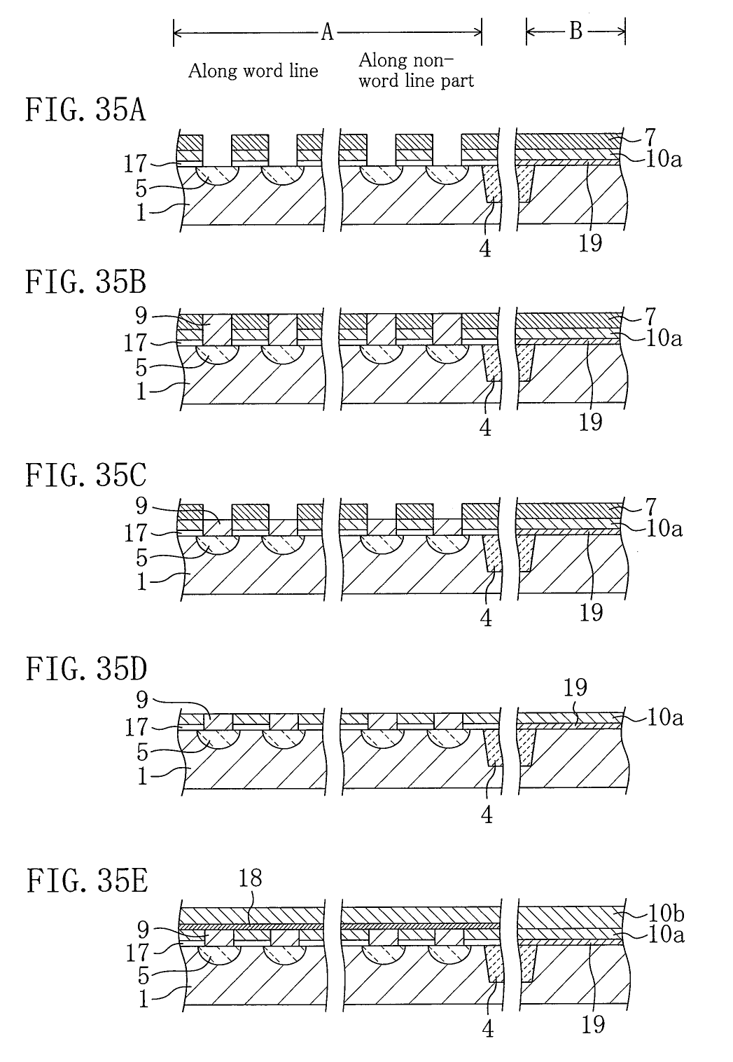

Next, as shown in FIG. 35A, dry etching using the resist film 7B (not shown) as a mask is performed on the mask formation film 7A to form, from the mask formation film 7A, a mask film 7 having openings for forming the source/drain regions 5. Then, the silicon oxide film (not shown), the first polycrystalline silicon film 10a, and the tunneling film 17 in the openings are removed. The tunneling film 17, which is thin, may be left for use as a protection film in ion implantation. Subsequently, using the mask film 7 thus formed, arsenic, for example, as an n-type impurity is implanted at an acceleration energy of 5 keV to 200 keV with a dosage of 1×10¹⁴ cm⁻² to 1×10¹⁷ cm⁻² one time or two or more time to form the source/drain regions 5 of n-type impurity diffusion layers in the memory element part A. Then, the resist film 7B is removed.

Subsequently, as shown in FIG. 35B, an insulating film (to be buried oxide films) 9 of silicon oxide is deposited in the openings of the mask film 7 by HDPCVD, LPCVD, or the like, and the silicon oxide film other than its parts filled in the openings of the mask film 7 is removed selectively by CMP or etching back, for example.

Thereafter, as shown in FIG. 35C, wet etching or dry etching back is performed to adjust the height of the filled silicon oxide film to be almost equal to the height of the first polycrystalline silicon film 10a.

Subsequently, as shown in FIG. 35D, wet etching or etching back is performed to selectively remove only the mask film 7, and the silicon oxide (not shown) is removed to form buried bit line oxide films 9. Whereby, the height of the buried bit line oxide films 9 is adjusted to be almost equal to the height of the polycrystalline silicon film 10a. This height adjustment is performed before selective removal of the mask film 7 in the present example embodiment, but may be preferably performed both before and after the selective removal thereof when further precision is required.

Thereafter, as shown in FIG. 35E, an inter-electrode insulating film 18 formed with a staked film (ONO film) of silicon oxide, silicon nitride, and silicon oxide is deposited on the buried oxide films 9 and the first polycrystalline silicon film 10a by, for example, LPCVD. Then, the inter-electrode insulating film 18 in the logic circuit part B is removed selectively. In addition, a second polycrystalline silicon film 10b, with which phosphorous as an n-type impurity is doped with 1×10¹⁸ cm^{-3 to} 1×10²² cm⁻³ is deposited on the memory element part A and the logic circuit part B by LPCVD, for example.

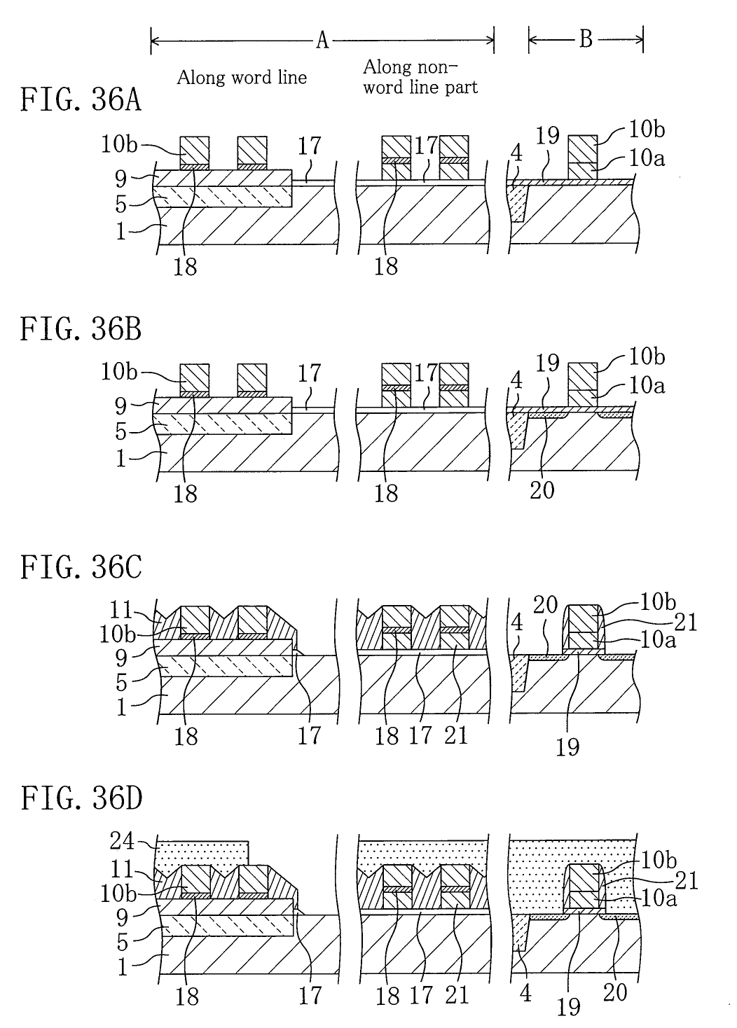

Subsequently, as shown in FIG. 36A, after coating a resist film (not shown), a resist pattern is formed in the direction of the word lines across source/drain regions 5 arranged at intervals in the memory element part A by lithography. At the same time, a resist pattern for a logic circuit is formed in the logic circuit part B. Then, dry etching using the resist pattern thus formed as a mask is performed to form openings in predetermined regions of the first and second polycrystalline silicon films 10a, 10b and the inter-electrode insulating film 18, thereby exposing the tunneling film 17 from the openings thus formed in the memory element part A, and exposing the gate oxide film 19 in the logic circuit part B. In FIG. 36A, the gate electrodes 10a, 10b are shown which form an angle of approximately 90±1° relative. Alternatively, the sidewalls of the gate electrodes 10b may be inclined at an angle of about 84°. Then, the resist film is removed.

Next, as shown in FIG. 36B, a resist film (not shown) having an opening pattern for exposing the logic circuit part B is formed on the semiconductor substrate 1, and an n-type ion is implanted into the logic circuit part B with the use of the resist film thus formed and the gate electrodes 10a, 10b as a mask to form low-concentration impurity diffusion layers 20 on the respective sides of the gate electrodes 10a, 10b in the logic circuit part C of the semiconductor substrate 1. Then, the resist film is removed.

Subsequently, as shown in FIG. 36C, CVD is performed to deposit a silicon oxide film with a thickness of about 5 nm to 100 nm and a silicon nitride film with a thickness of about 30 nm to 100 nm, for example, on the entirety of the semiconductor substrate 1. Etching back is performed to remove the insulating film on the tops of the gate electrodes 10b with the insulating film left on the side surfaces of the gate electrodes 10a, 10b. Further removed are the gate oxide film 19 in the logic circuit part B and part of the insulating film and part of the tunneling film 17 in the bit line contact parts 13 in the memory element part A. By doing this, sidewall insulating films 21 are formed on the respective sides of the gate electrodes 10a, 10b in the logic circuit part B, while buried films 11 are formed between the word lines in the memory element part A.

The etching rate in this time is set to correspond to a time period required for removing only the insulating film on the tops of the gate electrodes 10a, 10b and the gate oxide film 19 in the logic circuit part B. This causes substantially no removal of the insulating films buried between the gate electrodes 10a, 10b in the memory element part A to form ignorable projections and depressions on the memory cells. Appropriate adjustment of the overetching in the logic circuit part B may decrease variations in width of the sidewall insulating films 21, thereby enabling suppression of variations in transistor characteristics. For example, the etching rate is preferably set so that height difference between the top surfaces of the gate electrodes 10b and the top surfaces of the insulating films buried between the gate electrodes 10a, 10b in the memory element part A is equal to or smaller than 100 nm.

Thereafter, as shown in FIG. 36D, a resist pattern 24 is formed in the memory element part A for selectively exposing the sidewall insulating films (buried films 11) of the boundary word lines the closes to the bit line contact regions and the tunneling film 17.

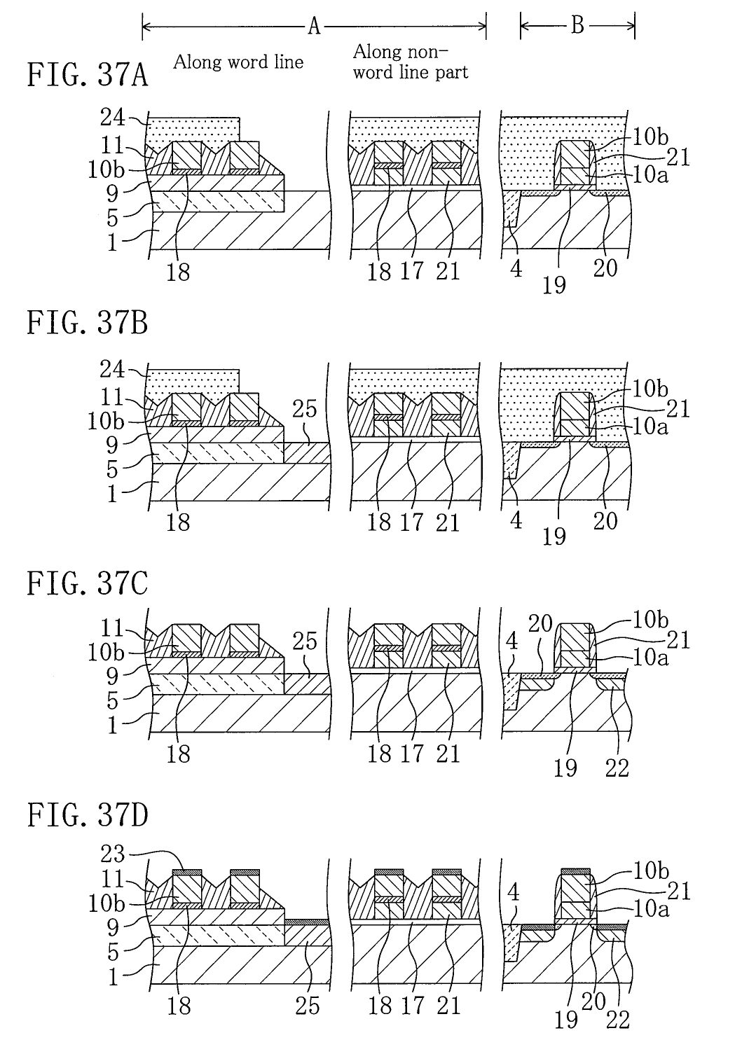

Next, as shown in FIG. 37A, dry etching is performed to remove the tunneling film 17 in the openings of the resist pattern 24, and to etch part of the sidewall insulating films (the buried films 11) of the boundary word lines. By this step, the sidewall insulating films (the buried films 11) of the boundary word lines are processed so as to decrease in width as the etching for removing the tunneling film 17 progresses, in other words, so as to expand the opening regions of the semiconductor substrate 1 in the openings.

Subsequently, as shown in FIG. 37B, ion implantation of, for example, arsenic as an n-type impurity is performed one time or two or more times under implantation conditions of 5 keV to 200 keV acceleration energy and 1×10 ¹⁴ cm⁻² to 1×10¹⁷ cm⁻² dosage to form high-concentration impurity diffusion layers 25 of n-type impurity diffusion layers in the bit line contact regions. The high-concentration impurity diffusion layers 25 are electrically connected to the source/drain regions 5 formed below the buried bit line oxide films 9. The, the resist pattern 24 is removed.

Thereafter, as shown in FIG. 36C, a resist film (not shown) having an opening pattern for exposing the logic circuit part B is formed on the semiconductor substrate 1, and an n-type impurity ion is implanted into the logic circuit part B of the semiconductor substrate 1 selectively with the use of the resist film thus formed, the gate electrodes 10a, 10b, and the sidewall insulating films 21 as a mask to form high-concentration impurity diffusion layers 22 to be the sources or the drains. The high-concentration impurity diffusion layers 22 in the logic circuit part B may be formed before forming the high-concentration diffusion layers 25 of the bit line contact parts 13 in the memory element part A shown in FIG. 36D to 37B.

Next, as shown in FIG. 37D, a metal film of cobalt, nickel, or the like is deposited on the entirety of the semiconductor substrate 1 by, for example, vacuum deposition, or the like, and thermal treatment is performed. Thus, a meal silicide layer 23 is formed in the upper parts of first word lines 10a and second word lines 10b, and the upper parts of the high-concentration impurity diffusion layers 25 of the bit line contact parts 13 in the memory element part A, while being formed in the upper parts of the gate electrodes 10b and the upper parts of the high-concentration impurity diffusion layers 22 in the logic circuit part B.

Although the steps thereafter will not be shown, as described in the third example embodiment, an interlayer insulating film of silicon oxide is deposited on the entirety of the semiconductor substrate 1 by CVD, for example, and then, a plurality of connection holes are formed selectively in the interlayer insulating film for exposing the metal silicide layer on the bit line contact parts by lithography and etching.

Subsequently, a conductive film of a single layer or stacked metal film is deposited entirely on the interlayer insulating film to fill the connection holes. The single layer or stacked metal film may be made of tungsten, a tungsten compound, titanium, a titanium compound of titanium nitride, or the like. Then, the conductive film thus deposited is patterned so that the source/drain regions disposed in the line direction are connected to each other, thereby forming bit lines from the conductive film.

Thus, a nonvolatile semiconductor memory device including the logic circuit part B and the memory element part A, which has the same configuration as that in the third example embodiment, can be obtained.

Hence, according to the present example embodiment, the same various effects can be obtained as those described in the third example embodiment.

Since the word lines (the gate electrodes) 10a, 10b in the memory element part A and the gate electrodes 10a, 10b of the transistors in the logic circuit part B can be formed in a single step, the number of steps can be reduced.

Variations can be suppressed in width of the sidewall insulating films 21 of the gate electrodes 10a, 10b of the transistors in the logic circuit part B to suppress variations in transistor characteristics. Hence, high yield can be achieved.

In the sixth example embodiment, the gate insulating film 19 in the logic circuit part B has a thickness of 3 nm, as one example, but may be adjusted to have a thickness in the range between 1 nm and 30 nm so as to optimize the kinds and characteristics of the transistors. Alternatively, gate insulating films having two more film thicknesses may be formed in combination.

In the present example embodiment, the dry etching on the polycrystalline silicon film is stopped at a time point when the height of the openings becomes equal to the height of the buried oxide films. As long as the step is stopped at the time point when the openings become at a height within the range of about 30 nm above or below the height of the buried oxide films, etching residue can be removed substantially. Accordingly, no problem can be involved

The second polycrystalline silicon film 10b forming the word lines in the memory element part A and forming the gate electrodes in the logic circuit part B is deposited as doped polysilicon in the present example embodiment. Alternatively, an impurity may be implanted after non-doped polysilicon with which no impurity is doped is deposited. The first and second polycrystalline silicon films 10a, 10b are only examples, and may be replaced by a single layer film or a stacked film of any of polysilicon, amorphous silicon, high-melting point metal having a melting point equal to or higher than 600° C., such as tantalum, titanium, and the like, a metal compound, and metal silicide. Alternatively, the second polycrystalline silicon film 10b forming the word lines may be silicided by metal.

In the present example embodiment, a silicon oxide film and a silicon nitride film by CVD are used as films buried and filled between the word lines 10, as an example. Any insulating film can be used preferably which is excellent in step coverage and capable of being formed by film formation using no plasma. However, a film is desirable which can be deposited in the form required for forming the sources and the drains by using sidewalls formed by a self-alignment technique in the logic circuit part B.

In the present example embodiment, the surfaces of parts in contact with the bit line contacts in the source/drain regions 5 of the memory element may be silicided by metal.

Each of the above example embodiments refers, but is not limited to a nonvolatile semiconductor memory device called a flash memory. Any of the above configurations is applicable, when optimized, to highly integrated nonvolatile semiconductor memory devices in which similar bit lines and word lines are arranged across each other, nonvolatile semiconductor memory devices, such as DRAMs and the like, and nonvolatile semiconductor memory devices, such as MRAMs, RRAMs, FRAMs, and the like.

As described above, the semiconductor memory devices and the manufacturing methods thereof in accordance with the example embodiments of the present invention can achieve both secured electrical connection between the bit line contacts and the bit line diffusion layers and suppression of void formation between the gate electrodes where the bit line contact regions are narrowed. Therefore, the present invention is useful in semiconductor memory devices especially having a structure in which bit line diffusion layers are connected electrically to bit lines thereabove through bit line contact parts, and manufacturing methods thereof.

What is claimed is:

1. A semiconductor memory device, comprising, in a memory region:
a plurality of bit line diffusion layers formed in upper part of a substrate and extending in a column direction;
a plurality of word lines formed on the substrate and extending in a line direction; and
a plurality of memory elements arranged in matrix and each including a pair of adjacent bit line diffusion layers, a gate insulating film interposed between the substrate and the word lines between the bit line diffusion layer pairs, and a gate electrode formed with part of a word line on the gate insulating film,
wherein each of the plurality of bit line diffusion layers is divided in plural in the column direction,
the plurality of bit line diffusion layers in respective columns are connected electrically to each other through bit line contact diffusion layers formed in upper part of the substrate,
regions between adjacent word lines are filled with sidewall insulating films formed on the respective sides of the adjacent word lines, and
among the sidewall insulating films formed at word lines adjacent to the bit line contact diffusion layers, sidewall insulating films formed on the sides of the bit line contact diffusion layers have a width smaller than those formed on the opposite sides of the bit line contact diffusion layers.

2. The device of claim 1, wherein
the gate electrode is formed with a stacked film of a lower layer film in each of the plurality of memory elements and an upper layer film formed on the lower layer film and forming a word line, and
the height of top surfaces of buried insulating films formed on the bit line diffusion layers and between the lower layer films is equal to that of top surfaces of the lower layer film in the line direction.

3. The device of claim 1, wherein
the gate insulating film forming a memory element includes a trap film having a charge storing function.

4. The device of claim 3, wherein
the gate insulating film is formed with a stacked film of a silicon oxide film, a silicon nitride film having a charge storing function, and a silicon oxide film, which are formed in this order from below.

5. The device of claim 2, wherein
the gate electrode is formed with a stacked film of
a floating gate electrode as the lower layer film having a charge storing function,
an inter-electrode insulating film formed on the floating gate electrode, and
a control gate electrode as the upper layer film formed on the inter-electrode insulating film.

6. The device of claim 1, wherein
the bit line diffusion layers include
a first impurity diffusion layer of a conductivity type opposite to a conductivity type of the substrate, and
a second impurity diffusion layer of the same conductivity type as that of the substrate, the second impurity diffusion layer being formed around the first impurity diffusion layer.

7. The device of claim 6, wherein
the first impurity diffusion layer has an impurity concentration higher than the second impurity diffusion layer.

8. The device of claim 1, wherein
the gate electrode is made of polycrystalline silicon or amorphous silicon.

9. The device of claim 8, further comprising:
a metal silicide layer formed in upper part of the gate electrode.

10. The device of claim 1, wherein
the gate electrode is formed with a metal film.

11. The device of claim 2 wherein
at least the upper layer film of the upper layer film and the lower layer film of the gate electrode is formed with a metal film.

12. The device of claim 1, further comprising:
a metal silicide layer formed in upper parts of the bit line contact diffusion layers.

13. The device of claim 1, further comprising:
a logic circuit region including a peripheral transistor in a region other than the memory region in the substrate,
wherein the peripheral transistor includes a gate electrode made of the same material as the gate electrode in the memory element.

14. A semiconductor memory device manufacturing method comprising:
(a) forming on a substrate a trap film having a charge storing function and a mask film in this order;
(b) forming, after forming openings by selectively removing the mask film, a plurality of bit line diffusion layers extending in a column direction and divided in plural in respective columns by introducing an impurity into the substrate through the openings;
(c) exposing, after filling the openings with a first buried insulating film after (b), the top surface of the mask film;
(d) removing, after (c), the mask film, while removing upper part of the first buried insulating film;
(e) forming, after (d), a conductive film on the substrate to cover the first buried insulating film;
(f) selectively removing the conductive film to expose part of the top surface of the trap film and part of the top surface of the first buried insulating film, and to form a plurality of word lines of the conductive film extending in a line direction;
(g) depositing, after (f), an insulating film on the substrate to cover the word lines, the exposed top surface of the trap film, and the exposed top surface of the first buried insulating film, and then performing etching back, thereby allowing sidewall insulating films formed with the insulating film remaining on the side surfaces of the word lines to form second buried insulating films buried between adjacent word lines;
(h) performing, after (g), etching using a mask pattern having openings for exposing bit line contact diffusion layer formation regions dividing the plurality of bit line diffusion layers in the respective columns to reduce the thickness of sidewall insulating films formed on the sides of the bit line contact diffusion layers among sidewall insulating films formed on word lines arranged adjacent to the bit line contact diffusion layer formation regions, and to remove the trap film exposed in the bit line contact diffusion layer formation regions, thereby exposing the substrate; and
(i) forming, after (h), bit line contact diffusion layers in the bit line contact diffusion layer formation regions by introducing an impurity to the exposed parts of the substrate.

15. The method of claim 14, wherein
the conductive film is a film selected from the group consisting of a polycrystalline silicon film, an amorphous silicon film, a metal film, a stacked film of a polycrystalline silicon film and a silicide film, and a stacked film of an amorphous silicon film and a silicide film.

16. The method of claim 14, wherein
(b) includes introducing the impurity into the substrate through the trap film with the trap film remaining on regions where the bit line diffusion layers are to be formed.

17. The method of claim 14, wherein
(b) includes introducing the impurity directly into the substrate with the trap film on regions where the bit line diffusion layers are to be formed removed.

18. The method of claim 14, further comprising:
siliciding, after (i), upper parts of the word lines and upper parts of the bit line contact diffusion layers.

19. The method of claim 14, wherein
in (g), the etching back is performed so that height difference between the word lines and the second buried insulating films is equal to or smaller than 100 nm.

20. A semiconductor memory device manufacturing method comprising:
(a) forming on a substrate a trap film having a charge storing function, a first conductive film, and a mask film in this order;
(b) forming, after forming openings by selectively removing the mask film and the first conductive film, a plurality of bit line diffusion layers extending in a column direction and divided in plural in respective columns by introducing an impurity into the substrate through the openings;
(c) exposing, after filling the openings with a first buried insulating film after (b), the top surface of the mask film;
(d) removing, after (c), the mask film to expose the top surface of the first conductive film, while removing the upper part of the first buried insulating film to equalize the height of the first buried insulating film to that of the first conductive film:
(e) forming, after (d), a second conductive film on the semiconductor substrate to cover the first conductive film and the first buried insulating film of which the top surfaces are exposed;
(f) selectively removing the first conductive film and the second conductive film to expose part of the top surface of the trap film and part of the top surface of the first buried insulating film and to form a plurality of word lines of the second conductive film extending in a line direction;
(g) depositing, after (f), an insulating film on the substrate to cover the word lines, the exposed top surface of the trap film, and the exposed top surface of first buried insulating film, and then performing etching back, thereby allowing sidewall insulating films formed with the insulating film remaining on the side surfaces of the word lines to form second buried insulating films buried between adjacent word lines;
(h) performing, after (g), etching using a mask pattern having openings for exposing bit line contact diffusion layer formation regions dividing the plurality of bit line diffusion layers in the respective columns to reduce the thickness of sidewall insulating films formed on the sides of the bit line contact diffusion layers among sidewall insulating films formed on word lines arranged adjacent to the bit line contact diffusion layer formation regions, and to remove the trap film exposed in the bit line contact diffusion layer formation regions, thereby exposing the substrate; and
(i) forming, after (h), bit line contact diffusion layers in the bit line contact diffusion layer formation regions by introducing an impurity to the exposed parts of the substrate.

21. The method of claim 20, wherein
the second conductive film is a film selected from the group consisting of a polycrystalline silicon film, an amorphous silicon film, a metal film, a stacked film of a polycrystalline silicon film and a silicide film, and a stacked film of an amorphous silicon film and a silicide film.

22. The method of claim 20, wherein
(b) includes introducing the impurity into the substrate through the trap film with the trap film remaining on regions where the bit line diffusion layer are to be formed.

23. The method of claim 20, wherein
(b) includes introducing the impurity directly into the substrate with the trap film on regions where the bit line diffusion layers are to be formed removed.

24. The method of claim 20, further comprising:
siliciding, after (i), upper parts of the word lines and upper parts of the bit line contact diffusion layers.

25. The method of claim 20, wherein
in (g), the etching back is performed so that height difference between the word lines and the second buried insulating films is equal to or smaller than 100 nm.

26. A semiconductor memory device manufacturing method comprising:
(a) forming on a substrate a tunneling film, a first conductive film, and a mask film in this order;
(b) forming, after forming openings by selectively removing the mask film and the first conductive film, a plurality of bit line diffusion layers extending in a column direction and divided in plural in respective columns by introducing an impurity into the substrate through the openings;
(c) exposing, after filling the openings with a first buried insulating film after (b), the top surface of the mask film;
(d) removing, after (c), the mask film to expose the top surface of the first conductive film, while removing the upper part of the first buried insulating film to equalize the height of the first buried insulating film to that of the first conductive film;
(e) forming, after (d), an inter-electrode insulating film and a second conductive film on the substrate in this order to cover the first conductive film and the first buried insulating film of which the top surfaces are exposed;
(f) selectively removing the first conductive film, the inter-electrode insulating film, and the second conductive film to expose part of the top surface of the tunneling film and part of the top surface of the first buried insulating film, and to form a plurality of word lines formed with the second conductive film and extending in a line direction;
(g) depositing, after (f), an insulating film on the substrate to cover the word lines, the exposed top surface of the tunneling film, and the top surface of the first buried insulating film, and then performing etching back, thereby allowing sidewall insulating films formed with the insulating film remaining on the side surfaces of the word lines to form second buried insulating films between adjacent word lines;
(h) performing, after (g), etching using a mask pattern having openings for exposing bit line contact diffusion layer formation regions dividing the plurality of bit line diffusion layers in the respective columns to reduce the thickness of sidewall insulating films formed on the sides of the bit line contact diffusion layers among sidewall insulating films formed on word lines arranged adjacent to the bit line contact diffusion layer formation regions, and to remove the tunneling film exposed in the bit line contact diffusion layer formation regions, thereby exposing the substrate; and
(i) forming, after (h), bit line contact diffusion layers in the bit line contact diffusion layer formation regions by introducing an impurity to the exposed parts of the substrate.

27. The method of claim 26, wherein
the second conductive film is a film selected from the group consisting of a polycrystalline silicon film, an amorphous silicon film, a metal film, a stacked film of a polycrystalline silicon film and a silicide film, and a stacked film of an amorphous silicon film and a silicide film.

28. The method of claim 26, wherein
(b) includes introducing the impurity into the substrate through the tunneling film with the tunneling film remaining on regions where the bit line diffusion layers are to be formed.

29. The method of claim 26, wherein
(b) includes introducing the impurity directly into the substrate with the tunneling film on regions where the bit line diffusion layers are to be formed removed.

30. The method of claim 26, further comprising:
siliciding, after (i), the upper parts of the word lines and the upper parts of the bit line contact diffusion layers.

31. The method of claim 26, wherein
in (g), the etching back is performed so that height difference between the word lines and the second buried insulating films is equal to or smaller than 100 nm.

32. A semiconductor memory device manufacturing method comprising:
(a) forming a trap film having a charge storing function in a memory element formation region and a logic circuit formation region formed in regions defined in a substrate;
(b) removing the trap film on the logic circuit formation region;
(c) forming, after (b), a gate insulating film on the logic circuit formation region;
(d) forming a mask film on the trap film in the memory element formation region;
(e) forming, after forming openings by selectively removing the mask film, a plurality of bit line diffusion layers extending in a column direction and divided in plural in respective columns in the memory element formation region by introducing an impurity into the substrate through the openings;
(f) exposing, after filling the openings with a first buried insulating film, the top surface of the mask film in the memory element formation region;
(g) removing, after (f), the mask film, while removing the upper part of the first buried insulating film in the memory element formation region;
(h) forming, after (g), a conductive film to cover the first buried insulating film in the memory element formation region, and to cover the gate insulating film in the logic circuit formation region;
(i) selectively removing the conductive film to expose part of the top surface of the trap film and part of the top surface of the first buried insulating film and to form a plurality of word lines extending in the line direction and formed with the conductive film in the memory element formation region, and to form gate electrodes formed with the conductive film in the logic circuit formation region;
(j) depositing, after (i), an insulating film on the substrate to cover the word lines, the exposed top surface of the trap film, and the exposed top surface of the first buried insulating film in the memory element formation region, and to cover the gate electrodes in the logic circuit formation region, and then performing etching back, thereby allowing first sidewall insulating films formed with the insulating film remaining on the side surfaces of the word lines to form second buried insulating films buried between adjacent word lines in the memory element formation region, and to form second sidewall insulating films formed with the insulating film remaining on the side surfaces of the gate electrodes in the logic circuit formation region;
(k) performing, after (j), etching back using a mask pattern having openings for exposing bit line contact diffusion layer formation regions dividing the plurality of bit line diffusion layers in the respective columns in the memory element formation region to reduce the thickness of the first sidewall insulating films formed on the sides of the bit line contact diffusion layers among the first sidewall insulating films formed on word lines arranged adjacent to the bit line contact diffusion layer formation regions, and to remove the trap film exposed in the bit line contact diffusion layer formation regions, thereby exposing the semiconductor substrate; and
(l) forming, after (k), bit line contact diffusion layers in the bit line contact diffusion layer formation regions in the memory element formation region by introducing an impurity to the exposed part of the substrate.

33. A semiconductor memory device manufacturing method comprising:
(a) forming a trap film having a charge storing function in a memory element formation region and a logic circuit formation region formed in regions defined in a substrate;
(b) removing the trap film on the logic circuit formation region;
(c) forming, after (b), a gate insulating film on the logic circuit formation region;
(d) forming a first conductive film on the trap film in the memory element formation region, and on the gate insulating film in the logic circuit formation region;
(e) forming a mask film on the first conductive film in the memory element formation region;
(f) forming, after forming openings by selectively removing the mask film and the first conductive film, a plurality of bit line diffusion layers extending in a column direction and divided in plural in respective columns in the memory element formation region by introducing an impurity into the substrate through the openings;
(g) filling the openings with a first buried insulating film, and then exposing the top surface of the mask film in the first memory element formation region;
(h) removing, after (g), the mask film to expose the top surface of the first conductive film, while removing part of the upper part of the first buried insulating film in the memory element formation region, thereby equalizing the height of the first buried insulating film to that of the first conductive film;
(i) forming, after (h), a second conductive film to cover the first conductive film and the first buried insulating film of which the top surfaces are exposed in the memory element formation region, and to cover the first conductive film in the logic circuit formation region;
(j) selectively removing the second conductive film to expose part of the top surface of the trap film and part of the top surface of the first buried insulating film and to form a plurality of word lines extending in the line direction and formed with the second conductive film in the memory element formation region, and to form gate electrodes formed with the first conductive film and the second conductive film in the logic circuit formation region;
(k) depositing, after (j), an insulating film on the substrate to cover the word lines, the exposed top surface of the trap film, and the exposed top surface of the first buried insulating film in the memory element formation region, and to cover the gate electrodes in the logic circuit formation region, and then performing etching back, thereby allowing first sidewall insulating films formed with the insulating film remaining on the side surfaces of the word lines to form second buried insulating films buried between adjacent word lines in the memory element formation region, and to form second sidewall insulating films formed with the insulating film remaining on the side surfaces of the gate electrodes in the logic circuit formation region;
(l) performing, after (k), etching back using a mask pattern having openings for exposing bit line contact diffusion layer formation regions dividing the plurality of bit line diffusion layers in the respective columns in the memory element formation region to reduce the thickness of the first sidewall insulating films formed on the sides of the bit line contact diffusion layers among the first sidewall insulating films formed on word lines arranged adjacent to the bit line contact diffusion layer formation regions, and to remove the trap film exposed in the bit line contact diffusion layer formation regions, thereby exposing the semiconductor substrate; and
(m) forming, after (l), bit line contact diffusion layers in the bit line contact diffusion layer formation regions in the memory element formation region by introducing an impurity to the exposed part of the substrate.

34. A semiconductor memory device manufacturing method comprising:
(a) forming a tunneling film having a charge storing function in a memory element formation region and a logic circuit formation region formed in regions defined in a substrate;
(b) removing the tunneling film on the logic circuit formation region;
(c) forming, after (b), a gate insulating film on the logic circuit formation region;
(d) forming a first conductive film on the tunneling film in the memory element formation region, and the gate insulating film in the logic circuit formation region;
(e) forming a mask film on the first conductive film in the memory element formation region;
(f) forming, after forming openings by selectively removing the mask film and the first conductive film, a plurality of bit line diffusion layers extending in a column direction and divided in plural in respective columns in the memory element formation region by introducing an impurity into the substrate through the openings;
(g) filling the openings with a first buried insulating film, and then exposing the top surface of the mask film in the memory element formation region;
(h) removing, after (g), the mask film to expose the top surface of the first conductive film, while removing part of the upper part of the first buried insulating film in the memory element formation region, thereby equalizing the height of the first buried insulating film to that of the first conductive film;
(i) forming, after (h), an inter-electrode insulating film in the memory element formation region and the logic circuit formation region, and then removing the inter-electrode insulating film on the logic circuit formation region;
(j) forming, after (i), a second conductive film to cover the inter-electrode insulating film in the memory element formation region, and to cover the first conductive film in the logic circuit formation region;
(k) selectively removing the second conductive film to expose part of the top surface of the tunneling film and part of the top surface of the first buried insulating film and to form a plurality of word lines extending in the line direction and formed with the second conductive film in the memory element formation region, and to form gate electrodes made of the first conductive film and the second conductive film in the logic circuit formation region;
(l) depositing, after (k), an insulating film on the substrate to cover the word lines, the exposed top surface of the tunneling film, and the exposed top surface of the first buried insulating film in the memory element formation region, and to cover the gate electrodes in the logic circuit formation region, and then performing etching back, thereby allowing first sidewall insulating films formed with the insulating film remaining on the side surfaces of the word lines to form second buried insulating films buried between adjacent word lines in the memory element formation region, and to form second sidewall insulating films formed with the insulating film remaining on the side surfaces of the gate electrodes in the logic circuit formation region;
(m) performing, after (l), etching back using a mask pattern having openings for exposing bit line contact diffusion layer formation regions dividing the plurality of bit line diffusion layers in the respective columns in the memory element formation region to reduce the thickness of the first sidewall insulating films formed on the sides of the bit line contact diffusion layers among the first sidewall insulating films formed on word lines arranged adjacent to the bit line contact diffusion layer formation regions, and to remove the tunneling film exposed in the bit line contact diffusion layer formation regions, thereby exposing the semiconductor substrate; and
(n) forming, after (m), bit line contact diffusion layers in the bit line contact diffusion layer formation regions in the memory element formation region by introducing an impurity to the exposed part of the substrate.
